(19) United States
(12) Patent Application Publication
(10) Pub. No.: US 2011/0061812 A1
(43) Pub. Date: Mar. 17, 2011

(54) Apparatus and Methods for Cyclical Oxidation and Etching

(75) Inventors: Udayan Ganguly, Sunnyvale, CA (US); Yoshitaka Yokota, San Jose, CA (US); Christopher S. Olsen, Fremont, CA (US); Matthew D. Scotney-Castle, Morgan Hill, CA (US); Vicky Nguyen, Milpitas, CA (US); Swaminathan Srinivasan, Pleasanton, CA (US); Wei Liu, San Jose, CA (US); Johanes F. Swenberg, Los Gatos, CA (US); Jose A. Marin, San Jose, CA (US); Aijit Balakrishna, Sunnyvale, CA (US); Jacob Newman, Palo Alto, CA (US); Stephen C. Hickerson, Hollister, CA (US)

(73) Assignee: Applied Materials, Inc., Santa Clara, CA (US)

(21) Appl. No.: 12/720,926

(22) Filed: Mar. 10, 2010

Related U.S. Application Data
(63) Continuation-in-part of application No. 12/558,370, filed on Sep. 11, 2009.

(51) Int. Cl. H01L 21/465

(52) U.S. Cl. 156/345.34; 156/345.1; 257/E21.485

(57) ABSTRACT

Apparatus and methods for the manufacture of semiconductor devices suitable for narrow pitch applications and methods of fabrication thereof are described herein. Disclosed are various single chambers configured to form and/or shape a material layer by oxidizing a surface of a material layer to form an oxide layer; removing at least some of the oxide layer by an etching process; and cyclically repeating the oxidizing and removing processes until the material layer is formed to a desired shape. In some embodiments, the material layer may be a floating gate of a semiconductor device.

### CROSS REFERENCE TO RELATED APPLICATIONS

This application is a continuation in part of benefit of U.S. application Ser. No. 12/558,370, filed Sep. 11, 2009, which is herein incorporated by reference in its entirety.

### FIELD

Embodiments of the present invention generally relate to the field of semiconductor manufacturing processes and devices, and more particularly, to apparatus and methods for the manufacture of devices suitable for use in narrow pitch applications.

### BACKGROUND

Scaling semiconductor devices by simply shrinking the device structure often does not produce acceptable results at small dimensions. For example, in NAND flash memory devices, when a floating gate is scaled the capacitive coupling (e.g., sidewall capacitance) of the floating gate is scaled accordingly with the surface area of the floating gate. As such, the smaller the surface area of the floating gate, the smaller the capacitive coupling between the floating gate and, for instance, a control gate. Typically, a trade-off that sacrifices capacitive coupling for scaling is acceptable provided the NAND memory device still functions. Unfortunately, the scaling is limited when the device node becomes sufficiently small such that the capacitive coupling between the floating gate and control gate becomes too small to effectively program the device at permissible operational voltages. Furthermore, parasitic capacitance (i.e., noise) between adjacent floating gates increases beyond the margin for read error of a system controller in a NAND memory device. Thus, a functioning NAND device is not possible under such conditions.

Methods and apparatus for the manufacture of devices have small surface area, for example, NAND devices and other devices.

### SUMMARY

Apparatus and methods for manufacturing semiconductor devices suitable for narrow pitch applications are described herein. While the various apparatus and methods described herein are not intended to be limited to the manufacture of a particular type of device, the apparatus and methods described herein are particularly suitable for manufacturing a semiconductor device including a floating gate having a first width proximate a base of the floating gate that is greater than a second width proximate a top of the floating gate. In some embodiments, the width of the floating gate decreases non-linearly from the first width to the second width.

In some embodiments, an apparatus for processing a substrate may include a process chamber having a substrate support disposed therein and configured to support a substrate, the substrate support further having a temperature control system coupled thereto to control the temperature of the substrate support proximate a first temperature; a gas source to provide at least an oxygen-containing gas, an inert gas and an etching gas; a plasma source coupled to the process chamber to provide energy to gases provided by the gas source to form at least one of an oxidizing plasma or an etching plasma; and a heat source coupled to the process chamber to provide energy to the substrate to selectively raise the temperature of the substrate to a second temperature greater than the first temperature. Other and further embodiments of the present invention are described hereinbelow.

According to one or more embodiments, a complete process sequence of an oxidation (and/or nitridation) and an etching step can be completed in the chambers in less than about three minutes. In specific embodiments, a complete process sequence of an oxidation and/or nitridation and an etching step can be completed in the chambers in less than about two minutes, and in more specific embodiments, a complete process sequence of an oxidation and/or nitridation and an etching step can be completed in the chambers in less than about one minute, for example 45 seconds or 30 seconds.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a semiconductor structure having a floating gate made utilizing methods and apparatus in accordance with some embodiments of the present invention;

FIG. 2 depicts a flow chart for a method of forming a floating gate in accordance with some embodiments of the present invention.

FIGS. 3A-C depict stages of fabrication of a floating gate in accordance with some embodiments of the method of FIG. 2.

FIG. 4 depicts a flow chart for a method of forming a floating gate in accordance with some embodiments of the present invention.

FIGS. 5A-E depict stages of fabrication of a floating gate in accordance with some embodiments of the method of FIG. 4.

FIG. 6 depicts a flow chart for a method of forming a floating gate in accordance with some embodiments of the present invention.

FIGS. 7A-D depict stages of fabrication of a floating gate in accordance with some embodiments of the method of FIG. 6.

FIGS. 8A-B depict stages of fabrication of a floating gate in accordance with some embodiments of the method of FIG. 6.

FIG. 9 depicts a schematic plot of oxide thickness as a function of time in accordance with some embodiments of the present invention.

FIG. 10A-D depicts the stages of fabrication of a floating gate in accordance with some embodiments of the present invention.

FIG. 11A-C depicts the stages of fabrication of a structure in accordance with some embodiments of the present invention.

FIG. 12 depicts an exemplary process chamber in accordance with some embodiments of the present invention.

FIG. 13A depicts a first exemplary modified plasma process chamber in accordance with some embodiments of the present invention.

FIG. 13B depicts an exemplary embodiment of substrate support cooling system that can be used in chambers according to several embodiments.

FIG. 14 depicts a second exemplary modified plasma process chamber in accordance with some embodiments of the present invention.

FIG. 15 depicts a third exemplary modified plasma process chamber in accordance with some embodiments of the present invention.

FIG. 16 depicts a light source system that can be used for heating a material surface according to chambers of one or more embodiments.

FIG. 17 depicts further detail of the light source system of FIG. 16 that can be used for heating a material surface according to one or more embodiments

FIG. 18 depicts a modified chamber for performing cyclical oxidation and etching according to an embodiment of the invention.

FIG. 19 depicts a top portion of the chamber of FIG. 18.

FIG. 20 depicts a lower portion of the chamber of FIG. 18.

FIG. 21 depicts a modified rapid thermal processing chamber according to one or more embodiments.

FIG. 22 depicts a gas distribution plate used in the chamber of FIG. 21.

The drawings have been simplified for clarity and are not drawn to scale. To facilitate understanding, identical reference numerals have been used, wherever possible, to designate identical elements that are common to the figures. It is contemplated that some elements of one embodiment may be beneficially incorporated in other embodiments.

### DETAILED DESCRIPTION

Apparatus and methods for oxidizing a surface of a material layer of a semiconductor device to form an oxide layer and removing at least a portion of the oxide layer by etching in a single chamber. While the present invention is not to be limited to a particular device, the apparatus and methods described can be used for the manufacture of semiconductor devices and structures suitable for narrow pitch applications. As used herein, narrow pitch applications include half-pitches of 32 nm or less (e.g., device nodes of 32 nm or less). The term “pitch” as used herein refers to a measure between the parallel structures or the adjacent structures of the semiconductor device. The pitch may be measured from side to side of the same side of the adjacent or substantially parallel structures. Of course, the semiconductor devices and structures may be utilized in applications having greater pitches as well. The semiconductor devices may be, for example, NAND or NOR flash memory, or other suitable devices. In some embodiments, the semiconductor devices maintain or improve sidewall capacitance between a floating gate and, for example, a control gate of the device, thereby reducing interference (i.e., noise) between adjacent floating gates in adjacent devices. The inventive apparatus and methods disclosed herein advantageously limit undesired effects, such as oxygen diffusion which can, for example, thicken a tunnel oxide layer during processing. Further, the inventive apparatus and methods can advantageously be applied towards the fabrication of other devices or structures, for example, such as Fin Field Effect Transistors (FinFET) devices, hard mask structures, or other structures, to overcome size limitations in the critical dimension imposed by conventional lithographic patterning. It is contemplated that the specific oxidation and etching apparatus and processes disclosed herein with respect to the formation of one structure may be utilized in the formation of any other structure disclosed herein unless noted to the contrary.

Thus, embodiments of the present invention provide apparatus and methods for performing layer by layer cyclic oxidation and etching in a single chamber or tool, enabling higher throughput than if the processes were performed in separate chambers or tools. When multiple iterations of cyclic oxidation and etching are required to be performed in separate chambers, throughput suffers due to interchamber transfer time. Throughputs can be enhanced if a chamber or tool capable of multiple processes is provided. However, a chamber that can perform multiple etching an oxidation processes that require very disparate temperatures is not believed to be available. According to one or more embodiments, chambers or tools are provided that enable rapid heating and cooling of substrates in a single chamber, thus allowing cyclic oxidation and/or nitridation and etching processes to be performed. In one or more embodiments, the process chambers disclosed herein can perform a single cycle of oxidation and etching as described herein in less than 5 minutes, less than 4 minutes, less than 3 minutes, less than 2 minutes, less than 1 minute, or less than 30 seconds. In one or more embodiments, the oxidation process is performed at temperatures between about 200° C. and 800° C., more specifically between about 300° C. and 500° C., and a portion of the etching process is performed at a temperature below about 150° C., specifically, below about 120° C., and more specifically at less than or equal to about 100° C. In one or more embodiments, the etching process utilizes a dry etch process using a plasma, for example, a fluorine-containing plasma, and the etching process includes a process that is performed below about 50° C., specifically below about 40° C., and more specifically in the range of about 25° C. to 35° C. followed by a step performed at a temperature exceeding about 100° C., for example in the range of about 100° C. to about 200° C.

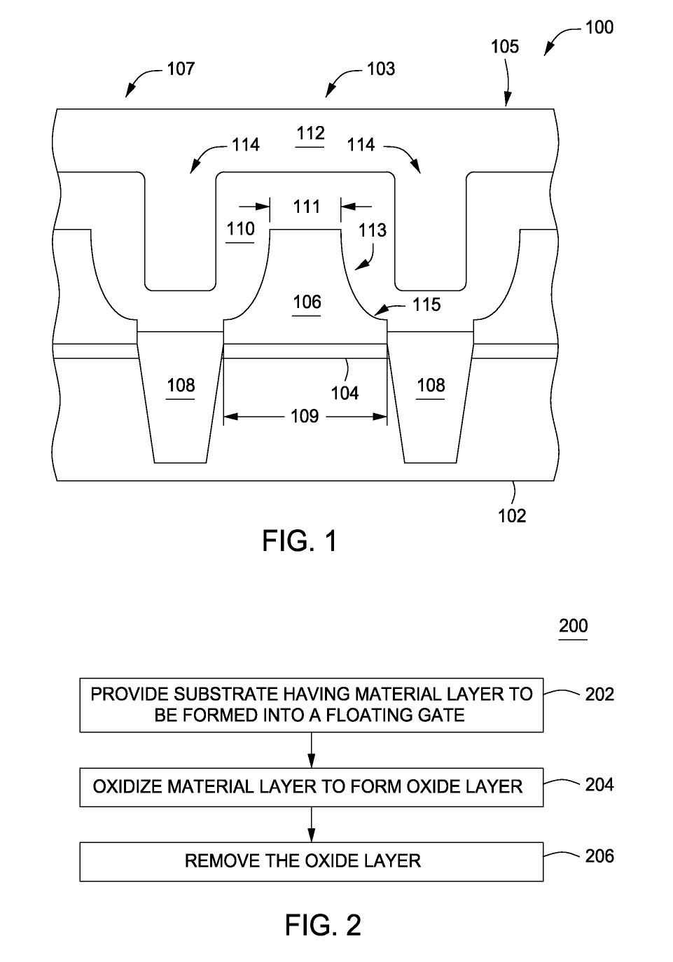

An example of a semiconductor device that can be made with and apparatus and/or method embodiment of the present invention is described below with respect to FIG. 1 in an illustrative application as a memory device 100. The memory device 100 includes a substrate 102 having a tunnel oxide layer 104 disposed thereon. A floating gate 106 is disposed on the tunnel oxide layer 104. The floating gate 106, the tunnel oxide layer 104, and the underlying portion of the substrate 102 may comprise a cell 103 (or memory unit) of the memory device 100. Each cell of the memory device may be separated. For example, in the memory device 100, a shallow trench isolation (STI) region 108 is disposed in the substrate 102 between each cell (for example, adjacent to the tunnel oxide layer 104 and floating gate 106, where the STI region 108 separates the cell 103 from adjacent cells 105 and 107). The memory device 100 further includes an inter-poly dielectric (IPD) layer 110 disposed above the floating gate 106 and a control gate layer 112. The IPD layer 110 separates the floating gate 106 from the control gate layer 112.

The substrate 102 may comprise a suitable material such as crystalline silicon (e.g., Si<100> or Si<111>), silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, or the like. In some embodiments, the substrate 102 comprises silicon. The tunnel oxide layer 104 may comprise silicon and oxygen, such as silicon oxide (SiO₂), silicon oxynitride (SiON), or high-k dielectric materials, such as aluminum—(Al), hafnium—(Hf), or lanthanum—(La), zirconium—(Zr) based oxides or oxynitrides, or silicon nitrides (Si_{X}N_{Y}), in single or layered structures (e.g., SiO₂/high-k/SiO₂), or the like. The tunnel oxide layer 104 may have any suitable thickness, for example, between about 5 to about 12 nm. The tunnel oxide layer 104 may have a width, within each cell, substantially equivalent to the width of a base of the floating gate 106. The STI region 108 may comprise silicon and oxygen, such as silicon oxide (SiO₂), silicon oxynitride (SiON), or the like.

The floating gate 106 typically comprises a conductive material, such as polysilicon, metals, or the like. The floating gate 106 has a configuration suitable to facilitate disposing portions of the control gate layer 112 between adjacent cells (e.g., between cells 103, 105, and 107). As such, the floating gate may be formed in an inverted “T” shape. As used herein, the term inverted “T” refers generally to the geometry of the structure wherein an upper portion of the floating gate 106 is relieved with respect to a base of the floating gate 106. Such relief provides room for the IPD layer 110 to be formed over the floating gate 106 without completely filling the gap between adjacent floating gates 106, thereby allowing a portion of the control gate layer 112 to be disposed between adjacent floating gates 106.

For example, as illustrated in FIG. 1, the floating gate 106 is generally shown in the shape of an inverted T having a base 115 and a stem 113 (or an upper portion of the floating gate 106). The floating gate 106 may generally have any dimensions as desired for a particular application. In some embodiments, the height of the floating gate 106 may be between about 20 to about 100 nm. In some embodiments, the thickness of the base 115 may be less than or equal to about 35 nm.

Due to the relief of the upper portion of the floating gate 106, the floating gate 106 has a first width 109 proximate the base 115 of the floating gate 106 that is greater than a second width 111 proximate the top of the floating gate 106. In some embodiments, a ratio of the first width 109 to the second width 111 is at least about 2:1. In some embodiments, the first width 109 may exceed the second width 111 by about 4 nm or more, or about 6 nm or more, or between about 4 to about 6 nm. The width of the floating gate 106 may vary linearly, non-linearly, continuously, non-continuously, in any fashion, between the base 115 and the top of the floating gate 106. In some embodiments, and as illustrated in FIG. 1, the width of the floating gate 106 varies non-linearly between the first width 109 and the second width 111. In some embodiments, the first width may be less than about 35 nm, or between about 20 to about 35 nm. The second width may be between about 5 to about 30 nm, for example, 5 nm, 10 nm, 12 nm, 13 nm, 14 nm, 15 nm, 20 nm, 25, nm or 30 nm.

The stem 113 may have a sidewall portion thereof having a substantially vertical profile, as illustrated in FIG. 1. In some embodiments, substantially vertical means less than or equal to about 10 degrees of vertical, or less than or equal to about 5 degrees of vertical, or less than or equal to about 1 degree of vertical. The substantially vertical profile of the sidewall may be up to about 40 percent, or greater than about 40 percent of the total height of the floating gate 106. In some embodiments, the substantially vertical profile is greater than about 40 percent of the height of the floating gate 106. In some embodiments, the substantially vertical profile is between about 20 to about 100 nm.

The IPD layer 110 may comprise any suitable single or multi-layer dielectric materials. A single layer IPD may comprise SiO₂, SiON, a high-k dielectric material as discussed above with respect to tunnel oxide layer 104, or the like. A non-limiting example of a multi-layer IPD is a multi-layer ONO layer comprising a first oxide layer, a nitride layer, and a second oxide layer. The first and second oxide layers typically comprise silicon and oxygen, such as silicon oxide (SiO₂), silicon oxynitride (SiON), or the like. The nitride layer typically comprises silicon and nitrogen, such as silicon nitride (SiN), or the like. In some embodiments, a multi-layer IPD layer comprising SiO₂/high-k/SiO₂ (such as, SiO₂/Al₂O₃/SiO₂) can also be used as the IPD layer 110. In some embodiments, the IPD layer 110 is deposited to a thickness of between about 12 to about 15 nm.

Conformal deposition of the IPD layer 110 over the inverted T shape of the floating gate 106 facilitates forming a well 114 in the deposited IPD layer 110. The well 114 is formed between adjacent floating gates. In some embodiments, the well 114 has a width of between about 4 to about 20 nm and a depth of between about 20 to about 90 nm.

Optionally, prior to IPD deposition, the depth level of the IPD penetration between adjacent floating gates may be defined by depositing a layer of material, such as SiO₂, to fill the gap between adjacent floating gates, planarizing the layer of material, for example, by chemical mechanical planarization (CMP), to remove excess material down to the top of the floating gate 106. The material remaining in the gap between adjacent floating gates may then be etched to a desired depth to set the level of IPD penetration between the floating gates.

The control gate layer 112 may be deposited atop the IPD layer 110 and in the well 114 to form a control gate. The control gate layer 112 typically comprises a conductive material, such as polysilicon, metal, or the like. The addition of the well 114 provides a larger surface area for the control gate layer 112 proximate a sidewall of the floating gate 106. The increased surface area of the control gate layer 112 facilitated by the well 114 may advantageously improve capacitive coupling between a sidewall of the floating gate 106 and the control gate. Further, the well 114, disposed between adjacent floating gates (for example, those of cells 103 and 105) may reduce parasitic capacitance between adjacent floating gates, floating gate interference, noise, or the like. In addition, the inverted T shape of the floating gate 106 reduces the surface area as compared to an approximate rectangle for the same floating gate height. The reduced cross-section advantageously reduces parasitic capacitance between adjacent floating gates in the bitline direction (e.g., in a different word line and the same bit line of a memory device). Advantageously, the sidewall capacitance between the floating gate and the control gate can be independently controlled (e.g., maintained at a desirable level) by control of the height of the floating gate.

FIG. 2 depicts a method 200 of fabricating a semiconductor device having a floating gate geometry in accordance with some embodiments of the present invention. The methods described herein may be performed in any suitable single chamber configured for oxidation and etching with the ability to process at disparate temperatures. In processes that involve cyclic oxidation and etching, according to one or more embodiments, the oxidation is performed at relatively high temperatures, and etching is performed at relatively low temperatures. For example, oxidation may be performed at temperatures of 500° C. and above according to one or more embodiments, and alternatively, at temperatures of 500° C. and below, more particularly 400° C. and below. For example, portions of the etch process may be performed at low temperatures, for example, room temperature, such as 20° C., 25° C. or 30° C. It will be understood that the etching process may be performed at higher temperatures such as up to about 75° C. After etching, it may be desirable to raise the temperature to about 100° C. to sublimate compounds, which is described in more detail below.

Aspects of the invention pertain to performing an oxidation process, an etching process and sublimation in a single chamber. Oxidation may be achieved by plasma oxidation, rapid thermal oxidation (RTO), radical oxidation, or the like. Suitable oxidation chambers may include plasma chambers such as Plasma Immersion Ion Implantation (P3I), or Decoupled Plasma Oxidation (DPO). Alternatively, thermal oxidation chambers can be used such as RADIANCE®, VANTAGE® RADOX™ chambers available from Applied Materials, Inc. of Santa Clara, Calif., or a furnace including a remote and/or local plasma source. Exemplary thermal oxidation processes may be performed with various oxidative chemistries include varying reducing gas concentration for reducing gases, such as one or more of hydrogen (H₂), ammonia (NH₃) or the like within an oxidative gas mixture include oxidative gases, such as one or more of oxygen (O₂), nitric oxide (NO), nitrous oxide (N₂O) or the like, and optionally including inert gases, such as one or more of nitrogen (N₂), argon (Ar), helium (He), or the like. Exemplary plasma oxidation processes may use any of the oxidative chemistries discussed above for thermal oxidation processes, and may be performed with or without a heating chuck. Photochemical processes, for example, utilizing oxygen species (e.g., O₂) in the presence of ultraviolet light (UV) to form an oxide layer, or wet chemical oxidation, for example utilizing a chemical solution including nitric acid (HNO₃) another suitable acid for oxidation, can also be applied. However, these chambers are typically configured to perform oxidation processes only, and are not configured for low temperature processing such as low temperature etching. Accordingly, modification to the chambers will be necessary to achieve rapid temperature changes required between oxidation and etching. Specific details will be provided below.

Alternatively, embodiments of methods described herein may be performed in any suitable modified etch chamber configure for wet or dry etch, reactive ion etch (RIE), or the like. Exemplary etch chambers include the SICONI™, Producer®, or Carina™ chambers, also available from Applied Materials, Inc. of Santa Clara, Calif. One non-limiting, exemplary dry etch process may include ammonia or (NH₃) or nitrogen trifluoride (NF₃) gas, or an anhydrous hydrogen fluoride (HF) gas mixture with a remote plasma, which condenses on SiO₂ at low temperatures (e.g., −30° C.) and reacts to form a compound which can be sublimated at moderate temperature (e.g., >100° C.) to etch SiO₂. Such an exemplary etch process can diminish over time and eventually saturate to a point where no further etching occurs unless portions of the compound are removed (for example, by the sublimation process described above). The etch process can be controlled using the above mechanism and/or by a timed etch process (e.g., etching for a predetermined period of time). Exemplary wet etch processes may include hydrogen fluoride (HF) or the like. Exemplary plasma or remote plasma etch processes may include one or more etchants such as carbon tetrafluoride (CF₄), trifluoromethane (CHF₃), sulfur hexafluoride (SF₆), hydrogen (H₂), or the like, and may be performed with or without a heating chuck. The etch selectivity can be engineered to be between about 1 to about 1000 for different materials combinations, such as heterogeneous surfaces and the like. For example, in some embodiments, the etch selectivity can be about 100 for silicon (Si) in a silicon dioxide (SiO₂) etch. The etch can be terminated as the etch rate drops to between about 0% to about 90%, or to about 75% of the initial etch rate to provide thickness control of the materials being etched. For example, in some embodiments, terminating the etch process as discussed above may provide thickness control when etching. This control may be particularly advantageous when etching an oxide layer disposed atop heterogeneous materials, for example, including silicon (Si) and silicon dioxide (SiO₂). Etching chambers such as the SICONI chambers will require modifications to perform oxidation processes in the chamber, which will be described in more detail below.

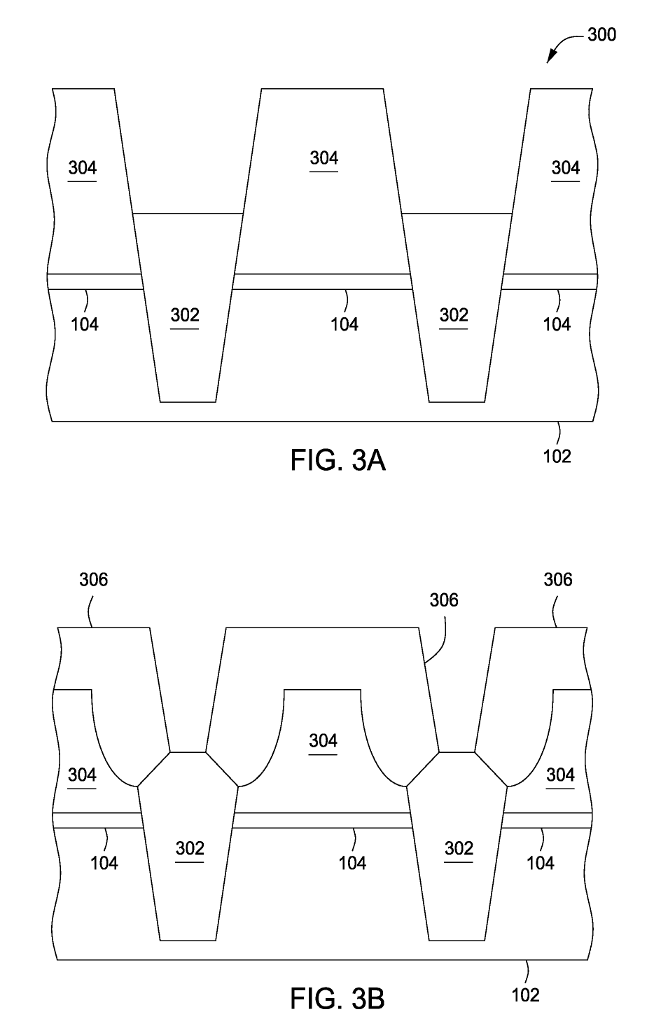

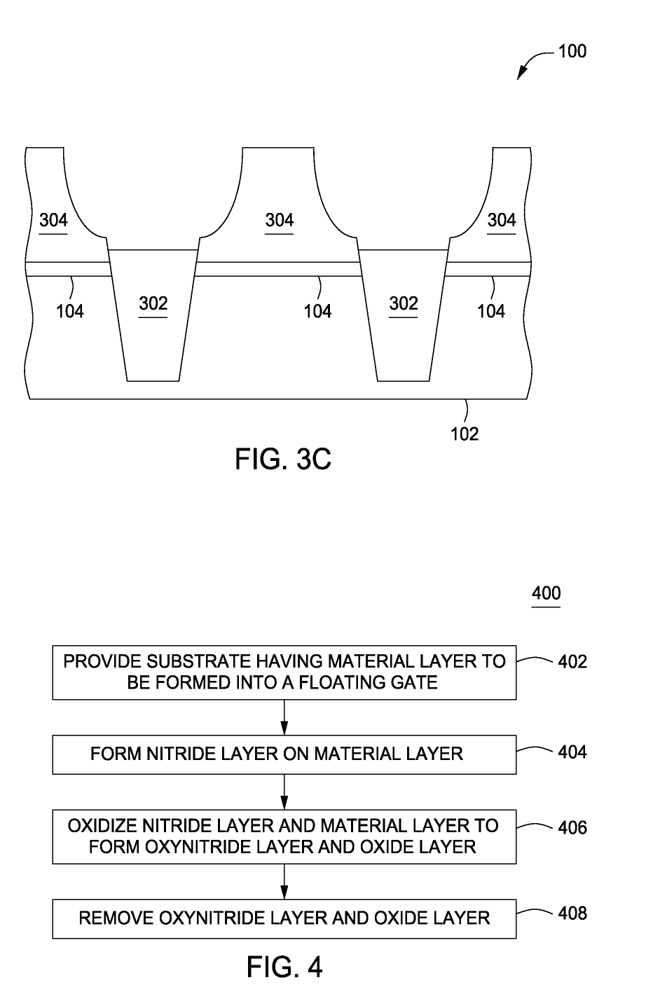

Thus, method 200, which is understood to be performed in a single chamber, begins at 202, where a substrate having a material layer to be formed into a floating gate may be provided. For example, as shown in FIG. 3A, the substrate 102 and material layer 304 may be part of a partially fabricated memory device 300. The memory device 300 may comprise the substrate 102 having the tunnel oxide layer 104 disposed thereon. The material layer 304 may be deposited atop the tunnel oxide layer 104. A shallow trench isolation (STI) region 302 (similar to STI region 108) may be disposed adjacent to the tunnel oxide layer 104 and the material layer 304. Other fabrication steps to provide the substrate and partially fabricated memory device 300 performed prior to beginning the method 200 include deposition of an isolation material, such as SiO₂, in the STI region 302, planarizing the isolation material level with an upper surface of the material layer 304, and etching the isolation material down to a desired level to result in a substrate having the material layer 304 ready to be processed into a floating gate in accordance with the teachings provided herein.

The material layer 304 may comprise a conductive material, such as polysilicon, a metal or the like. The material layer 304 may generally have a slightly trapezoidal or rectangular cross section. The material layer 304 may generally have any suitable starting shape such that when oxidized and/or etched by the methods described herein, the material layer 304 may be formed into a floating gate having an inverted T shape as described above with respect to FIG. 1 (for example, the material layer 304 may be patterned and etched to facilitate forming the STI structures 302, and the resultant profile of the material layer 304 may be the starting point for further processing as disclosed herein).

At 204, the material layer 304 is selectively oxidized to form an oxide layer 306 as shown in FIG. 3B. The oxide layer 306 is formed on the top and sidewalls of the material layer 304, and may comprise a silicon oxide, metal oxide, or the like. In some embodiments, the oxide layer 306 may consume the material layer 304 to a depth of about 3 to about 15 nm, or about 10 nm. The oxide layer 306 may further consume (or in other encroach or displace) a portion of the STI region 302 as shown in FIG. 3B. The oxide layer 306 may be formed using wet or dry oxidation, rapid thermal oxidation (RTO), radical oxidation, plasma oxidation, for example, decoupled plasma oxidation (DPO), or any other oxidation process described herein. In some embodiments, where a low thermal budget and/or reduced diffusion of oxygen are desired, plasma oxidation or radical oxidation may be utilized. A low thermal budget may be required to prevent thickening of the tunnel oxide layer 104 during the oxidation of the material layer 304. As used herein, a low thermal budget means a thermal budget less than a furnace process of tens of minutes at 850 degrees Celsius peak temperature.

Next, at 206, the oxide layer 306 is removed by an etch process, as depicted in FIG. 3C in the same chamber that the oxidation step 204 was performed. The remaining portion of the material layer 304 after oxidation of the material layer 304 and removal of the oxide layer 306 may be generally in the shape of an inverted T, for example, similar to the shape of the floating gate 106 depicted in FIG. 1. The etch process may use chemicals or gases comprising hydrofluoric acid (HF) hydrochloric acid (HCl), or other etch processes disclosed herein, or the like. The etch process may be selective, for example, selectively removing the oxide layer 306. In one embodiment, the etch process is selective to silicon oxide, and removes the oxide layer 306 comprising silicon oxide relative to the material layer comprising polysilicon. The etch process may further remove a portion of the STI region 302 during removal of the oxide layer 306.

Upon completion of the etch process to form a floating gate having an inverted T shape, the method 200 generally ends. Further processing of the memory device may include the deposition of an IPD layer and a control gate layer, similar to those layers described with respect to FIG. 1. In some embodiments, prior to the deposition of an IPD layer, the region between adjacent material layers 304 and above the STI region 302 is filled with a gap fill material, for example, SiO₂ or the same material that comprises the STI region 302. Next, the top of this filled region can be planarized by chemical mechanical planarization (CMP), or any suitable planarization method, to be substantially even with the top of the material layer 304. The gap fill and CMP are followed by an etch of the gap fill material to set a desired penetration depth for the IPD between the adjacent material layers 204, prior to deposition of the IPD layer.

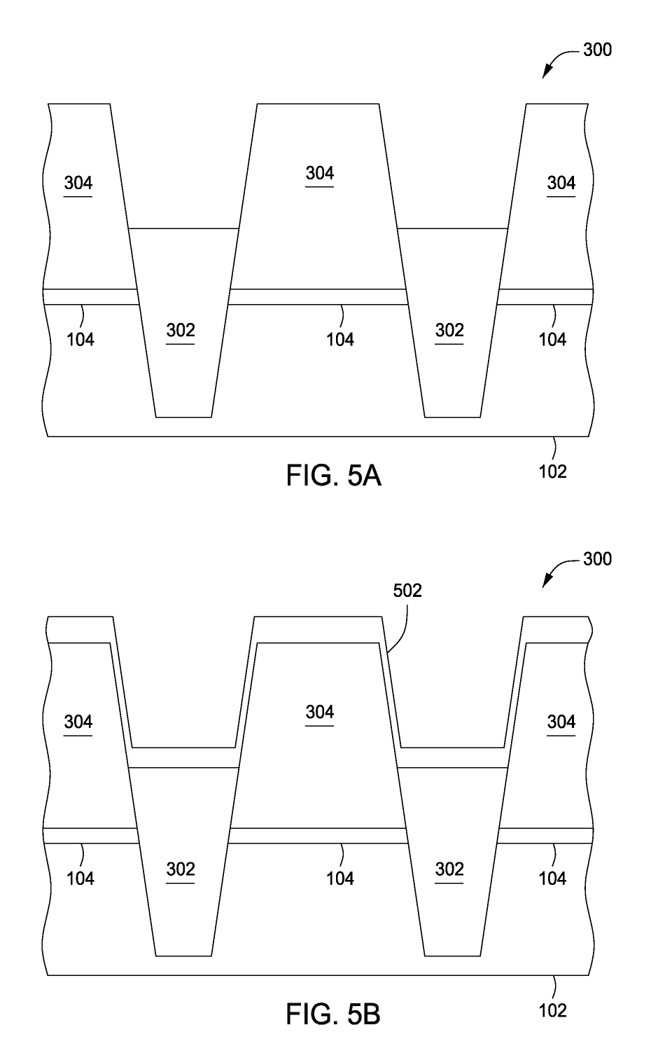

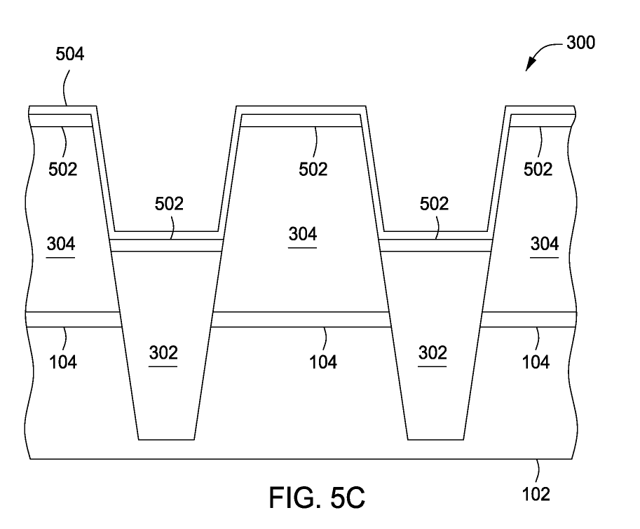

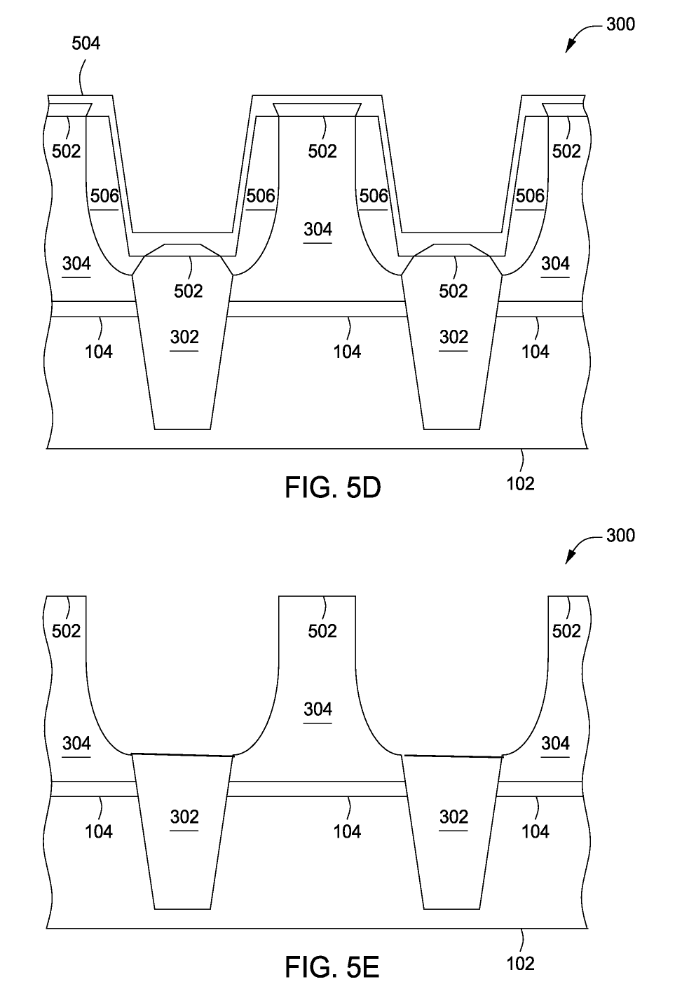

Alternatively, the floating gate having an inverted T shape may be formed using a method 400, as depicted in FIG. 4. The method 400 is illustratively described with reference to FIGS. 5A-E, which depicts stages of fabrication of the memory device 300 in accordance with the embodiments of the method 400. The method 400 includes the deposition of a sacrificial nitride layer, which may be utilized to limit the diffusion of oxygen during an oxidation process used to oxidize the material layer 304. It may be desired to limit oxygen diffusion to prevent undesirable thickening of the tunnel oxide layer 104 and/or to prevent undesirable removal of portions of the tunnel oxide layer 104 and/or the STI region 302 (or the gap fill material) during the oxide layer removal process as described below.

The method 400 generally begins at 402, where the partially fabricated memory device 300 is provided as illustrated in FIG. 5A. The memory device 300 has been described above, and includes the substrate 102 having a tunnel oxide layer 104 disposed thereon and having the material layer 304 disposed above the tunnel oxide layer 104. The memory device 300 further includes the STI layer 302 disposed in the substrate 102 and adjacent to the tunnel oxide layer 104 and material layer 304.

At 404, a nitride layer 502 is formed on the exposed surfaces of the material layer 304 and the STI region 202 as illustrated in FIG. 5C. The nitride layer 502 may be formed by any suitable nitridation process, for example, plasma nitridation or silicon nitride deposition. The nitride layer 502 may comprise silicon nitride (SiN), silicon oxynitride (SiON), or both. The nitride layer 502 may be formed to a greater thickness on the horizontal surfaces of the material layer 304 and STI region 302 as compared to the sidewall of the material layer 304 (for example, by a directional nitridation process). In some embodiments, a ratio of nitride layer thickness on the horizontal surfaces of the material layer 304 and STI region 302 to that on the sidewall of the material layer 304 is about 2:1 to about 10:1. In some embodiments, the nitride layer 502 has a thickness of about 5 to about 10 nm on the horizontal surfaces of the material layer 304 and the STI region 302. In some embodiments, the nitride layer 502 has a thickness of about 1 nm or less on the sidewalls of the material layer 304.

At 406, the nitride layer 502 and the material layer 304 are selectively oxidized to form an oxynitride layer 504 and an oxide layer 506. The oxidation process is performed in the same chamber as nitridation step 504. The oxidation step 506 may include any suitable oxidation process as discussed above with respect to method 200, and may be performed in a single stage process described with respect to FIGS. 5C-D. Initially, as depicted in FIG. 5C, the oxidation process facilitates the formation of an oxynitride layer 504. The oxynitride layer 504 may consume a portion of the nitride layer 502 on the horizontal surface of the material layer 304 and STI region 302, and may consume substantially the entire nitride layer 502 on the sidewall of the material layer 304. The increased thickness of the nitride layer 502 on the horizontal surfaces may limit or prevent oxidation of those underlying surfaces. Upon consumption of the nitride layer 502 on the sidewall of the material layer 304, the oxidation process may consume a portion of the material layer 304. The oxidation of the sidewalls of the material layer may proceed more quickly than on the horizontal surfaces due to the remaining unconsumed nitride layer 502 disposed on those surfaces.

As illustrated in FIG. 5D, the oxidation process proceeds at a faster rate on the sidewalls of the material layer 304 forming an oxide layer 506 by generally consuming the material layer 304 from the sidewall inward. The remaining unconsumed portion of the material layer 304 may generally be in the desired shape of an inverted T. Further, and as illustrated in FIG. 5D the oxidation process continues to consume a portion of remaining nitride layer 502 and a portion of the STI region 302, albeit at a slower rate than the consumption of the material layer 304 at the sidewall.

At 408, the oxynitride layer 504 and the oxide layer 506 may be removed, resulting in a floating gate having an inverted T shape as depicted in FIG. 5E. The layers may be removed by an etch process, for example, a wet or dry chemical etch, reactive ion etch, or the like as discussed above with respect to method 200. The etch process may be selective, for example, selectively removing the oxynitride layer 504 and oxide layer 506. In one embodiment, the etch process is selective to silicon oxide (SiO₂), silicon oxynitride (SiON), and silicon nitride (SiN), and removes the nitride layer 502 comprising SiN, the oxynitride layer 504 comprising SiON, and the oxide layer 506 comprising SiO₂ selective to the material layer 304 comprising polysilicon. The etch process may further selectively remove a portion of the STI region 302 as illustrated in FIG. 5E. In some embodiments, the etch process may be a multi-stage etch process. For example, initially the etch process may be selective to selective to only SiO₂ to remove the oxide layer 506. Next, the etch process may be SiON and SiN to remove the oxynitride layer 504 and the nitride layer 502. Upon completion of the etch process to form a floating gate having an inverted T shape, the memory device 200 may be processed further, for example, by depositing an IPD layer and a control gate layer, similar to those layers described with respect to FIG. 1. As discussed above, a gap fill and CMP of the filled region between adjacent material layers 304, followed by an etch of the filled region may be performed prior to deposition of the IPD layer.

As discussed above, a low thermal budget (e.g. low diffusion of materials such as one or more of dopants, oxygen (O₂) or silicon (Si)) may be desired in some embodiments, for example, to limit thickening of the tunnel oxide layer 104 or the STI region 302. However, if possible to limit such undesirable thickening effects, high thermal budget processes (i.e., high oxygen diffusion) may be utilized. For example, high thermal budget processes (e.g., wet, dry, or RTO) can provide conformal oxidation, faster oxidation rates, thicker oxidation (e.g., about 5 to about 15 nm thickness) and more efficient sidewall oxidation. In addition, high thermal budget oxidation processes provide reduced sensitivity to different crystallographic orientation of the material layer used to form a floating gate, thus advantageously generating a smooth surface during oxidation. Reduced sensitivity to crystallographic orientation may be desired, for example, when a material layer comprising a polycrystalline material is used to form a floating gate. Smooth surfaces advantageously improve reliability in the memory device, for example, by reducing junction resistance, or the like.

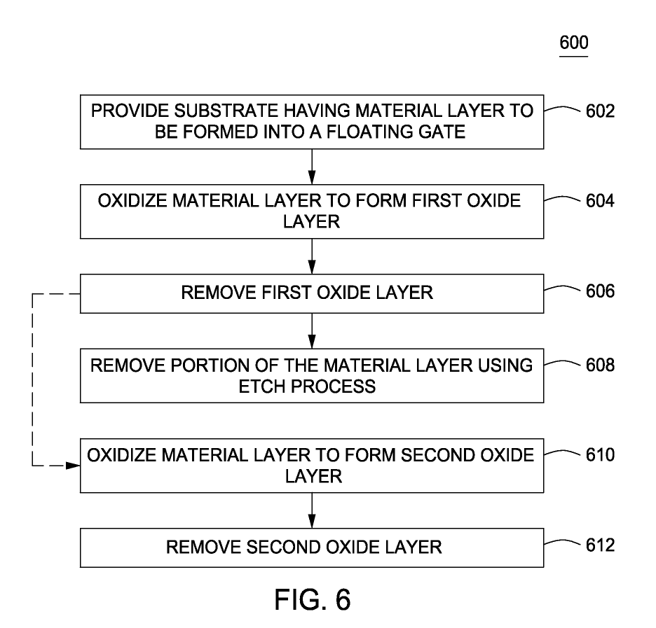

Thus, in some embodiments, such as described below with respect to FIG. 6, a partially fabricated memory device 700 having a material layer 702 may be used to form a floating gate having an inverted T shape. The material layer 702 may be taller, for example, compared to the material layer 304 illustrated in FIGS. 3A and 5A, respectively. In addition, the height of the STI region 302 may be scaled with the height of the material layer 702 (for example, by depositing and etching back a gap fill material, such as SiO₂, as discussed above) to provide an increased distance between exposed surfaces thereof and the tunnel oxide layer, thereby facilitating resistance to oxidation diffusion into the tunnel oxide layer during high thermal budget processes. In some embodiments, a gap between the top of the material layer 702 and the top of the STI region 302 may be substantially equivalent in distance to that of similar structures illustrated in FIGS. 3A and 5A. The increased height of both the material layer 702 and the STI region 302 as compared with similar memory devices in FIGS. 3A and 5A, may advantageously lengthen the distance oxygen atoms have to travel to reach the tunnel oxide layer 104. The increased height of both structures allows for the use of a higher thermal budget oxidation process, while limiting thickening of the tunnel oxide layer 104. Thus, by increasing the height of the STI region 302 in the memory device 700, high thermal budget oxidation processes may advantageously be used to form a floating gate having an inverted T shape. Following the high thermal budget oxidation process and removal of an oxide layer formed thereby, an etch process and/or a more controllable low thermal budget oxidation process may be used to reduce the thickness at the base of the floating gate. Such a combination of a high thermal budget oxidation process with either an etch process or a low thermal budget oxidation process is described below with respect to FIGS. 6-8.

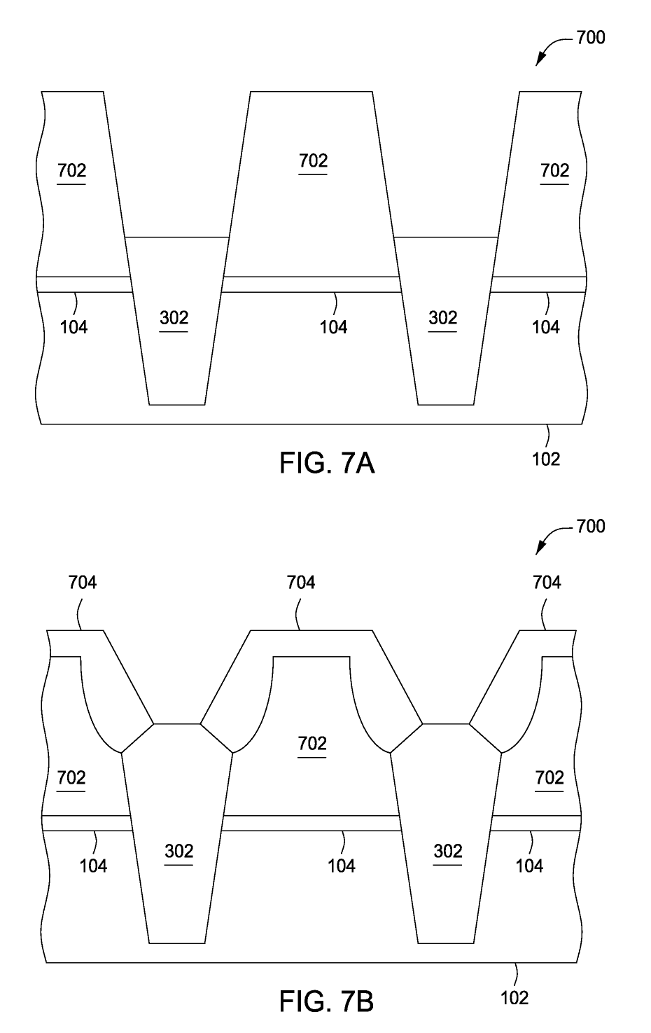

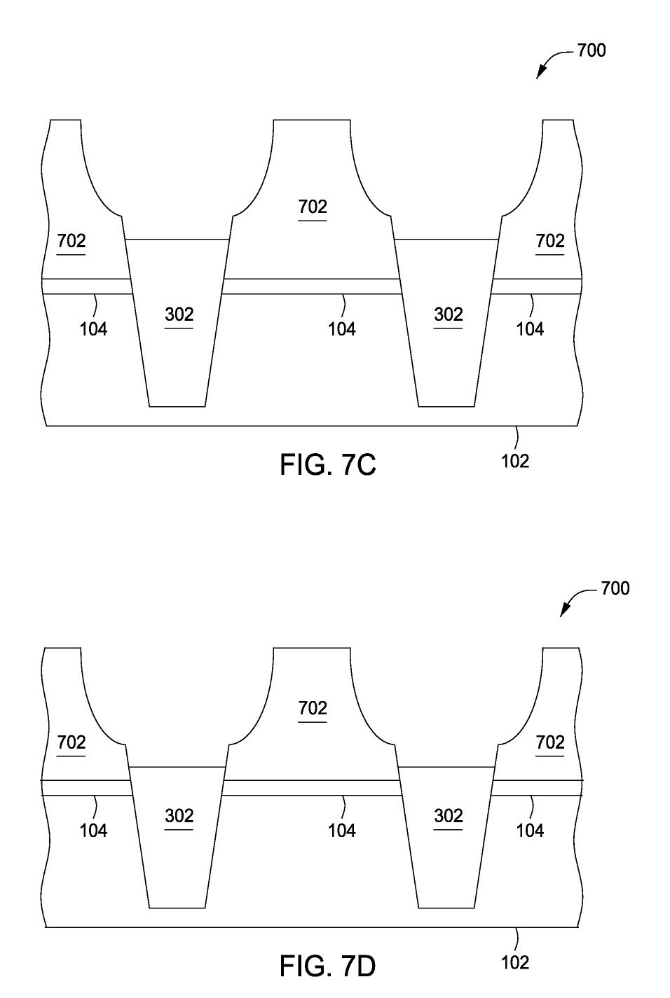

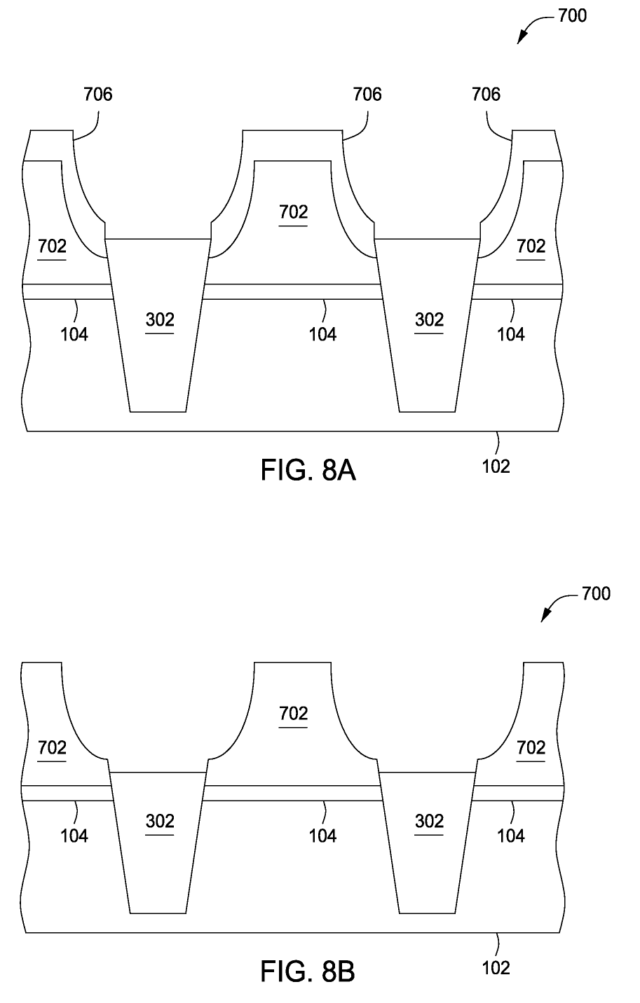

For example, FIG. 6 depicts a method 600 of fabricating semiconductor device having a floating gate in accordance with some embodiments of the present invention. The method 600 is illustratively described with reference to FIGS. 7A-D and FIGS. 8A-B, which depicts stages of fabrication of a memory device 700 in accordance with embodiments of the method 600.

The method 600 generally begins at 602, where a substrate having a material layer to be formed into a floating gate may be provided. For example, as shown in FIG. 7A, the substrate 102 and a material layer 702 may be part of a partially fabricated memory device 700. The memory device 700 may include the substrate 102 having the tunnel oxide layer 104 disposed thereon. The material layer 702 may be deposited atop the tunnel oxide layer 104. Shallow trench isolation (STI) regions 302 may be disposed in the substrate 102, adjacent to the tunnel oxide layer 104 and the material layer 702. The substrate 102, the tunnel oxide layer 104 and the STI regions 302 have been discussed above.

The material layer 702 may comprise a conductive material, such as polysilicon, a metal or the like. The material layer 702 may have a starting shape comprising a substantially rectangular or slightly trapezoidal cross section. The material layer 702 may generally have any suitable starting shape such that when oxidized and/or etched by the methods described herein, the material layer 702 may be formed into a floating gate having an inverted T shape. The material layer 702 may have a height of greater than about 30 nm, or up to about 130 nm. The material layer 702 may have a ratio of height to width of greater than about 2:1.

Next, at 604, the material layer 702 is selectively oxidized to form a first oxide layer 704 as shown in FIG. 7B. The first oxide layer 704 is formed on the top and sidewalls of the material layer 702, and may comprise a silicon oxide, metal oxide, or the like. In some embodiments, the first oxide layer 704 may consume the material layer 702 to a depth of about 5 to about 15 nm, or about 10 nm. The first oxide layer 704 may further thicken a portion of the STI region 302. The formation of the oxide layer may be performed using wet or oxidation, rapid thermal oxidation (RTO), radical oxidation, or plasma oxidation, for example, decoupled plasma oxidation (DPO). In some embodiments, where a low thermal budget and/or reduced diffusion of oxygen are desired, plasma oxidation or radical oxidation may be utilized. A low thermal budget may be required to prevent thickening of the tunnel oxide layer 104 during the oxidation of the material layer 702.

The remaining portion of the material layer 702 after oxidation may be generally in the shape of an inverted T having a greater dimensions than the desired final form (e.g., the height of the base and/or the width of the stem may be greater). At 606, the first oxide layer 704 is removed by an etch process in the same chamber as step 604 resulting in the floating gate having a generally inverted T shape as illustrated by the remaining portion of the material layer 702 depicted in FIG. 7C. The etch process may be a wet or dry etch, or a reactive ion etch. The etch process may use chemicals or gases comprising hydrofluoric acid (HF) hydrochloric acid (HCl), or the like. The etch process may be selective, for example, selectively removing the first oxide layer 704. In one embodiment, the etch process is selective to silicon oxide, and removes the first oxide layer 704 comprising silicon oxide relative to the material layer comprising polysilicon. The etch process may further remove a portion of the STI region 302 during removal of the first oxide layer 704.

At 608, an etch process may be used to remove an additional portion of the remaining material layer 702 to form a floating gate having a desired inverted T shape, as depicted in FIG. 7D. The etch process may include wet or dry etch, reactive ion etch, or the like. In one embodiment, the etch process is a reactive ion etch. The floating gate formed using method 600 may be similar in dimension to the floating gates formed in methods 200 and 400, as discussed above.

Upon etching the material layer 702 to form a floating gate having an inverted T shape and the dimensions discussed above, the method 600 generally ends and further processing to complete the fabrication of the memory device may be performed. Further processing of the memory device 700 may include the deposition of an IPD layer and a control gate layer as discussed above. Optionally, a gap fill and CMP process, followed by an etch back of the filled region to control the desired depth of the IPD layer in the region between adjacent floating gates may be performed prior to the IPD layer deposition, as discussed above.

Alternatively, in some embodiments, after removal of the first oxide layer 704, the method 600 may proceed from in the same chamber 606 to 610, where the material layer may be selectively oxidized to form a second oxide layer 706. The second oxide layer 706 is formed on the top and sidewalls of the remaining portion of the material layer 702 as depicted in FIG. 8A, and may comprise a silicon oxide, metal oxide, or the like. In some embodiments, the second oxide layer 706 may consume the material layer 702 to a depth of about 5 to about 15 nm, or about 10 nm. The formation of the oxide layer may be performed using wet or oxidation, rapid thermal oxidation (RTO), radical oxidation, or plasma oxidation, for example, decoupled plasma oxidation (DPO), and a low thermal budget and/or reduced diffusion of oxygen are desired, plasma oxidation or radical oxidation may be utilized. In some embodiments, low thermal budget directional oxidation (e.g., plasma oxidation) maybe used where the second oxide layer 706 grows at a higher rate on horizontal surfaces of the material layer 702 than on sidewall surfaces.

The remaining portion of the material layer 702 after selective oxidation to form the second oxide layer 706 may be generally in the shape of an invert T. At 612, the second oxide layer 706 is removed by an etch process to complete the formation of a floating gate having an inverted T as illustrated by the remaining portion of the material layer 702 depicted in FIG. 8B. The etch process may be a dry etch, or a reactive ion etch. The etch process may use chemicals or gases comprising hydrofluoric acid (HF) hydrochloric acid (HCl), or the like. The etch process may be selective, for example, selective for removing the second oxide layer 706. In one embodiment, the etch process is selective to silicon oxide, and removes the second oxide layer 706 comprising silicon oxide relative to the material layer 702 comprising polysilicon. The etch process may further remove a portion of the STI region 302 during removal of second oxide layer 706.

Upon etching the remaining portion of material layer 702 to remove the second oxide layer 706 and form a floating gate having a desired inverted T shape the method 600 generally ends. The floating gate formed by the method 600 may have equivalent dimensions to those discussed above at 608. Further processing of the memory device 700 may include the deposition of an IPD layer and a control gate layer as discussed above.

Although high thermal budget processes may be advantageous for some embodiments, as discussed above, the oxidation rate of a material layer, such as material layer 702 above, tends to saturate as higher thermal budgets are applied. For example, this can result in an inability to shape the material layer 702 into a shape having the desired dimensions, thickening of the tunnel oxide layer 104, or both. Further, while the oxidation rate can saturate using any of a broad range of temperatures, for example between about 30 to about 1100 degrees Celsius, the initial oxidation rate is high even at lower temperatures in the range, such as 30 degrees Celsius. This temperature range is valid for all oxidation processes disclosed herein. In addition, plasma oxidation or photochemical (UV or ozone) or dry/wet chemical (e.g. ozone, nitric acid, hydrogen peroxide) based oxidation can occur at room temperature or below. Accordingly, the inventors have developed a method of shaping a material layer, such as material layer 702, which advantageously utilizes a high initial oxidation rate as discussed below.

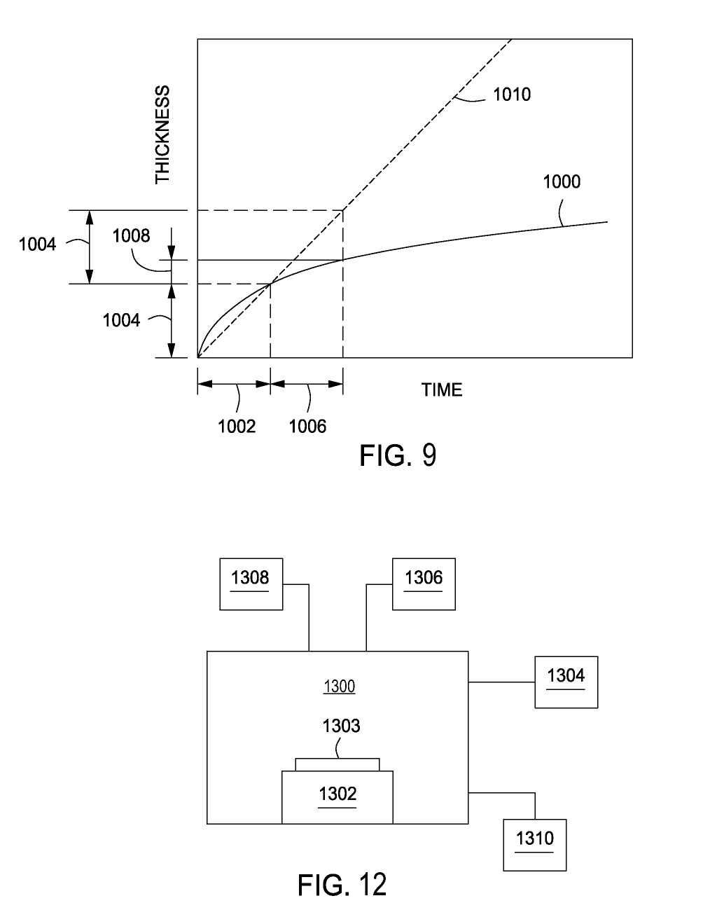

A schematic illustration of saturation in the oxidation rate at high thermal budgets is shown in FIG. 9, which generally depicts a plot of an oxide layer thickness as a function of time. An isotherm 1000 is representative of an oxidation process where an oxide layer is continuously grown at a desired arbitrary temperature. Initially, over a first period 1002 of time in the isotherm 1000, the oxidation rate is high as illustrated by a first oxide layer thickness 1004 grown over the first period 1002. As time (and thermal budget) increases, the oxidation rate begins to saturate. For example, over a second period 1006 equivalent in duration to, and immediately following the first period 1002, a second oxide layer thickness 1008 grown during the second period 1006 is less than the first oxide layer thickness 1004 owing to a slower oxidation rate during the second period 1006. The inventors have further discovered that the general shape of the isotherm 1000 is followed at various temperatures.

Accordingly, to shape the material layer 702 to a desired shape, a high thermal budget may be required to achieve the necessary oxide layer thickness to form the desired dimensions of the floating gate. Unfortunately, during fabrication of some structures, the application of a high thermal budget oxidation process can undesirably cause oxygen (O₂) to diffuse into exposed oxide layers (such as the tunnel oxide layer 104), causing the oxide layer to undesirably thicken.

As such, in some embodiments of the method 600, a repetitive oxidation and etch processes may advantageously utilize the high initial oxidation rate applied during the first period 1002, as described in FIG. 9 above. For example, in some embodiments, at 604, a surface of a material layer (e.g., material layer 702) may be oxidized to form an oxide layer (e.g., first oxide layer 704) at an initial oxidation rate. The material layer 702 may be oxidized for a first period (e.g., first period 1002) of time where the initial oxidation rate is relatively high. After the oxidation rate decreases to a predetermined amount, for example during the second period 1006, the oxidation process is terminated. In some embodiments, the formation of the first oxide layer 704 may be terminated when the oxidation rate is about 90% or below, or about 75% or below, of the initial oxidation rate. In some embodiments, the formation of the first oxide layer 704 may be terminated when the oxidation rate is between about 0% to about 90%, or about 75%, of the initial rate.

Once the oxidation process has been terminated, at 606, at least some of the first oxide layer 704 is removed by an etching process (as discussed above and as illustrated in FIG. 7C). As illustrated in FIG. 7C, once the first oxide layer 704 has been removed, the material layer 702 may be at least partially formed into the desired shape as discussed above. The removal of the first oxide layer 704 provides a fresh exposed surface of the material layer 702 which can further be oxidized until the desired shape of the material layer is formed. In some embodiments, the etch process may be a two-stage condensation and sublimation etch process, as described above. In some embodiments, the etch process may be terminated when the etch rate falls to about 0% to about 75%, or to about 90% of the initial etch rate. The decrease in etch rate may be due to material contrast (e.g., Si to SiO₂ selectivity) or diffusion related saturation (e.g., on a homogeneous SiO₂ layer). The time dependency of the etch rate during the etch process may provide a method of additional and independent control of the material removal during the sacrificial oxidation. This provides the capability of layer-by-layer removal on a heterogeneous surface (Si/SiO₂) as exemplified in Floating Gate formation structures. This may be advantageously used when removing oxidized materials from a heterogeneous substrate to avoid non-uniform material removal.

For example, at 610, the exposed surface of the partially shaped material layer 702 is again oxidized to form another oxide layer (e.g., second oxide layer 706). The oxidation process proceeds at an initial oxidation rate that can be substantially equivalent to the initial oxidation rate discussed above for the first oxidation layer 704 due to the removal of the first oxide layer 704. As above, after the oxidation rate decreases to a predetermined amount, for example during the second period 1006, the oxidation process is terminated. The desired point of termination of the process can be any time similar to discussed above. Oxidation to form the second oxide layer 706 is illustrated in FIG. 8A.

Once the repeated oxidation process has been terminated, at 612, at least some of the second oxide layer 706 is removed by an etching process (as discussed above and as illustrated in FIG. 8B). As illustrated in FIG. 8B, once the second oxide layer 706 has been removed, the material layer 702 may be formed into the desired shape, as discussed above. Alternatively, the removal of the second oxide layer 706 again provides a fresh exposed surface of the material layer 702 which can further be oxidized until the desired shape of the material layer is formed. As such, although disclosed as repeating oxidation and etch process just once, the repetition of these processes may continue as many times as necessary to form the desired shaped of the material layer (i.e., the process can be repeated one or more times).

Oxidizing in a cyclical process of oxidation and removal of an oxide layer makes it possible to form more oxide at the same thermal budget as compared to an oxidation process performed continuously. Performing the cyclical process of oxidation and removal of an oxide layer in a single chamber can greatly increase process throughput. For example, as shown in FIG. 9, a continuously applied oxidation process such as illustrated by the isotherm 1000 applied over the first and second periods 1002, 1006 will form an oxide layer having a thickness which is the sum of the first and second thicknesses 1004, 1008. However, a cyclical oxidation and removal process, for example forming a first oxide layer (e.g., first oxide layer 704) over the first period 1002, removing the first oxide layer, and oxidizing the material layer to form a second oxide layer (e.g., second oxide layer 706) over the second period 1006 can result in a total oxide thickness (e.g., summation of the thicknesses of the first and second oxide layer 704, 706) which is twice the first thickness 1004 using the same thermal budget as a continuous oxidation process.

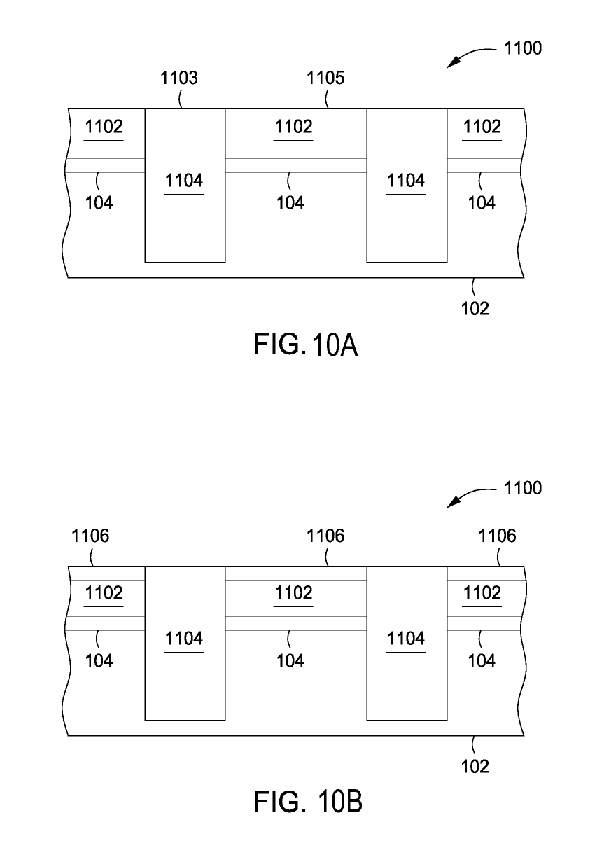

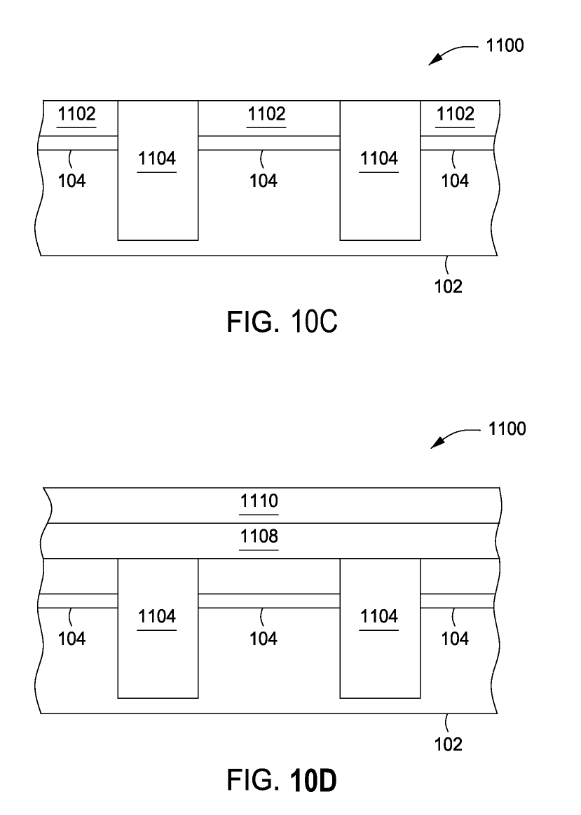

An isotherm 1010 which schematically illustrates the cyclical oxidation and removal process is shown in FIG. 9. As illustrated, the isotherm 1010 deviates substantially from the isotherm 1000 (representative of a continuous oxidation process) after the first period 1002. The isotherm 1010 is depicted as linear in FIG. 10, however, that is merely illustrative. The isotherm 1010 can have any shape based on how the cyclical oxidation and removal process is applied. For example, if each repeat oxidation process is for the same period of time (e.g., the first period 1002), then the isotherm 1010 can have a shape which repeats the shape of the isotherm 1010 during the first period 1002 at each successive step. Alternatively, a successive step in the cyclical oxidation and removal process may be applied for a different duration than the first period (not shown), and the shape of the isotherm 1010 can vary accordingly. However, the total oxide formed during the cyclical oxidation and removal process will be greater than that formed by a continuous oxidation process (e.g., isotherm 1000) using the same thermal budget. In some embodiments, the total oxide formed during the cyclical oxidation and removal process may be up to about 3 times greater than that formed by a continuously oxidation process using the same thermal budget.

pow The above cyclical oxidation and removal process can be advantageously used to form other structures, including structures having sub-lithographic dimensions. Such structures may include, for example, an ultra thin floating gate, the fin of a finFET device, a patterned hard mask, or the like.

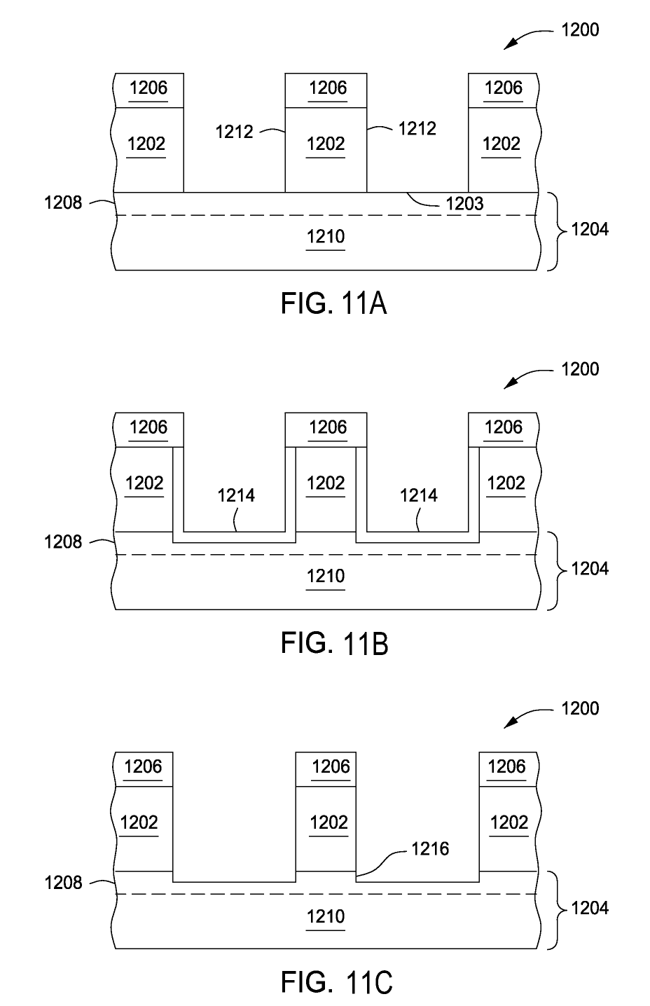

For example, in some embodiments, the cyclical oxidation and removal process can be utilized to form an ultra thin floating gate as illustrated in FIGS. 11A-D. FIGS. 11A-D depict the stages of fabrication of a floating gate 1102 in accordance with some embodiments of the present invention. The method begins as shown in FIG. 11A by providing a partially fabricated memory device 1100. The memory device 1100 is similar in structure and composition to the memory device 100 discussed above. The memory structure 1100 includes the substrate 102 having the tunnel oxide layer 104 disposed thereon. A material layer 1102, similar in composition to any material layer discussed above, is disposed atop the tunnel oxide layer 104. An STI region 1104, similar in composition to the STI regions discussed above, is disposed on either side of the material layer 1102 and adjacent thereto. The STI regions 1104 separate the individual memory cells of the device 1100. Generally, a top surface 1103 of the STI region 1104 and a top surface 1105 of the material layer 1102 are substantially planar.

Next, the cyclical oxidation and removal process discussed above can be utilized in the same chamber to thin the material layer 1102 to a desired shape (e.g., thickness). The top surface 1105 of the material layer 1102 may be oxidized as discussed above to form an oxide layer 1106 at an initial oxidation rate as illustrated in FIG. 11B. The oxidation process is terminated when the oxidation rate falls below a specified percentage of the initial rate as discussed above. The oxide layer 1106 (along with a portion of the oxide in the STI region 1104) is then removed by an etch process as illustrated in FIG. 11C. The oxidation and removal processes can be repeated until the material layer 1102 is thinned to a desired shape to form a floating gate.

In some embodiments, the desired shape of the material layer 1102 may have a first width at the bottom of the material layer 1102 that is substantially equivalent to a second width at the top of the material layer 1102. Further, the desired shape may include a final thickness of the material layer 1102, for example, of less than about 5 nanometers (although other thicknesses are contemplated, for example, about 1 to about 20 nm, or about 1 to about 10 nm). The cyclical oxidation and removal process advantageously thins the material layer 1102 into the desired shape of a floating gate without unwanted oxidative thickening of the underlying tunnel oxide layer 104. The inventors have discovered that the oxide present in the

STI region 1104 acts as a barrier to prevent the oxidation process from reaching the tunnel oxide layer 104. As illustrated in FIG. 10D, an IPD layer 1108 and conductive layer 1110 may be deposited atop the thinned material layer 1102 to form a completed memory device 1100. The IPD layer 1108 and the control gate layer 1100 each may comprise any suitable material or combination of materials for an IPD layer and control gate layer as discussed above.

In some embodiments, the cyclical oxidation and removal process can be utilized to form structures to critical dimensions that are smaller than those dimensions accessible by lithographic techniques. For example, FIGS. 11A-C depicts the stages of utilizing the cyclical oxidation and removal process to trim a lithographically patterned structure 1200 to a sub-lithographic critical dimension. The structure 1200 may be, for example, a partially fabricated logic device, such as a FinFET, or a partially fabricated hard mask structure.

The structure 1200 includes a material layer 1202 deposited atop a substrate 1204. The material layer 1202 may be deposited as illustrated in FIG. 11 A such that one or more portions of the upper surface 1203 of the substrate 1204 remain exposed. A mask layer 1206 may be deposited atop the material layer 1202. The mask layer 1206, for example, may have been used to pattern the material layer 1202 to a lithographically defined critical dimension.

The substrate 1204 may be any suitable substrate as discussed above. In some embodiments, for example in the fabrication of a logic device the substrate 1204 may comprise silicon (Si) or silicon dioxide (SiO₂). In some embodiments, for example in the fabrication of a hard mask structure, the substrate 1204 may comprise a layer 1208 (illustrated by dotted line in FIGS. 11A-C) deposited atop a non-silicon layer 1210 to be patterned by the hard mask. The layer 1208 may function as a second hard mask when etching the non-Si layer 1210. The layer 1208 may comprise one or more of silicon dioxide (SiO₂), silicon nitride (SiN), aluminum oxide (Al₂O₃) or other materials deposited at low temperatures, or a buried oxide formed during silicon on insulator (SOI) fabrication. The non-silicon layer 1210 may comprise metals, such as one or more of tungsten (W), titanium nitride (TiN) or the like, and/or a dielectric material, such as SiO₂, high-k binary oxides, ternary oxides, phase-change materials (such as nickel oxide, germanium antimony telluride, or the like) and/or alternate channel materials in Group IV (e.g., Ge, SiGe), and/or III-V materials (e.g., GaAs, GaN, InP etc) and/or organics (e.g., pentacene, fullerenes, or the like). Some materials may degrade at temperatures above about 100 degrees Celsius, but can benefit from sub-lithographic patterning made accessible by the inventive methods to enhance device performance.

The mask layer 1206 may be any suitable mask layer such as a hard mask 5or photoresist layer. The mask layer 1206 may comprise at least one of SiO₂, SiN, silicides, such as titanium silicide (TiSi), nickel silicide (NiSi) or the like, or silicates, such as aluminum silicate (AlSiO), zirconium silicate (ZrSiO), hafnium silicate (HfSiO), or the like.

The cyclical oxidation and removal process discussed above can be applied to the existing structure 1200 to trim the lithographically patterned material layer 1202 to a sub lithographic critical dimension. As illustrated in FIG. 11A, a side wall 1212 of the material layer 1202 and, in some embodiments the exposed upper surface 1203 of the substrate 1204 may be oxidized to form an oxide layer 1214 at an initial oxidation rate as discussed above. The oxidation process may be terminated after a first period of time when the initial oxidation rate falls below a fraction of the initial rate as discussed above.

The oxide layer 1214 is removed, as shown in FIG. 11C, using an etch process, which may be any suitable etch process, as discussed above, performed in the same chamber as the oxidation process. The oxidation and removal processes may be repeated as necessary to form the material layer 1202 to a desired shape, for example, having a desired sub-lithographic dimension. In some embodiments where the substrate 1204 (or the oxide layer 1208) is at least partially consumed by the oxidation and/or etch processes, upon completion of the cyclical oxidation and etch process, the material layer 1202 may be disposed on a raised portion 1216 of the substrate 1204 formed by the cyclical process. The raised portion 1216 may have a width that is substantially equivalent to a first width proximate the bottom of the material layer 1202 and a second width proximate the top of the material layer 1202. In some embodiments, the first width and second width of the trimmed material layer 1202 may be between about 1 to about 30 nanometers. In some embodiments, the trimmed material layer 1202 (e.g., the desired shape of the material layer) has an aspect ratio of between about 0.5 to about 20. In some embodiments, the height of the trimmed material layer 1202 is between about 1 to about 30 nanometers. Alternatively, in some embodiments, the substrate may substantially not be consumed by the cyclic process and the raised portion 1216 may not be present. For example, the raised portion maybe avoided if the etch process is selective to the material of the layer 1208, e.g., a layer 1208 comprising SiN may not be etched while etching SiO₂ in some embodiments.

The structure 1200 after trimming the material layer 1202 using the cyclical oxidation and removal process may be further processed. For example, the material layer 1202 may be utilized as a fin in a FinFET device and a gate layer and source/drain regions may be deposited. Alternatively, the trimmed material layer 1202 may itself be utilized to define the critical dimension of a hard mask to be formed from the substrate 1204. Further, the inventive methods may be advantageously utilized for the reduction of line-edge roughness and surface roughness created by lithography and fin etch. The reduction of roughness and variation on FinFET channel shape and sidewall surface may improve device and system performance by reducing noise and variability.

It is further contemplated that parts and/or the whole of the individual methods described above may be used interchangeably where appropriate to form a memory device having a floating gate with an inverted T shape. For example, a nitride layer (as discussed with respect to FIG. 4) may be deposited atop the material layer 702 of the partially fabricated memory device 700 (as discussed with respect to FIG. 6) to further limit thickening of the tunnel oxide layer. Other combinations and variations of the methods disclosed herein are similarly within the scope of the present invention.

The methods described herein, for example, such as oxidation and etch processes are performed in a single substrate processing chamber configured to provide the respective process gases, plasmas, and the like, necessary to perform the processes discussed above.

Thus, the inventive method is performed in a single reactor or chamber configured to perform oxidation, etch and, optionally, nitridation processes. The process chamber may be configured to perform an oxidation process including one or more of ultraviolet (UV)-, ozone-, thermal-, plasma-based oxidation, or other radical based oxidation schemes (e.g., hot wire). As such, a gas source may be coupled to the chamber to provide one or more oxygen containing gases for the oxidation process. The process chamber may further be configured to perform an etch process including one or more of plasma etching, or a two-stage etch including condensation and sublimation, as discussed above. The two-stage etch process can be activated with a plasma, or may be heat activated with no plasma provided. The process chamber is further configured with a thermal control system for rapidly controlling the temperature of the substrate to facilitate the two-stage etch process. For example, the process chamber may include a cyclical heating (and cooling) capability for cyclically heating and cooling the substrate. Such heating capability may include flash energy based systems (such as lamps, lasers, or the like), heat sources that provide a large thermal gradient between at least two predetermined substrate processing zones in the chamber (such as suitable to selectively maintain low substrate temperature suitable for condensation and high substrate temperature suitable for sublimation by positioning the substrate in the respective processing zone), or via the use of a combination of a remote plasma source for remote plasma activation of etching gases and a direct plasma source to provide plasma induced heating. The substrate support may be movable to support the substrate in the predetermined processing zones and may further include lift pins or other substrate lifting mechanisms to selectively raise the substrate from the support surface during heating portions of the process and return the substrate to the substrate support surface during cooling portions of the process. The substrate support may also have a cooling (or temperature control) system to maintain the substrate support at a predetermined temperature (such as proximate a condensation temperature for the etch process). For example, in some embodiments, the thermal control system is suitable to rapidly (e.g., in less than about 1 second, or up to about 10 seconds, or up to about 100 seconds) alter the substrate temperature from about 30 degrees Celsius (to facilitate condensation) to at least about 100 degrees Celsius (to facilitate sublimation).

For example, a schematic of a process chamber 1300 having such a configuration is illustrated in FIG. 12. The process chamber 1300 includes a substrate support 1302 disposed therein for supporting a substrate 1303 thereon. A gas source 1304 is coupled to the chamber 1300 to provide oxygen-containing gases, etching gases, and optionally inert gases and/or nitrogen-containing gases (for example, any of the gases discussed above). A plasma source 1306 may be coupled to the process chamber to provide energy to the gases provided by the gas source to form at least one of an oxidizing plasma or an etching plasma, and, optionally, a nitridizing plasma. A heating source 1308 is coupled to the process chamber to selectively heat the substrate, and, optionally, to provide energy to gases of the gas source to form at least one of an oxidizing or an etching chemistry. A controller 1310 is coupled to the process chamber 1300 for controlling the operation and components thereof. The gas source 1304 may be any suitable gas source, such as a gas panel having multiple gas sources or the like. The gas source 1304 is minimally configured to provide an oxygen-containing gas and an etching gas to respectively form one or more of, an oxidizing plasma, an etching plasma, an oxidizing chemistry, or a etching chemistry. Optionally, the gas source 1304 may also provide one or more inert gases and/or a nitrogen-containing gas to form a nitridizing plasma.

The plasma source 1306 may be any suitable plasma source or plurality of plasma sources, such as a remote plasma source, inductively coupled source, capacitively coupled source, a first source coupled to an overhead electrode (not shown) and a second source (not shown) coupled to the substrate support, or any other plasma source configurations to form a plasma. In some embodiments, the plasma source 1306 is configured to provide energy to the gases of the gas source 1304 to form the oxidizing plasma, the etching plasma and, optionally, the nitridizing plasma. In some embodiments, the plasma source can supply heat to the wafer for sublimation of reaction byproducts during etching.

The heating source 1308 may be any suitable heating source to heat the substrate and/or to form an oxidizing or etching chemistry from a gas provided by the gas source 1304. For example, the heating source may include one or more lamps configured to heat the substrate or gases provided by the gas source. Alternatively or in combination, the heating source may include a heater, such as a resistive heater or the like, which may for example be disposed in the substrate support 1302 or a gas showerhead for providing the process gases to the process chamber.

In operation, the system controller 1310 enables data collection and feedback from the respective systems such as gas source 1304, plasma source 1306, and heating source 1308 to optimize performance of the tool 1300. The system controller 1310 generally includes a Central Processing Unit (CPU), a memory, and a support circuit. The CPU may be one of any form of a general purpose computer processor that can be used in an industrial setting. The support circuit is conventionally coupled to the CPU and may comprise a cache, clock circuits, input/output subsystems, power supplies, and the like. Software routines, such as one for performing a method of forming an floating gate as described above, when executed by the CPU, transform the CPU into a specific purpose computer (controller) 1310. The software routines may also be stored and/or executed by a second controller (not shown) that is located remotely from the tool 1300. Specific single chamber apparatus for performing processes described above in accordance with one or more embodiments will now be described.

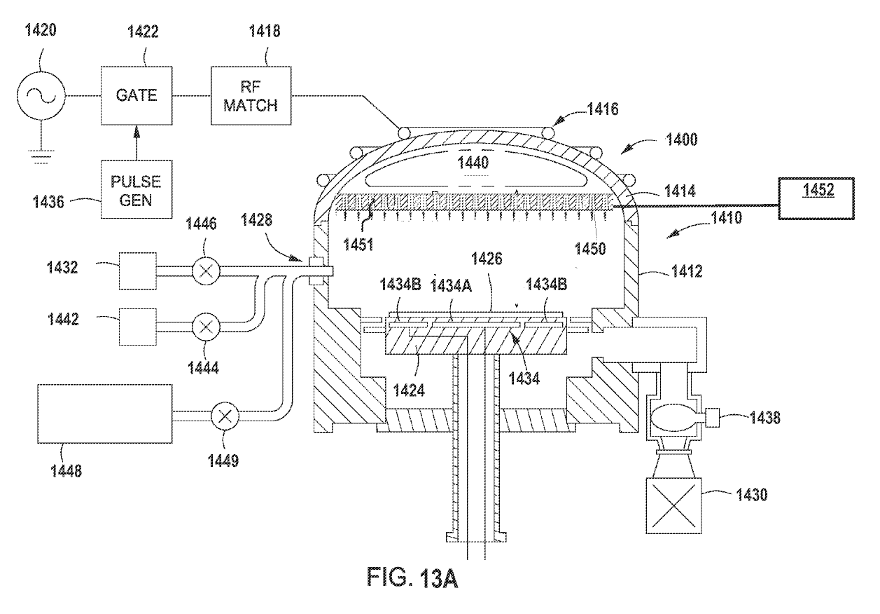

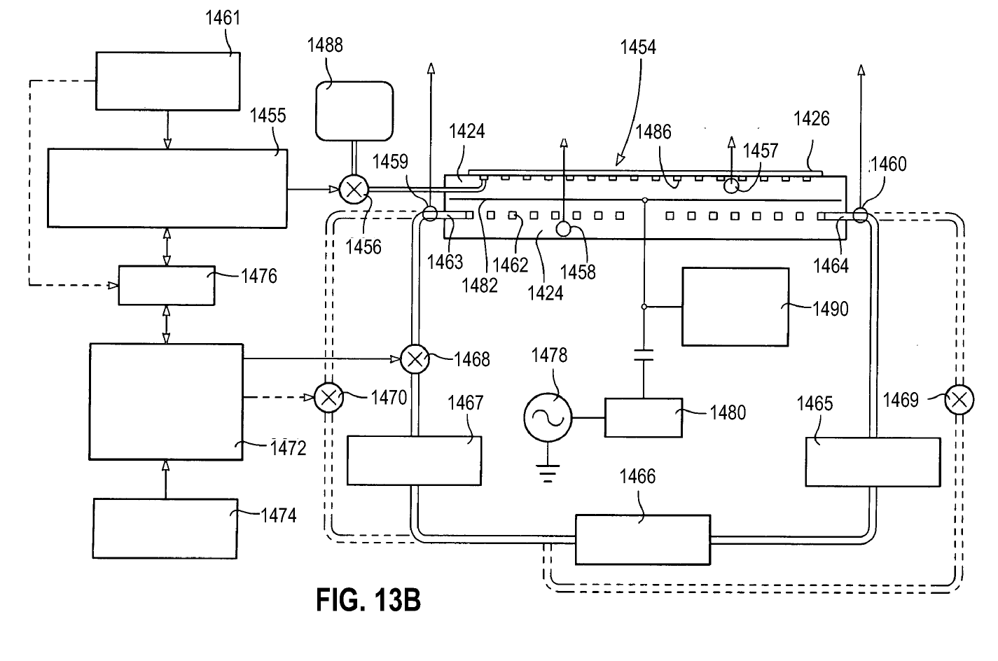

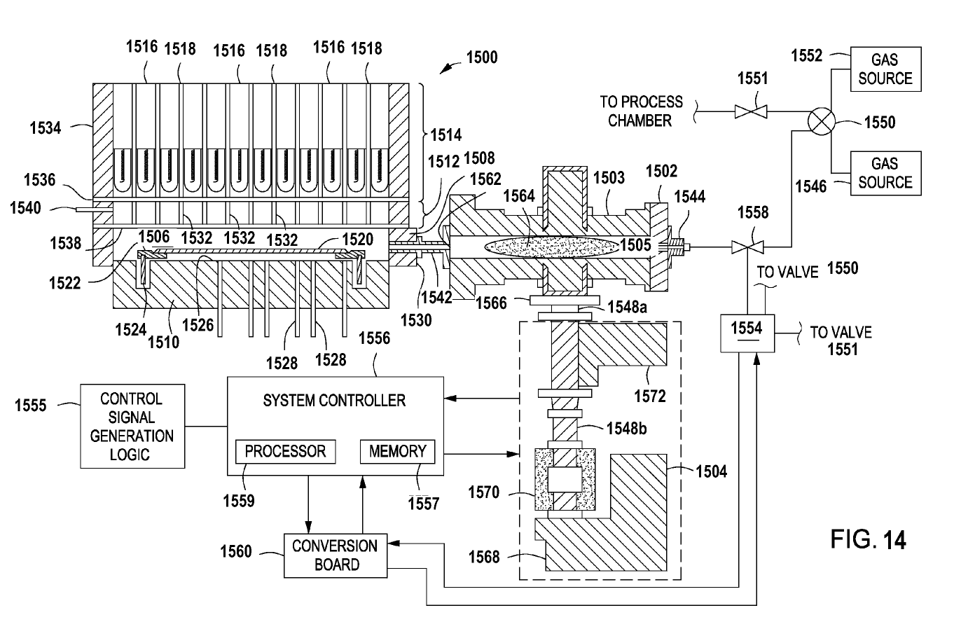

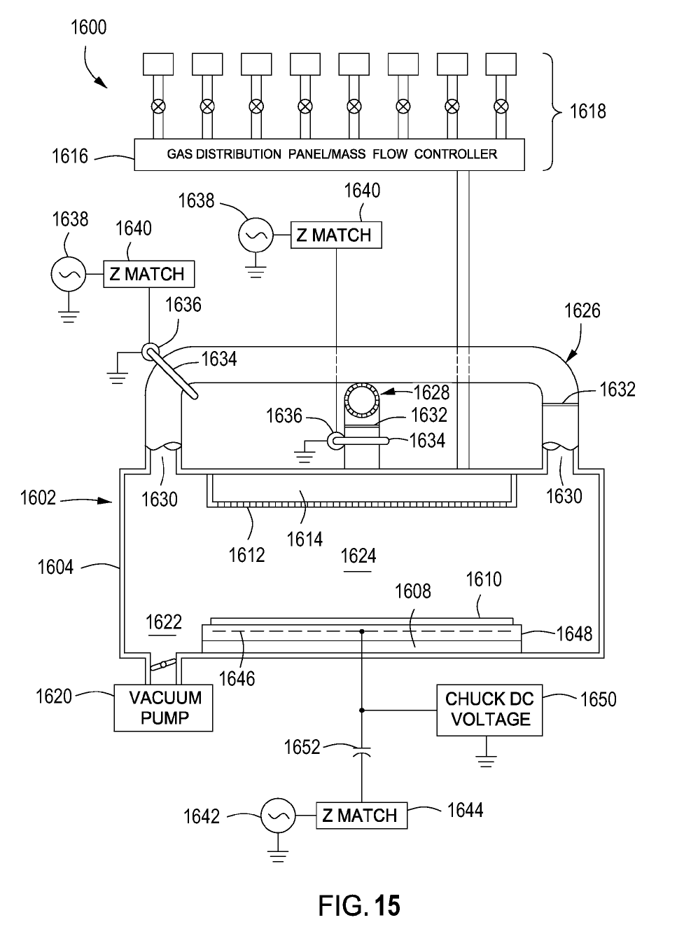

FIGS. 13-15 describe embodiments of modified plasma processing chambers. Embodiments of the present invention may be carried out in suitably equipped plasma reactors, such as Decoupled Plasma Oxidation (DPO) reactors available from Applied Materials, Inc., of Santa Clara, Calif., or elsewhere, and described below with reference to FIG. 13. Other suitable plasma reactors may also be utilized including Remote Plasma Oxidation (RPO) reactors, or toroidal source plasma immersion ion implantation reactor, such as P3I available from Applied Materials, Inc. which are described below with reference to FIGS. 14 and 15, respectively. For example, FIG. 13 depicts an illustrative plasma reactor 1400 suitable for carrying out a cyclical oxide formation and removal processes in accordance with embodiments of the present invention. The reactor 1400 may provide a low ion energy plasma via an inductively coupled plasma source power applicator driven by a pulsed or continuous wave (CW) RF power generator. The reactor includes a chamber 1410 having a cylindrical side wall 1412 and a ceiling 1414 which may be either dome-shaped (as shown in the drawing), flat, or other geometry. The plasma source power applicator comprises a coil antenna 1416 disposed over the ceiling 1414 and coupled through an impedance match network 1418 to an RF power source consisting of an RF power generator 1420 and a gate 1422 at the output of the generator 1420 controlled by a pulse signal having a selected duty cycle. The RF power generator 1420 is configured to provide power between about 50 watts to about 2500 watts. It is contemplated that other low ion energy producing plasma source power applicators may be utilized as well, such as remote RF or microwave plasma sources. Alternatively, the power generator can be a pulsed DC generator.

The reactor 1400 further includes a substrate support pedestal 1424, such as an electrostatic chuck or other suitable substrate support, for holding a substrate 1426, for example a 200 or 300 mm semiconductor wafer or the like. The substrate support pedestal 1424 typically includes a heating apparatus, such as a heater 1434 beneath the top surface of the substrate support pedestal 1424. The heater 1434 may be a single or multiple zone heater, such as a dual radial zone heater having radially inner and outer heating elements 1434a, 1434b, as depicted in FIG. 13.

The reactor 1400 further includes a gas injection system 1428 and a vacuum pump 1430 coupled to the interior of the chamber. The gas injection system 1428 is supplied to one or more process gas sources, for example, oxidizing gas container(s) 1432 for supplying oxidizing gases including O₂, N₂O, NO, NO₂, H₂O, H₂, and H₂O₂, reducing gas container(s) 1442 for supplying reducing gases such as hydrogen, etching gas container(s) 1448 for supplying etching gases such as CF₄, CHF₃, SF₆, NH₃, NF₃, He, Ar, etc, or other process gas source as required for a particular application, for example, gases such as He, Ar or nitridizing gases such as N₂. Flow control valves 1446, 1444, and 1449 respectively coupled to the gas sources (e.g., the oxidizing gas container(s) 1432, the reducing gas container(s) 1442, etching gas containers 1448, and the like) may be utilized to selectively provide process gases or process gas mixtures to the interior of the chamber during processing. Other gas sources (not shown) for providing additional gases, such as inert gases (helium, argon, or the like), gaseous mixtures, or the like, may also be provided. The chamber pressure may be controlled by a throttle valve 1438 of the vacuum pump 1430.

The duty cycle of the pulsed RF power output at the gate 1422 may be controlled by controlling the duty cycle of a pulse generator 1436 whose output is coupled to the gate 1422. Plasma is generated in an ion generation region 1440 corresponding to a volume under the ceiling 1414 surrounded by the coil antenna 1416. As the plasma is formed in an upper region of the chamber 1410 at a distance from the substrate, the plasma is referred to as a quasi-remote plasma (e.g., the plasma has benefits of remote plasma formation, but is formed within same process chamber 1410 as the substrate 1426.) Alternatively, a remote plasma may be utilized, in which case the ion generation region 1440 may be disposed outside of the chamber 1410.

In operation, the plasma reactor 1400 may be employed to carry out oxidation processes in accordance with embodiments of the present invention to oxide layers described above. For example, a plasma may be generated from the process gases within the plasma process chamber 1400 to form an oxide layer. The plasma is formed in the ion generation region 1440 of the chamber 1410 via inductive coupling of RF energy from the coil antenna 1416 disposed over the ceiling 1414, providing a low ion energy (e.g., less than about 5 eV for pulsed plasmas and less than 15 eV for CW plasmas).

In some embodiments, about 25 to 5000 watts of power may be provided to the coil antenna 1416 at a suitable frequency to form a plasma (for example, in the MHz or GHz range, or about 13.56 MHz or greater). The power may be provided in a continuous wave or pulsed mode with duty cycles of between about 2 to 70 percent.

For example, in some embodiments, the plasma may be generated during successive “on” times, and ion energy of the plasma allowed to decay during successive “off” intervals. The “off” intervals separate successive “on” intervals and the “on” and “off” intervals define a controllable duty cycle. The duty cycle limits kinetic ion energy at the surface of the substrate below a pre-determined threshold energy. In some embodiments, the pre-determined threshold energy is at or below about 5 eV.

For example, during the “on” time of the pulsed RF power, the plasma energy increases and during the “off” time it decreases. During the short “on” time, the plasma is generated in the ion generation region 1440 loosely corresponding to the volume enclosed by the coil antenna 1416. The ion generation region 1440 is elevated a significant distance L_{D} above the substrate 1426. Plasma generated in the ion generation region 1440 near the ceiling 1414 during the “on” time drifts at an average velocity V_{D} toward the substrate 1426 during the “off” time. During each “off” time, the fastest electrons diffuse to the chamber walls, allowing the plasma to cool. The most energetic electrons diffuse to the chamber walls at a much faster velocity than the plasma ion drift velocity V_{D}. Therefore, during the “off” time, the plasma ion energy decreases significantly before the ions reach the substrate 1426. During the next “on” time, more plasma is produced in the ion generation region 1440, and the entire cycle repeats itself. As a result, the energy of the plasma ions reaching the substrate 1426 is significantly reduced. At the lower range of chamber pressure, namely around 10 mT and below, the plasma energy of the pulsed RF case is greatly reduced from that of the continuous RF case.

The “off” time of the pulsed RF power waveform and the distance L_{D} between the ion generation region 1440 and the substrate 1426 must both be sufficient to allow plasma generated in the ion generation region 1440 to lose a sufficient amount of its energy so that it causes little or no ion bombardment damage or defects upon reaching the substrate 1426. Specifically, the “off” time is defined by a pulse frequency between about 2 and 30 kHz, or at about 10 kHz, and an “on” duty cycle between about 5% and 20%. Thus, in some embodiments, the “on” interval may last between about 5-50 microseconds, or about 20 microseconds and the “off” interval may last between about 50-95 microseconds, or about 80 microseconds.

The plasma generated may be formed in a low pressure process, thereby reducing the likelihood of contamination induced defects. For example, in some embodiments, the chamber 1410 may be maintained at a pressure of between about 1-500 mTorr. Moreover, ion bombardment-induced defects that would be expected at such a low chamber pressure levels may be limited or prevented by using the quasi-remote plasma source and, optionally, by pulsing the plasma source power as described above.

The substrate may be maintained at about room temperature (about 22 degrees Celsius), or at a temperature of between about 20-750 degrees Celsius, or less than about 700 degrees Celsius, or less than about 600 degrees Celsius. In some embodiments, higher temperatures may be utilized as well, such as less than about 800 degrees Celsius in remote plasma oxidation processes.

The chamber in FIG. 13A also includes means for cooling the substrate. The means for cooling can include a showerhead 1450 disposed above the pedestal 1425. The showerhead 1450 having a plurality of opens 1451 in communication via channels or conduits (not shown) with a coolant supply 1452. Coolant supply can be a suitable gas, for example an inert gas such as nitrogen or a conductive gas such as helium, neon or mixtures thereof.

The cooling means can also separately include, or together with the showerhead, a cooling system for the support pedestal 1424. FIG. 13B shows a modified chuck with a feedback cooling system 1454 for cooling the chuck to at least as low as 20° C., for example 22° C., 25° C., 30° C. or any other suitable temperature to perform the cyclical oxidation and etching process. It will be understood that the cooling system 1454 does not necessarily have to include feedback control. Conventional cooling systems for regulating the temperature of the support pedestal 1424 pedestal can be used. Such conventional systems employ a refrigeration system that cools a refrigerant or coolant medium using a conventional thermal cycle and transfers heat between the coolant and the support pedestal through a separate liquid heat transfer medium. The coolant may be a mixture of deionized water with other substances such as glycol and (or) perfluoropolyethers.

In the system show in FIG. 13B, a temperature feedback control system 1454 of the type shown in United States Patent Application Publication No. 2007/0097580, in which a feedback control loop processor 1455 governs a backside gas pressure valve 1456.

The wafer temperature may be controlled or held at a desired temperature under a given RF heat load on the substrate 1426 using a temperature feedback control loop governing either (or both) an expansion valve 1468 and a bypass valve 1470, although the simplest implementation controls the expansion valve 1468 only.

Thermal conductivity between the wafer 1426 and the cooled support pedestal 1424 is enhanced by injection under pressure of a thermally conductive gas (such as helium) into the interface between the backside of the wafer 1426 and the top surface of the support pedestal 1424. For this purpose, gas channels 1486 are formed in the top surface of the support pedestal and a pressurized helium supply 1488 is coupled to the internal as channels 1486 through a backside gas pressure valve 1456. The wafer 1426 is electrostatically clamped down onto the top surface of the by a D.C. clamping voltage applied by a clamp voltage source 1490 to the grid electrode 1482. The thermal conductivity between the wafer 1426 and the support pedestal 1424 is determined by the clamping voltage and by the thermally conductive gas (helium) pressure on the wafer backside. Wafer temperature control is carried out by varying the backside gas pressure (by controlling the valve 1456) so as to adjust the wafer temperature to the desired level. As the backside gas pressure is changed, the thermal conductivity between the wafer and the support pedestal 1424 is changed, which changes the balance between (a) the heat absorbed by the wafer 1426 from RF power applied to the grid electrode 1482 or coupled to the plasma and (b) the heat drawn from the wafer to the cooled support pedestal. Changing this balance necessarily changes the wafer temperature. A feedback control loop governing the backside gas pressure can therefore be employed for agile or highly responsive control of the wafer temperature. The actual temperature is sensed at a temperature probe, which may be a temperature probe 1457, a second temperature probe 1458, a temperature probe 1459 at evaporator inlet 1463 or a temperature probe 1460 at evaporator outlet 1464 or a combination of any or all of these probes. For this purpose, a feedback control loop processor 1472 governs the orifice opening size of the expansion valve 1468 in response to input or inputs from one or more of the temperature probes. The processor 1472 is furnished with a user-selected desired temperature value, which may be stored in a memory or user interface 1474. As a simplified explanation, during each successive processing cycle, the processor 1472 compares the current temperature measured by at least one of the probes (e.g., by the probe 1457 in the ESC insulating layer) against the desired temperature value. The processor 1472 then computes an error value as the difference between the desired and measured temperature values, and determines from the error a correction to the orifice size of either the bypass valve 1470 or the expansion valve 1468, that is likely to reduce the error. The processor 1472 then causes the valve orifice size to change in accordance with the correction. This cycle is repeated during the entire duration of a substrate process to control the substrate temperature.

One (or more) temperature sensors 1457, 1458, 1459 or 1460 in the support pedestal may be connected to an input of the processor 1455. A user interface or memory 1461 may provide a user-selected or desired temperature to the processor 1455. During each successive processing cycle, the processor 1455 computes an error signal as the difference between the current temperature measurement (from one of the sensors 1457, 1458, 1459) and the desired temperature. The processor 1455 determines from that difference a correction to the current setting of the backside gas pressure valve that would tend to reduce the temperature error, and changes the valve opening in accordance with that correction. For example, a substrate temperature that is deviating above the desired temperature would require increasing the backside gas pressure to increase thermal conductivity to the cooled support pedestal 1424 and bring down the substrate temperature. The converse is true in the case of a substrate temperature deviating below the desired temperature. The substrate temperature can thus be controlled and set to new temperatures virtually instantly within a temperature range whose lower limit corresponds to the chilled temperature of the support pedestal 1424 and whose upper limit is determined by the RF heat load on the substrate. For example, the substrate temperature cannot be increased in the absence of an RF heat load and the substrate temperature cannot be cooled below the temperature of the support pedestal 1424. If this temperature range is sufficient, then any conventional technique may be used to maintain the support pedestal 1424 at a desired chilled temperature to facilitate the agile temperature feedback control loop governing the backside gas pressure.

The support pedestal 1424 contains a heat exchanger 1462 in the form of cooling passages for a cooling medium, which can be any suitable cooling fluid such, for example a cooling gas such as helium or nitrogen, or a fluid of type described above. The heat exchanger 1462 cooling passages include an inlet 1463 and an outlet 1464. The heat exchanger 1462 is internally contained with the support pedestal 1424. The feedback control system 1454 can operate in either of two modes, namely a cooling mode (in which the heat exchanger 1462 functions as an evaporator) and a heating mode (in which the heat exchanger 1462 functions as a condenser). The remaining elements of the feedback control system 1454 are external of the support pedestal 1454, and include an accumulator 1465, a compressor 1466 (for pumping cooling medium through the loop), and (for the cooling mode of operation) a condenser 1467 and an expansion valve 1468 having a variable orifice size. The feedback control system 1454 (i.e., the heat exchanger 1462, the accumulator 1465, the compressor 1466, the condenser 1467, the expansion valve 1468 and the conduits coupling them together, contain the cooling medium (which functions as a refrigerant or coolant when the system operates in the cooling mode) of a conventional type and can have low electrical conductivity to avoid interfering with the RF characteristics of the reactor. The accumulator 1465 prevents any liquid form of the cooling medium from reaching the compressor 1466 by storing the liquid. This liquid is converted to vapor by appropriately operating a bypass valve 1469.

In order to overcome the problem of thermal drift during processing, the efficiency of the feedback control system 1454 is increased ten-fold or more by operating the Feedback control system 1454, 1462, 1465, 1466, 1467, 1468 so that the cooling medium inside the heat exchanger is divided between a liquid phase and a vapor phase. The liquid-to-vapor ratio at the inlet 1463 is sufficiently high to allow for a decrease in this ratio at the outlet 1464. This guarantees that all (or nearly all) heat transfer between the support pedestal 1424 and the cooling medium (coolant) within the heat exchanger (evaporator) 1462 occurs through contribution to the latent heat of evaporation of the cooling medium. As a result, the heat flow in the feedback control system 1454 exceeds, by a factor of 10, the heat flow in a single-phase cooling cycle. This condition can be satisfied with a decrease in the cooling medium's liquid-to-vapor ratio from the inlet 1463 to the outlet 1464 that is sufficiently limited so that at least a very small amount of liquid remains at (or just before) the outlet 1464. In the cooling mode, this requires that the coolant capacity of the feedback control system 1454 is not exceeded by the RF heat load on the substrate.

The temperature feedback control loop 1454 governing the backside gas pressure valve 1456 and the large range temperature feedback control loop governing a refrigeration expansion valve 1468 may be operated simultaneously in a cooperative combination under the control of a master processor 232 controlling both feedback control loop processors 1472, 1455.

The feedback control loop including the evaporator 1462, the compressor 1466, the condenser 1467 and the expansion valve 1468) controls the workpiece temperature by changing the temperature of the support pedestal 1424. The temperature range is limited only by the thermal capacity of the feedback control system 1454 and can therefore set the workpiece temperature to any temperature within a very large range (e.g., −10 ° C. to +150 ° C.). However, the rate at which it can effect a desired change in workpiece temperature at a particular moment is limited by the thermal mass of the support pedestal. This rate is so slow that, for example, with an electrostatic chuck for supporting a 300 mm workpiece or silicon wafer, a 10° C. change in workpiece temperature can require on the order of a minute or more from the time the refrigeration unit begins to change the thermal conditions of the coolant to meet the new temperature until the workpiece temperature finally reaches the new temperature.

In contrast, in making a desired change or correction in workpiece temperature, the temperature feedback control system 1454 does not change the support pedestal temperature (at least not directly) but merely changes the thermal conductivity between the workpiece and the support pedestal. The rate at which the workpiece temperature responds to such a change is extremely high because it is limited only by the rate at which the backside gas pressure can be changed and the thermal mass of the workpiece. The backside gas pressure responds to movement of the valve 1456 in a small fraction of a second in a typical system. For a typical 300 mm silicon wafer, the thermal mass is so low that the wafer (workpiece) temperature responds to changes in the backside gas pressure within a matter of a few seconds or a fraction of a second. Therefore, relative to the time scale over which the large range temperature control loop effects changes in workpiece temperature, the workpiece temperature response of the temperature feedback loop is comparatively instantaneous. However, the range over which the agile feedback loop can change the workpiece temperature is quite limited: the highest workpiece temperature that can be attained is limited by the RF heat load on the wafer, while the lowest temperature cannot be below the current temperature of the support pedestal. However, in combining the agile and large range temperature control loops together, the advantages of each one compensate for the limitations of the other, because their combination provides a large workpiece temperature range and a very fast response.

The master processor 1476 may be programmed to effect large temperature changes using the large range feedback control loop (the processor 1472) and effect quick but smaller temperature changes using the agile feedback control loop (the processor 230). An RF bias generator 1478 produces power in the HF band (e.g., 13.56 MHz). Its RF bias impedance match element 1480 is coupled to the conductive mesh 1482 by an elongate conductor or an RF conductor extending through the workpiece pedestal support.

As discussed above, embodiments of the present invention may be performed in different chambers than the decoupled plasma oxidation chamber described above with respect to FIGS. 13A and 13B. Two additional exemplary plasma reactors suitable for cyclical oxidation and etching include a modified rapid and/or remote plasma oxidation (RPO) reactor, illustrated in FIG. 14, and a modified toroidal source plasma immersion ion implantation reactor, such as P3I, illustrated in FIG. 15. Each of these reactors are available from Applied Materials, Inc. of Santa Clara, Calif.

FIG. 14 illustrates one embodiment of an apparatus or system used to form a plasma from process gases, and utilized to deposit an oxide layer on a semiconductor structure. The apparatus or system includes a rapid thermal processing (RTP) apparatus 1500, such as, but not limited to, the Applied Materials, Inc., RTP CENTURA® with a HONEYCOMB SOURCE™. Such a suitable RTP apparatus and its method of operation are set forth in U.S. Pat. No. 5,155,336, assigned to the assignee of the invention. Other types of thermal reactors may be substituted for the RTP apparatus such as, for example, the Epi or Poly Centura®. Single Wafer “Cold Wall” Reactor by Applied Materials used to form high temperature films, such as epitaxial silicon, polysilicon, oxides, and nitrides. The DxZ® chamber by Applied Materials is also suitable.

Coupled to RTP apparatus 1500 is a plasma applicator 1502 that, in operation, provides radicals of a plasma to RTP apparatus 1500. Coupled to plasma applicator 1502 is an energy source 1504 to generate an excitation energy to create a plasma.

In the embodiment illustrated in FIG. 14, the RTP apparatus 1500 includes a process chamber 1506 enclosed by a side wall 1508 and a bottom wall 1510. The upper portion of side wall 1508 of chamber 1506 is sealed to a window assembly 1512 by “O” rings. A radiant energy light pipe assembly or illuminator 1514 is positioned over and coupled to window assembly 1512. Light pipe assembly 1514 includes a plurality of tungsten halogen lamps 1516, for example, Sylvania EYT lamps, each mounted into, for example, light pipes 1518 that can be made of stainless steel, brass, aluminum, or other metals.

A wafer or substrate 1520 is supported on an edge inside chamber 1506 by a support ring 1522 typically made of silicon carbide. Support ring 1522 is mounted on a rotatable quartz cylinder 1524. By rotating quartz cylinder 1524, support ring 1522 and wafer or substrate 1520 are caused to rotate during processing. An additional silicon carbide adapter ring can be used to allow wafers or substrates of different diameters to be processed (e.g., 150 millimeter, 200 millimeter or 300 millimeter wafers).

Bottom wall 1510 of RTP apparatus 1520 includes, for example, a gold-coated top surface or reflector 1526 for reflecting energy onto the backside of wafer or substrate 1520. Additionally, RTP apparatus 1500 includes a plurality of fiber optic probes 1528 positioned through bottom wall 1510 of RTP apparatus 1500 to detect the temperature of wafer or substrate 1520 at a plurality of locations across its bottom surface.

RTP apparatus 1520 includes a gas inlet (not shown) formed through side wall 1508 for injecting a process gas into chamber 1506 to allow various processing steps to be carried out in chamber 1506. Positioned on the opposite side of gas inlet, in side wall 1508, is a gas outlet (not shown). The gas outlet is part of an exhaust system and is coupled to a vacuum source, such as a pump (not shown), to exhaust process gas from chamber 1506 and to reduce the pressure in chamber 1506. The exhaust system maintains the desired pressure while process gas, including radicals of a plasma, is continually fed into chamber 1506 during processing.

Another gas inlet 1530 is formed through side wall 1508 through which a plasma of a process gas may be injected into the process chamber. Coupled to gas inlet 1530 is applicator 1502 to inject radicals of the plasma into the process chamber.

Light pipe assembly 1514 may include lamps 1516 positioned in a hexagonal array or in a “honeycomb” shape. Lamps 1516 are positioned to adequately cover the entire surface area of wafer or substrate 1520 and support ring 1522. Lamps 1516 are grouped in zones that can be independently controlled to provide for extremely uniform heating of wafer or substrate 1520. Light pipes 1518 can be cooled by flowing a coolant, such as water, between the various light pipes.

Window assembly 1512 includes a plurality of short light pipes 1532. A coolant, such as water, can be injected into the space between light pipes 1532 to cool light pipes 1532. Light pipes 1532 register with light pipes 1518 of the illuminator. A vacuum can be produced in the plurality of light pipes 1532 by pumping through a tube 1540 connected to one of the light pipes 1532, which is in turn connected to the rest of the pipes.

RTP apparatus 1500 is a single wafer reaction chamber capable of ramping the temperature of wafer or substrate 1520 at a rate of 25-100 degrees Celsius/second. RTP apparatus 1500 can be referred to as a “cold wall” reaction chamber because the temperature of wafer or substrate 1520 during, for example, an oxidation process is at least 400 degrees Celsius greater than the temperature of chamber side wall 1508. Heating/cooling fluid can be circulated through side walls 1508 and/or bottom wall 1510 to maintain the walls at a desired temperature.

As noted above, plasma applicator 1502 is coupled to RTP apparatus 1500 to provide a source of radicals of a plasma to RTP apparatus 1500. In one embodiment, plasma is connected to RTP apparatus 1500 by an inlet member 1542.

Plasma applicator 1502 also includes a gas inlet 1544. Coupled to gas inlet 1544 is a gas source, such as a reservoir or tank 1546. Plasma applicator 1502 is coupled to energy source 1504 by waveguides 1548a and 1548b. The gas source may comprise one or more of an oxidizing gas, an inert gas, nitrogen gas for nitridation, and an etching gas, which may be in separate tanks or reservoirs.

FIG. 14 illustrates an embodiment wherein plasma applicator 1502 is remote from RTP apparatus 1500 in that the plasma is generated outside chamber 1506 of RTP apparatus 1500. By locating plasma applicator 1502 remotely from chamber 1506 of RTP apparatus 1500, a plasma source can be selectively generated to limit the composition of the plasma exposed to wafer or substrate 1520 to predominantly radicals. Thus, a plasma of ions, radicals, and electrons is generated in plasma applicator 1502. However, because of the size (e.g., length and volume) of plasma applicator 1502 or the combined size of plasma applicator 1502 and inlet member 1542, all or the majority of ions generated by the excitation of the process gas to form a plasma outlive their ionic lifetime and become charge neutral. Thus, the composition of the plasma that is supplied to the gas inlet of RTP apparatus 1500 is predominantly radicals.

Plasma applicator 1502 includes a body 1503 of, for example, aluminum or stainless. Body 1503 surrounds a tube 1505. The tube 1505 is, for example, made of quartz or sapphire. The tube 1505 preferably does not have any electrical bias present that might attract charged particles, e.g., ions. One end of body 1503 includes gas inlet 1544.

Coupled to gas inlet 1544 is gas source 1546. The gas source 1546 is coupled to gas inlet 1544 through a first input of a three-way valve 1550. A second input of three-way valve 1550 is coupled to another process gas source, such as a reservoir or tank 1552. In a first position, valve 1550 provides for gas flow between gas source 1546 and gas inlet 1544, while preventing any gas flow from gas source 1552 to process chamber 1506. The valve 1550, in a second position, provides for gas flow between gas source 1552 and process chamber 1506, while preventing gas flow from gas source 1546 to gas inlet 1544 of the applicator. The gas sources may comprise one or more of an oxidizing gas, an inert gas, nitrogen gas for nitridation, and an etching gas, which may be in separate tanks or reservoirs.

A flow controller 1554 is connected to valve 1550 to switch the valve between its different positions, depending upon which process is to be carried out. The flow controller can function as a mass flow controller and be coupled between source gas 1546 and gas inlet 1544 to regulate the flow of gas to plasma applicator 1502. The flow controller 1554 also functions in a similar fashion to control valves 1550 and 1551 to provide an appropriate process gas flow from gas source 546 or 552 to the process chamber.

Positioned on the opposite side of gas inlet 1544 is a radicals outlet 1562. Radicals outlet 1562 is coupled to inlet member 1542 to supply, in one embodiment, radicals of a plasma 1564 to chamber 1506 of RTP apparatus 1500. Radicals outlet 1562 typically has a diameter larger than gas inlet 1544 to allow the excited radicals to be efficiently discharged at the desired flow rate and to minimize the contact between the radicals and tube 1505. The flow rate of the radicals generated and discharged by plasma applicator 1502 is determined primarily by the source gas inlet flow, the dimensions of tube 1505 and radical outlet 1562, and the pressure in plasma applicator 1502.

The pressure in the process chamber should be less than the pressure in the applicator. The pressure in the process chamber may be between about 0.50 and 4.0 Torr, while the pressure in the applicator may be between about 1.0 and 8.0 Torr. For example, if the pressure in the applicator is about 2.00 Torr, then the pressure in the process chamber should be about 1.00 Torr.

At a position between gas inlet 1544 and radicals outlet 1562 of body 1503 is energy source inlet 1566. Energy source inlet 1566 allows the introduction into tube 1505 of excitation energy, such as an energy having a microwave frequency, from energy source 1504. In the case of a microwave frequency, the excitation energy moves into body 1503 of plasma applicator 1502 and through tube 1505 to excite the gas source traveling in a direction perpendicular to energy source inlet 564 into a plasma.

In one embodiment, energy source 1504 consists of a magnetron 1568, and an isolator and dummy load 1570, which is provided for impedance matching. Magnetron 1568 generates an excitation energy, such as for example, an electromagnetic or inductively coupled frequency. The magnetron can generate between 1.5 and 6.0 kilowatts of 2.54 GHZ of microwave energy. A suitable magnetron assembly can be obtained from Applied Sciences and Technology, Woburn, Mass., or Daihen America, Santa Clara, Calif.

The excitation energy from magnetron 1568 is directed through isolator and dummy load 1570, and waveguides 1548a and 1548b to tube 1505. Dummy load 1570 acts, in one sense, like a check valve to allow energy flow in a direction toward applicator 1502 but not toward magnetron 1568.

Between plasma applicator 1502 and waveguide 1548b is autotuner 1572. The autotuner redirects radiation reflected from applicator 1502 back toward the plasma applicator to increase the energy supplied to plasma applicator 1502. Autotuner 1572 also focuses the microwave energy into the center of tube 1505 so that the energy is more preferentially absorbed by the gas fed to the applicator. Although an autotuner is preferred, a manual tuner may be used.

A control signal generation logic 1555 is supplied to system controller 1556 in the form of, for example, software instruction logic that is a computer program stored in a computer-readable medium such as a memory 1557 in system controller 1556. The computer program includes, among other things, sets of instructions that dictate the timing, gas flow rate, chamber pressure, chamber temperature, RF power level, energy source regulation and other parameters of a particular process. The computer program is processed by system controller 1556 in a processor 1559. Thus, the instructions may be operative to dictate the timing, gas flow rate, chamber pressure, chamber temperature, RF power level, energy source regulation and other parameters to perform a cyclical oxidation and etching process as described herein. The apparatus in FIG. 14 may further include a cooling loop as described above with respect to FIG. 13B in communication with the system controller.

FIG. 15 illustrates one embodiment of toroidal source plasma ion immersion implantation reactor such as, but not limited to, the Applied Materials, Inc., P3I reactor. Such a suitable reactor and its method of operation are set forth in U.S. Pat. No. 7,166,524, assigned to the assignee of the invention.

Referring to FIG. 15, a toroidal source plasma immersion ion implantation (“P3I”) reactor 1600 may include a cylindrical vacuum chamber 1602 defined by a cylindrical side wall 1604 and a disk-shaped ceiling. A wafer support pedestal 1608 at the floor of the chamber supports a semi-conductor wafer 1610 to be processed. A gas distribution plate or showerhead 1612 on the ceiling 1606 receives process gas in its gas manifold 1614 from a gas distribution panel 1616 whose gas output can be any one of or mixtures of gases from one or more individual gas supplies 1618. A vacuum pump 1620 is coupled to a pumping annulus 1622 defined between the wafer support pedestal 1608 and the sidewall 1604. A process region 1624 is defined between the wafer 1610 and the gas distribution plate 1612.

A pair of external reentrant conduits 1626, 1628 establish reentrant toroidal paths for plasma currents passing through the process region, the toroidal paths intersecting in the process region 1624. Each of the conduits 1626, 1628 has a pair of ends 1630 coupled to opposite sides of the chamber. Each conduit 1626, 1628 is a hollow conductive tube. Each conduit 1626, 1628 has a D.C. insulation ring 1632 preventing the formation of a closed loop conductive path between the two ends of the conduit.

An annular portion of each conduit 1626, 1628, is surrounded by an annular magnetic core 1634. An excitation coil 1636 surrounding the core 1634 is coupled to an RF power source 1638 through an impedance match device 1640. The two RF power sources 1638 coupled to respective ones of the cores 1636 may be of two slightly different frequencies. The RF power coupled from the RF power generators 1638 produces plasma ion currents in closed toroidal paths extending through the respective conduit 1626, 1628 and through the process region 1624. These ion currents oscillate at the frequency of the respective RF power source 1626, 1628. Bias power is applied to the wafer support pedestal 1608 by a bias power generator 1642 through an impedance match circuit 1644.

Plasma formation and subsequent oxide layer formation may be performed by introducing the process gases into the chamber 1624 through the gas distribution plate 1612 and applying sufficient source power from the generators 1638 to the reentrant conduits 1626, 1628 to create toroidal plasma currents in the conduits and in the process region 1624. The plasma flux proximate the wafer surface is determined by the wafer bias voltage applied by the RF bias power generator 1642. The plasma rate or flux (number of ions sampling the wafer surface per square cm per second) is determined by the plasma density, which is controlled by the level of RF power applied by the RF source power generators 1638. The cumulative ion dose (ions/square cm) at the wafer 1610 is determined by both the flux and the total time over which the flux is maintained.

If the wafer support pedestal 1608 is an electrostatic chuck, then a buried electrode 1646 is provided within an insulating plate 1648 of the wafer support pedestal, and the buried electrode 1646 is coupled to the bias power generator 1642 through the impedance match circuit 1644.

In operation, the formation of an oxide or nitride layer on a semiconductor wafer is achieved by placing the wafer 1610 on the wafer support pedestal 1608, introducing one or more process gases into the chamber 1602 and striking a plasma from the process gases. The wafer bias voltage delivered by the RF bias power generator 1642 can be adjusted to control the flux of ions to the wafer surface.

In any of the apparatus described above with respect to FIGS. 13A, 14 and 15, exemplary conditions during oxidation are pressures in the range of about 1 milli Torr to about 10 Torr, power in the range about 1 to 5000 Watts, more specifically in the range of about 1 to 3000 Watts and temperatures in the range of about 0° C. to about 800° C., more specifically in the range of about 0° C. to about 500° C.

Exemplary etching conditions include chamber pressure in the range of about 1 milliTorr to about 10 Torr, power in the range of 1 to 5000 Watts, and temperature in the range of about 0° C. to about 800° C. In specific embodiments, etching is conducted with a direct plasma using NH₃/NF₃ chemistry at about 30° C. +/−5° C. A sublimation reaction can be achieved by heating the substrate to at least about 100° C. for at least about 1 minute, at a pressure in the range of 1 milliTorr to about 10 Torr. The chambers described above with respect o FIGS. 13A, 14 and 15 can be used to achieve these conditions and perform a cyclical etching and oxidation and/or nitridation process as described herein.

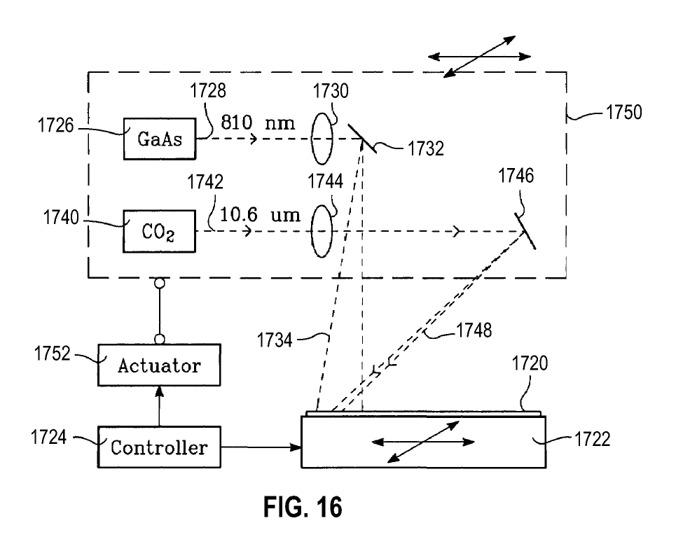

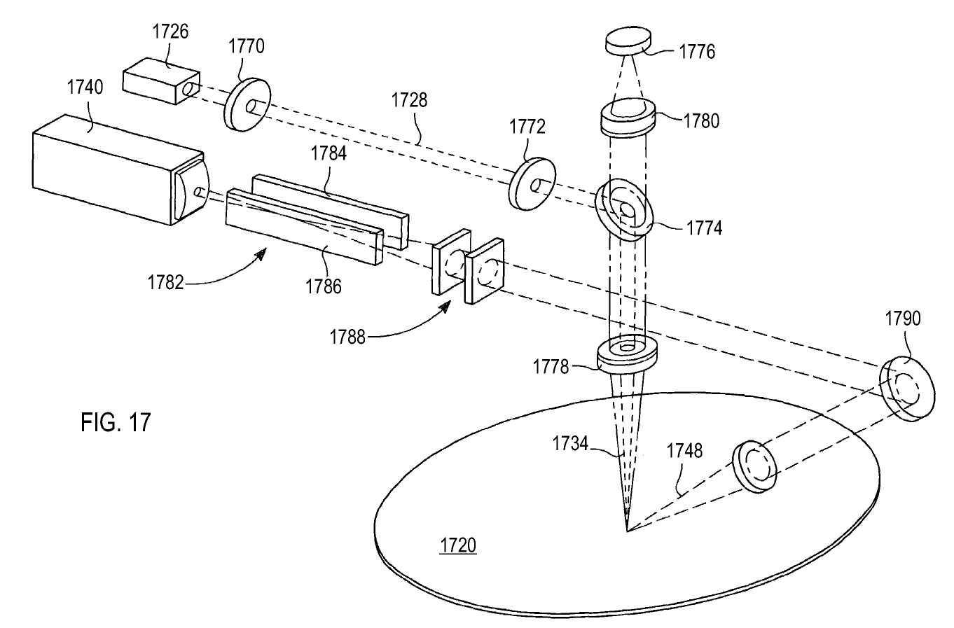

As will be appreciated any of the chambers described with respect to FIGS. 13A, 14 and 15 can include a system controller to control operation of the chamber as was described above with respect to the system show in FIG. 12. Thus in operation, the a system controller enables data collection and feedback from the respective systems such as gas sources, plasma source(s), heating source(s) and other components to optimize performance of the tool the chamber. Thus, the gas source can include a volume or mass flow controller that is in communication with the system controller that enables gas flow to increase or decrease and to increase or decrease pressure in the chamber. A system controller in communication with the plasma source can change the power, bias and other plasma parameters of the plasma source of the chamber. The system controller is also in communication with the heating source, whether the source is a heated showerhead, a resistive heater, a lamp source or a laser source of the type described below with respect to FIGS. 16 and 17. Additionally, the system controller may be in operative communication with cooling systems that cool the chamber walls, the substrate support or other localized cooling sources in the chamber. A system controller generally includes a Central Processing Unit (CPU), a memory, and a support circuit. The CPU may be one of any form of a general purpose computer processor that can be used in an industrial setting. The support circuit is conventionally coupled to the CPU and may comprise a cache, clock circuits, input/output subsystems, power supplies, and the like. Software routines, such as one for performing a method of forming a floating gate as described above, when executed by the CPU, transform the CPU into a specific purpose computer (controller). The software routines may also be stored and/or executed by a second controller (not shown) that is located remotely from the tool. Through the use of a system controller, the steps of formation of an oxide layer and/or nitride layer, etching (by plasma and sublimation) can be repeated cyclically within the chambers of FIGS. 13A, 14 and 15 until an oxide and/or nitride layer have a desired material thickness has been formed. Exemplary devices and process sequences are described above with respect to FIGS. 3A-3C, 5A-5E, 7A-7D, 8A-8B, 10A-10D or 11A-11C, and any of these processes can be performed in the single chambers described with respect to FIGS. 13A, 14 and 15.

According to one or more embodiments, a complete process sequence of an oxidation and/or nitridation and an etching step can be completed in the chambers in less than about three minutes. In specific embodiments, a complete process sequence of an oxidation and/or nitridation and an etching step can be completed in the chambers in less than about two minutes, and in more specific embodiments, a complete process sequence of an oxidation and/or nitridation and an etching step can be completed in the chambers in less than about one minute, for example 45 seconds or 30 seconds. It is believed that previously, such processing times could not be achieved in a single chamber that requires both etching chemistry, oxidation and/or nitridation chemistry and the ability to rapidly cycle from temperatures of about 100 degrees Centigrade or higher to less than 100 about degrees Centigrade, for example, less than about 50 degrees Centigrade, more specifically less than about 40 degrees Centrigrate, for example about 30 degrees Centigrade +/− five degrees Centigrade to complete at least one single process sequence of oxidation and/or nitridation and etch.

The manufacture of devices having ultra-narrow features of the type described above, which may have shallow and abrupt junctions, can benefit from precise thermal control of only the upper few microns of material surface. To this end, it may be desirable to include a lamp or laser heating feature in the systems described above with respect to FIGS. 13A and 14-15. In one or more embodiments, the light from the lamps or laser are configured to so that the light energy being emitted by the lamps contacts the wafer at an angle of incidence that optimizes absorption by the material being processed. The material being processed present invention can be contacted with a single wavelength source or with multiple wavelengths of light in a manner so that a portion of the wavelengths are efficiently absorbed by the material being heated. Suitable light sources include lasers, or various incoherent light sources such as arc lamps, tungsten halogen lamps, and the like.

Pulsed laser thermal processing has been developed that utilize short (for example, 20 ns) pulses of laser radiation that are focused at a reduced area of the device being processed. Ideally, the pulses are the same size as an optical stepper field in the neighborhood of 20 mm by 30 mm. The total energy of the laser pulse is sufficient to immediately heat the surface of the irradiated area to a high temperature. Thereafter, the small volume of heat generated by the shallow laser pulse quickly diffuses into the unheated lower portions of the material being processed, thereby greatly increasing the cooling rate of the irradiated surface region. Several types of high-power lasers can be pulsed at a repetition rate of hundreds of pulses per second. The laser is moved in a step-and-repeat pattern over the surface of the material being processed and is pulsed in neighboring areas to similarly thermally process the entire surface of the material being processed. A newer class of laser thermal processing equipment has been developed in which a narrow line beam of continuous wave (CW) laser radiation having a long dimension and a short dimension is scanned over the material to be processed in a direction along the short dimension, that is, perpendicular to the line. The line width is small enough and the scan speed high enough that the scanned line of radiation produces a very short thermal pulse at the surface, which thereafter quickly diffuses vertically into the substrate and horizontally to lower-temperature surface regions. The process may be referred to as thermal flux annealing. U.S. Pat. No. 6,987,240 discloses the use of laser diode bars lined up along the long direction of the beam to produce laser radiation. These laser diode bars are typically composed of GaAs or similar semiconductor materials and are composed of a number of diode lasers formed in a same layer of an opto-electronic chip. The GaAs laser bars disclosed in U.S. Pat. No. 6,987,240 emit near-infrared radiation at a wavelength of about 808 nm, which couples well into silicon. Thus, according to one or more embodiments, lamp radiation, pulsed lasers, continuous wave lasers, and/or laser diodes can be used to selectively oxidize a surface of a material layer to form an oxide layer and/or to etch the oxide layer.

More recently, laser sources other than GaAs diodes have been recognized as having advantages, for example, carbon dioxide lasers, and proposals have been made to utilize dual laser sources. For example, U.S. Pat. No. 7,279,721 discloses a dual laser source system that can be used to selectively oxidize oxidize a surface of a material layer to form an oxide layer and/or to etch the oxide layer.

Referring now to FIGS. 16 and 17, an exemplary embodiment of a dual source light system of the type disclosed in U.S. Pat. No. 7,279,721 is shown. FIG. 16 shows a simplified, schematic representation of one embodiment of the invention. A wafer 1720 or other substrate is held on a stage 1722 that is motor driven in one or two directions under the control of a system controller 1724. A relatively short-wavelength laser 1726, such as a GaAs laser bar, emits a visible or nearly visible continuous wave (CW) beam 1728 at a wavelength which is shorter than the silicon bandgap wavelength of about 1.11 μm. For the GaAs laser 1726, the emission wavelength is typically about 810 nm, which can be characterized as red. First optics 1730 focus and shape the beam 1728 and a reflector 1732 redirects the beam 1728 towards the wafer 1720 in a relatively wide activating beam 1734, also illustrated in the plan view of FIG. 17. The activating beam 1734 may be inclined at some angle, for example, of 15 degrees with respect to the wafer normal to prevent reflection back to the GaAs laser 1726. Such reflected radiation may shorten the lifetime of diode lasers. A long-wavelength laser 1740, for example, a CO₂ laser, emits an infrared continuous wave (CW) beam 1742 at a wavelength longer than the silicon bandgap wavelength of 1.11 μm. In a specific embodiment, the CO₂ laser emits at a wavelength near 10.6 μm. Second optics 1744 focus and shape the CO₂ beam 1742 and a second reflector 1746 reflects the CO₂ beam 1742 into a relatively narrow heating beam 1748. In specific embodiments, the CO₂ heating beam 1748 is inclined at the Brewster angle, which is about 72 degrees for silicon, with respect to the substrate normal so as to maximize coupling of the heating beam 1748 into the substrate 1720. Incidence at the Brewster angle is most effective for p-polarized radiation, that is, radiation polarized along the surface of the substrate 1720 since there is no reflected radiation arising from the fact that there is a 90 degree angle between the refracted beam in the substrate 1720 and any reflected beam. Therefore, s-polarized light is advantageously suppressed over p-polarized light in the CO₂ beam 1718. However, experiments have shown that a 20 degree cone of radiation centered at 40 degrees (+/−10 degrees) from the substrate normal results in a variability of absorption about 3.5% for a number of patterns that is nearly as good as the 2.0% achieved with a cone centered at the Brewster angle. As illustrated in FIG. 17, the long-wavelength (CO₂) heating beam 1748 is located within and preferably centered on the larger short-wavelength (visible) activating beam 1734. Both beams 1734, 1748 are synchronously scanned across the substrate 1720 as the stage 1722 moves the substrate 1720 relative to the optical source 1750 comprising the lasers 1726, 1740 and optical elements 1730, 1732, 1744, 1746. It is alternatively possible that the substrate 1720 is held stationary while an actuator 1752 moves all or part of the optical source 1750 in one or two directions parallel to the surface of the substrate 1720 in accordance to signals from the controller 1724.

The beam shapes on the substrate 1720 are substantially rectangular or at least highly elliptical for both the infrared heating beam 1748 and the visible activating beam 1734. It is understood that the illustrated beam shapes are schematic and represent some fraction of the center intensity since the beams in fact have finite tails extending beyond the illustrated shapes. Further, the infrared beam 1748 is preferably nearly centered on the larger visible beam 1734 as both beams 1734, 1748 are simultaneously moved relative to the substrate 1720.

The general effect is that the larger visible beam 1734, which is sharply attenuated in the silicon, generates free carriers in a somewhat large region generally close to the wafer surface. The smaller infrared beam 1748, which otherwise is not absorbed by the unirradiated silicon, interacts with the free carriers generated by the visible beam 1734 and its long-wavelength radiation is efficiently absorbed and converted to heat, thereby quickly raising the temperature in the area of the infrared beam 1748.

The temperature ramp rates and scanning speeds are primarily determined by the size of the small infrared beam 1748 while the larger visible beam 1734 should encompass the small infrared beam 1748. The width of the small heating beam 1748 in the scan direction determines in part the temperature ramp rate and is minimized in most applications. The length of the small heating beam 1748 perpendicular to the scan direction should be large enough to extend over a sizable fraction of the substrate and thus to anneal the sizable fraction in one pass. Typically, the length of the line beam is at least ten times its width. Optimally, the length equals or slightly exceeds the substrate diameter. However, for commercially feasible applications, the length may be on the order of millimeters. An exemplary size of the small heating beam 1748 on the wafer is 0.1 mm×1 mm, although other sizes may be used. Smaller widths are generally more desirable, for example, less than 500 μm or less than 175 .μm. The larger activating beam 1734 may be larger than the heating beam 1748 by, for example, 1 mm so that in the exemplary set of dimensions it would extend about 1 mm in the scan direction and a few millimeters in the perpendicular direction.

The dual wavelengths produce the result that more infrared absorption is concentrated in the surface region in which the visible radiation is absorbed. The depth of the surface region is less than the absorption length of CO₂ radiation by itself. The room-temperature attenuation depth of visible radiation in silicon rapidly decreases in the visible spectrum with decreasing wavelength, for example, an absorption depth of about 10 μm for 800 nm radiation, 3 μm for 600 nm radiation and about 1 μm for 500 nm. Accordingly, the shorter activation wavelengths are advantageous for generating free carriers only very near the wafer surface to confine the heating to near the surface. Thus, for some applications, an even shorter activating wavelength is desired, such as 532 nm radiation from a frequency-doubled Nd:YAG laser, which can be characterized as green.

It will be understood that the light source system above does not necessarily have to include a dual light source, and in some embodiments, a single light source can be used. If a light source system is used to heat a material layer on a substrate in accordance with one or more embodiments, the light source system can be in communication with a system controller of any of the chambers described above or below in this specification, and the heating of the material surface can be controlled by the system controller which can control a variety of process parameters to the light source, for example power to the light source and duration of exposure of a material layer to the light.

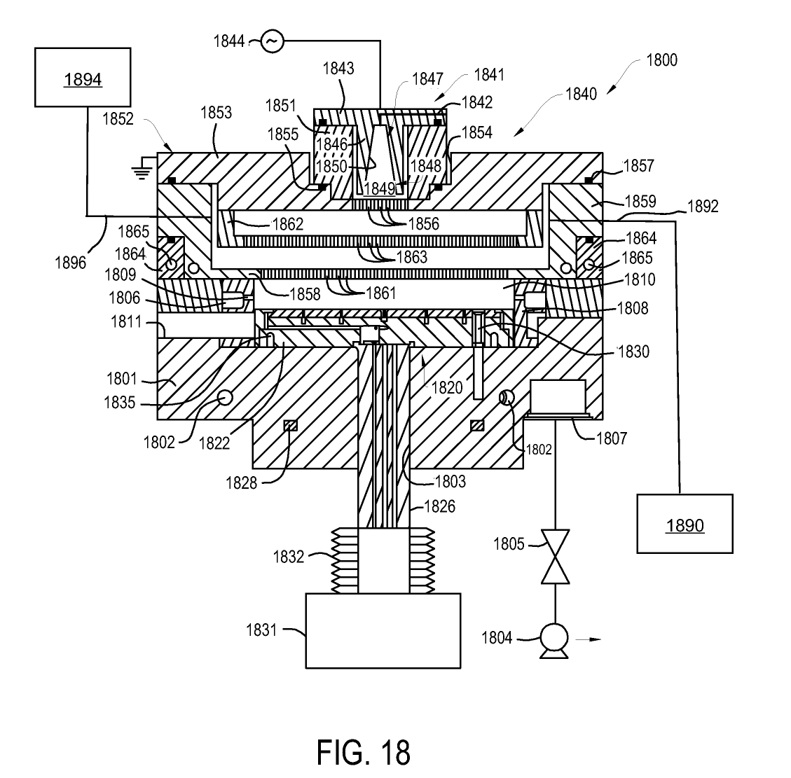

In another embodiment a modified dry etching chamber can be utilized to perform cyclical oxidation and etching of an oxide material surface. An exemplary chamber is a SICONI™ available from Applied Materials and will be described below with respect to FIGS. 18-20.

FIG. 18 is a partial cross sectional view showing an illustrative processing chamber 1800. The processing chamber 1800 may include a chamber body 1801, a lid assembly 1840, and a support assembly 1820. The lid assembly 1840 is disposed at an upper end of the chamber body 1801, and the support assembly 1820 is at least partially disposed within the chamber body 1801. The chamber body 1801 may include a slit valve opening 1811 formed in a sidewall thereof to provide access to the interior of the processing chamber 1800. The slit valve opening 1811 is selectively opened and closed to allow access to the interior of the chamber body.

The chamber body 1801 may include a channel 1802 formed therein for flowing a heat transfer fluid therethrough. The heat transfer fluid can be a heating fluid or a coolant and is used to control the temperature of the chamber body 1801 during processing and substrate transfer. Exemplary heat transfer fluids include water, ethylene glycol, or a mixture thereof. An exemplary heat transfer fluid may also include nitrogen gas.

The chamber body 1801 can further include a liner 1808 that surrounds the support assembly 1820. The liner 1808 is can be removable for servicing and cleaning. The liner 1808 can be made of a metal such as aluminum, or a ceramic material. However, the liner 1808 can be any process compatible material. The liner 1808 can be bead blasted to increase the adhesion of any material deposited thereon, thereby preventing flaking of material which results in contamination of the processing chamber 1800. The liner 1808 may include one or more apertures 1809 and a pumping channel 106 formed therein that is in fluid communication with a vacuum system. The apertures 1809 provide a flow path for gases into the pumping channel 1806, which provides an egress for the gases within the processing chamber 1800.

The vacuum system can include a vacuum pump 1804 and a throttle valve 1805 to regulate flow of gases through the processing chamber 1800. The vacuum pump 1804 is coupled to a vacuum port 1807 disposed on the chamber body 1801 and therefore is in fluid communication with the pumping channel 1806 formed within the liner 1808.

Apertures 1809 allow the pumping channel 1806 to be in fluid communication with a processing zone 1810 within the chamber body 1801. The processing zone 1810 is defined by a lower surface of the lid assembly 1840 and an upper surface of the support assembly 1820, and is surrounded by the liner 1808. The apertures 1809 may be uniformly sized and evenly spaced about the liner 1808. However, any number, position, size or shape of apertures may be used, and each of those design parameters can vary depending on the desired flow pattern of gas across the substrate receiving surface as is discussed in more detail below. In addition, the size, number and position of the apertures 1809 are configured to achieve uniform flow of gases exiting the processing chamber 1800. Further, the aperture size and location may be configured to provide rapid or high capacity pumping to facilitate a rapid exhaust of gas from the chamber 1800. For example, the number and size of apertures 1809 in close proximity to the vacuum port 1807 may be smaller than the size of apertures 1809 positioned farther away from the vacuum port 1807.

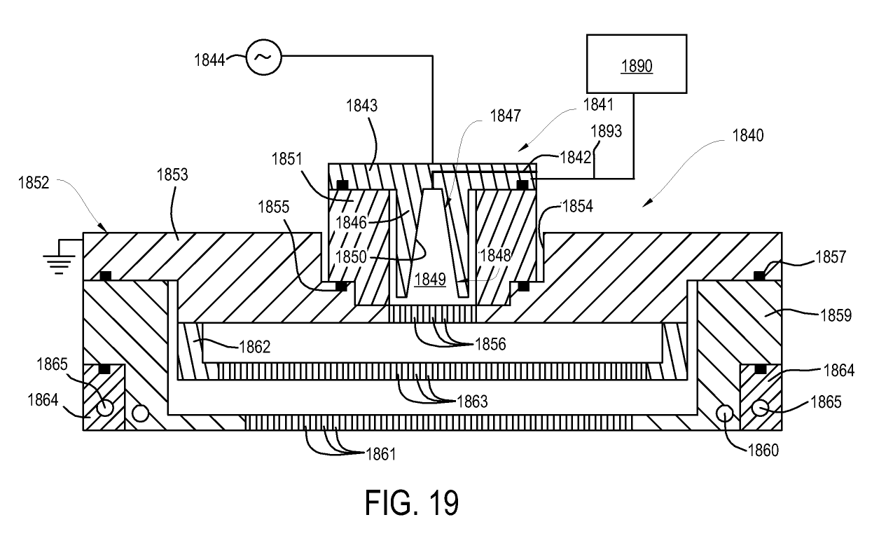

Considering the lid assembly 1840 in more detail, FIG. 19 shows an enlarged cross sectional view of lid assembly 1840 that may be disposed at an upper end of the chamber body 1801. Referring to FIGS. 18 and 19, the lid assembly 1840 includes a number of components stacked on top of one another to form a plasma region or cavity therebetween. The lid assembly 1840 may include a first electrode 1841 (“upper electrode”) disposed vertically above a second electrode 1852 (“lower electrode”) confining a plasma volume or cavity 1849 therebetween. The first electrode 1841 is connected to a power source 1844, such as an RF power supply, and the second electrode 1852 is connected to ground, forming a capacitance between the two electrodes 1841, 1852.

The lid assembly 1840 may include one or more gas inlets 1842 (only one is shown) that are at least partially formed within an upper section 1843 of the first electrode 1841. One or more process gases enter the lid assembly 1840 via the one or more gas inlets 1842. The one or more gas inlets 1842 are in fluid communication with the plasma cavity 1849 at a first end thereof and coupled to one or more upstream gas sources and/or other gas delivery components, such as gas mixers, at a second end thereof. The first end of the one or more gas inlets 1842 may open into the plasma cavity 1849 at the upper-most point of the inner diameter 1850 of expanding section 1846. Similarly, the first end of the one or more gas inlets 1842 may open into the plasma cavity 1849 at any height interval along the inner diameter 1850 of the expanding section 1846. Although not shown, two gas inlets 1842 can be disposed at opposite sides of the expanding section 1846 to create a swirling flow pattern or “vortex” flow into the expanding section 1846 which helps mix the gases within the plasma cavity 1849.

The first electrode 1841 may have an expanding section 1846 that houses the plasma cavity 1849. The expanding section 1846 may be in fluid communication with the gas inlet 1842 as described above. The expanding section 1846 may be an annular member that has an inner surface or diameter 1850 that gradually increases from an upper portion 1847 thereof to a lower portion 1848 thereof. As such, the distance between the first electrode 1841 and the second electrode 1852 is variable. That varying distance helps control the formation and stability of the plasma generated within the plasma cavity 1849.

The expanding section 1846 may resemble a cone or “funnel,” as is shown in FIGS. 18 and 19. The inner surface 1850 of the expanding section 1846 may gradually slope from the upper portion 1847 to the lower portion 1848 of the expanding section 1846. The slope or angle of the inner diameter 1850 can vary depending on process requirements and/or process limitations. The length or height of the expanding section 1846 can also vary depending on specific process requirements and/or limitations. The slope of the inner diameter 1850, or the height of the expanding section 1486, or both may vary depending on the volume of plasma needed for processing.

Not wishing to be bound by theory, it is believed that the variation in distance between the two electrodes 1841, 1852 allows the plasma formed in the plasma cavity 1849 to find the necessary power level to sustain itself within some portion of the plasma cavity 1849, if not throughout the entire plasma cavity 1849. The plasma within the plasma cavity 1849 is therefore less dependent on pressure, allowing the plasma to be generated and sustained within a wider operating window. As such, a more repeatable and reliable plasma can be formed within the lid assembly 1840.

The first electrode 1841 can be constructed from any process compatible materials, such as aluminum, anodized aluminum, nickel plated aluminum, nickel plated aluminum 6061-T6, stainless steel as well as combinations and alloys thereof, for example. In one or more embodiments, the entire first electrode 1841 or portions thereof are nickel coated to reduce unwanted particle formation. Preferably, at least the inner surface 1850 of the expanding section 1846 is nickel plated.

The second electrode 1852 can include one or more stacked plates. When two or more plates are desired, the plates should be in electrical communication with one another. Each of the plates should include a plurality of apertures or gas passages to allow the one or more gases from the plasma cavity 1849 to flow through.

The lid assembly 1840 may further include an isolator ring 1851 to electrically isolate the first electrode 1841 from the second electrode 1852. The isolator ring 1851 can be made from aluminum oxide or any other insulative, process compatible material. Preferably, the isolator ring 1851 surrounds or substantially surrounds at least the expanding section 1846.

The second electrode 1852 may include a top plate 1853, distribution plate 1858 and blocker plate 1862 separating the substrate in the processing chamber from the plasma cavity. The top plate 1853, distribution plate 1858 and blocker plate 1862 are stacked and disposed on a lid rim 1864 which is connected to the chamber body 1801 as shown in FIG. 18. As is known in the art, a hinge assembly (not shown) can be used to couple the lid rim 1864 to the chamber body 1801. The lid rim 1864 can include an embedded channel or passage 1865 for housing a heat transfer medium. The heat transfer medium can be used for heating, cooling, or both, depending on the process requirements.

The top plate 1853 may include a plurality of gas passages or apertures 1856 formed beneath the plasma cavity 1849 to allow gas from the plasma cavity 149 to flow therethrough. The top plate 1853 may include a recessed portion 1854 that is adapted to house at least a portion of the first electrode 1841. In one or more embodiments, the apertures 1856 are through the cross section of the top plate 1853 beneath the recessed portion 1854. The recessed portion 1854 of the top plate 1853 can be stair stepped as shown in FIG. 19 to provide a better sealed fit therebetween. Furthermore, the outer diameter of the top plate 1853 can be designed to mount or rest on an outer diameter of the distribution plate 1858 as shown in FIG. 19. An o-ring type seal, such as an elastomeric o-ring 1855, can be at least partially disposed within the recessed portion 1854 of the top plate 1853 to ensure a fluid-tight contact with the first electrode 1841. Likewise, an o-ring type seal 1857 can be used to provide a fluid-tight contact between the outer perimeters of the top plate 1853 and the distribution plate 1858.

The distribution plate 1858 is substantially disc-shaped and includes a plurality of apertures 1861 or passageways to distribute the flow of gases therethrough. The apertures 1861 can be sized and positioned about the distribution plate 1858 to provide a controlled and even flow distribution to the processing zone 1810 where the substrate to be processed is located. Furthermore, the apertures 1861 prevent the gas(es) from impinging directly on the substrate surface by slowing and re-directing the velocity profile of the flowing gases, as well as evenly distributing the flow of gas to provide an even distribution of gas across the surface of the substrate.

The distribution plate 1858 can also include an annular mounting flange 1859 formed at an outer perimeter thereof. The mounting flange 1859 can be sized to rest on an upper surface of the lid rim 1864. An o-ring type seal, such as an elastomeric o-ring, can be at least partially disposed within the annular mounting flange 1859 to ensure a fluid-tight contact with the lid rim 1864.

The distribution plate 1858 may include one or more embedded channels or passages 1860 for housing a heater or heating fluid to provide temperature control of the lid assembly 1840. A resistive heating element can be inserted within the passage 1860 to heat the distribution plate 1858. A thermocouple can be connected to the distribution plate 1858 to regulate the temperature thereof. The thermocouple can be used in a feedback loop to control electric current applied to the heating element.

Alternatively, a heat transfer medium can be passed through the passage 1860. The one or more passages 1860 can contain a cooling medium, if needed, to better control temperature of the distribution plate 1858 depending on the process requirements within the chamber body 1801. As mentioned above, any heat transfer medium may be used, such as nitrogen, water, ethylene glycol, or mixtures thereof, for example.

The lid assembly 1840 may be heated using one or more heat lamps (not shown). The heat lamps are arranged about an upper surface of the distribution plate 1858 to heat the components of the lid assembly 1840 including the distribution plate 1858 by radiation.

The blocker plate 1862 is optional and may be disposed between the top plate 1853 and the distribution plate 1858. Preferably, the blocker plate 1862 is removably mounted to a lower surface of the top plate 1853. The blocker plate 1862 should make good thermal and electrical contact with the top plate 1853. The blocker plate 1862 may be coupled to the top plate 1853 using a bolt or similar fastener. The blocker plate 1862 may also be threaded or screwed onto an out diameter of the top plate 1853.

The blocker plate 1862 includes a plurality of apertures 1863 to provide a plurality of gas passages from the top plate 1853 to the distribution plate 1858. The apertures 1863 can be sized and positioned about the blocker plate 1862 to provide a controlled and even flow distribution the distribution plate 1858.

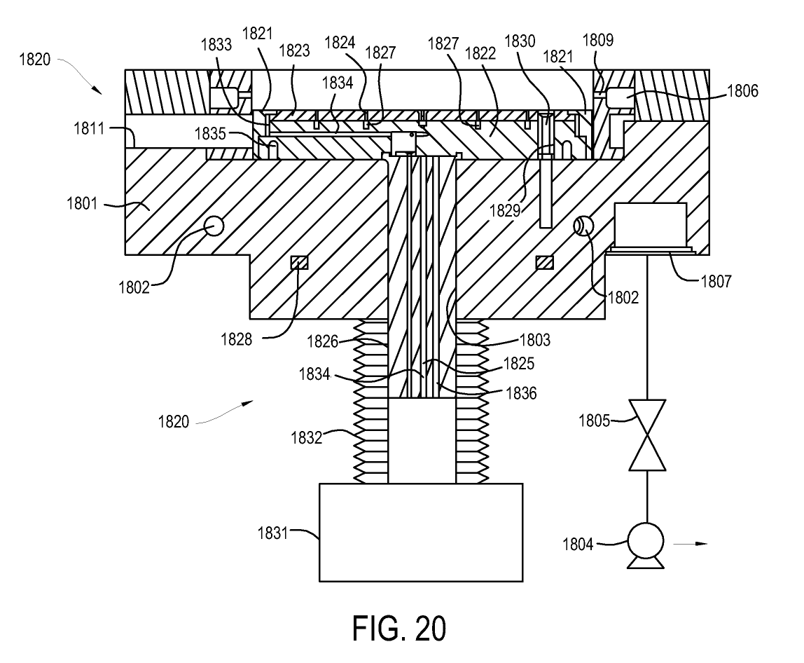

FIG. 20 shows a partial cross sectional view of an illustrative support assembly 1820. The support assembly 1820 can be at least partially disposed within the chamber body 1801. The support assembly 1820 can include a support member 1822 to support the substrate for processing within the chamber body 1801. The support member 1822 can be coupled to a lift mechanism 1831 through a shaft 1826 which extends through a centrally-located opening 1803 formed in a bottom surface of the chamber body 1801. The lift mechanism 1831 can be flexibly sealed to the chamber body 1801 by a bellows 1832 that prevents vacuum leakage from around the shaft 1826. The lift mechanism 1831 allows the support member 1822 to be moved vertically within the chamber body 1801 between a process position and a lower, transfer position. The transfer position is slightly below the opening of the slit valve 1811 formed in a sidewall of the chamber body 1801.

In one or more embodiments, the substrate may be secured to the support assembly 1820 using a vacuum chuck. The top plate 1823 can include a plurality of holes 1284 in fluid communication with one or more grooves 1827 formed in the support member 1822. The grooves 1827 are in fluid communication with a vacuum pump (not shown) via a vacuum conduit 1825 disposed within the shaft 1826 and the support member 1822. Under certain conditions, the vacuum conduit 1825 can be used to supply a purge gas to the surface of the support member 1822 when the substrate is not disposed on the support member 1822. The vacuum conduit 1825 can also pass a purge gas during processing to prevent a reactive gas or byproduct from contacting the backside of the substrate.

The support member 1822 can include one or more bores 1829 formed therethrough to accommodate a lift pin 1830. Each lift pin 1830 is typically constructed of ceramic or ceramic-containing materials, and are used for substrate-handling and transport. Each lift pin 1830 is slidably mounted within the bore 1829. The lift pin 1830 is moveable within its respective bore 1829 by engaging an annular lift ring 1828 disposed within the chamber body 1801. The lift ring 1828 is movable such that the upper surface of the lift-pin 1830 can be located above the substrate support surface of the support member 1822 when the lift ring 1828 is in an upper position. Conversely, the upper surface of the lift-pins 1830 is located below the substrate support surface of the support member 1822 when the lift ring 1828 is in a lower position. Thus, part of each lift-pin 1830 passes through its respective bore 1829 in the support member 1822 when the lift ring 1828 moves from either the lower position to the upper position.

When activated, the lift pins 1830 push against a lower surface of the substrate 2870, lifting the substrate off the support member 1822. Conversely, the lift pins 1830 may be de-activated to lower the substrate, thereby resting the substrate on the support member 1822.

The support assembly 1820 can include an edge ring 1821 disposed about the support member 1822. The edge ring 1821 is an annular member that is adapted to cover an outer perimeter of the support member 1822 and protect the support member 1822. The edge ring 1821 can be positioned on or adjacent the support member 1822 to form an annular purge gas channel 1833 between the outer diameter of support member 1822 and the inner diameter of the edge ring 1821. The annular purge gas channel 1833 can be in fluid communication with a purge gas conduit 1834 formed through the support member 1822 and the shaft 1826. Preferably, the purge gas conduit 1834 is in fluid communication with a purge gas supply (not shown) to provide a purge gas to the purge gas channel 1833. In operation, the purge gas flows through the conduit 1834, into the purge gas channel 1833, and about an edge of the substrate disposed on the support member 1822. Accordingly, the purge gas working in cooperation with the edge ring 1821 prevents deposition at the edge and/or backside of the substrate.

The temperature of the support assembly 1820 is controlled by a fluid circulated through a fluid channel 1835 embedded in the body of the support member 1822. The fluid channel 1835 may be in fluid communication with a heat transfer conduit 1836 disposed through the shaft 1826 of the support assembly 1820. The fluid channel 1835 may be positioned about the support member 1822 to provide a uniform heat transfer to the substrate receiving surface of the support member 1822. The fluid channel 1835 and heat transfer conduit 1836 can flow heat transfer fluids to either heat or cool the support member 1822. The support assembly 1820 can further include an embedded thermocouple (not shown) for monitoring the temperature of the support surface of the support member 1822.

In operation, the support member 1822 can be elevated to a close proximity of the lid assembly 1840 to control the temperature of the substrate being processed. As such, the substrate can be heated via radiation emitted from the distribution plate 1858 that is controlled by the heating element 1874. Alternatively, the substrate can be lifted off the support member 1822 to close proximity of the heated lid assembly 1840 using the lift pins 1830 activated by the lift ring 1828.

The modified chamber can further include an oxidizing gas supply to provide an oxidizing gas, for example, O₂, N₂O, NO, and combinations thereof in fluid communication with an auxiliary gas inlet 1892 into the chamber 1800 as shown in FIG. 18. In an alternative embodiment, shown in FIG. 19, oxidizing gas supply 1890 can be in fluid communication with an auxiliary gas inlet 1893 into the plasma volume or cavity 1849. In another variant (not shown), the oxidizing gas can be connected to a remote plasma source which generates an oxidizing plasma remote from the chamber 1800 and delivers the oxidizing plasma into the chamber 1800. A reducing gas supply 1894 can supply a reducing gas such as hydrogen to the chamber 1800 by a reducing gas inlet 1896. Other gas supplies can include inert gas supplies and inlets (not shown) to deliver inert gases such as helium, argon, and others. The system may also include a nitrogen source gas for so that a nitridation reaction on a material layer can be performed. Flow of each of these gases can be regulated by mass or volume flow controllers in communication with a system controller (not shown).

In another variant of chamber 1800, a lamp or laser heating feature of the type described above with respect to FIGS. 16 and 17 may be utilized to rapidly heat the device being processed. Furthermore, a cooling system of the type described above with respect to FIG. 13B for rapidly cooling the support member 1822 and substrate to temperatures to perform the cyclical oxidation and etch process described above on a material layer on the substrate. The heating and cooling system and other components described with respect to chamber 1800 can be operatively connected to a system controller to control the various system parameters. Desirably, the system controller can control the process to perform a complete process sequence of an oxidation and/or nitridation and an etching step can be completed in the chambers in less than about three minutes. In specific embodiments, a complete process sequence of an oxidation and/or nitridation and an etching step can be completed in the chambers in less than about two minutes, and in more specific embodiments, a complete process sequence of an oxidation and/or nitridation and an etching step can be completed in the chambers in less than about one minute, for example 45 seconds or 30 seconds.

An exemplary dry etch process for removing an oxide layer using an ammonia (NH₃) and nitrogen trifluoride (NF₃) gas mixture performed within the processing chamber 1800 will now be described. Referring to FIG. 18 and FIG. 20, the dry etch process begins by placing the substrate, into the processing zone 1810. The substrate is typically placed into the chamber body 1801 through the slit valve opening 1811 and disposed on the upper surface of the support member 1822. The substrate is chucked to the upper surface of the support member 1822, and an edge purge is passed through the channel 1833. The substrate may be chucked to the upper surface of the support member 1822 by pulling a vacuum through the holes 1824 and grooves 1827 that are in fluid communication with a vacuum pump via conduit 1825. The support member 1822 is then lifted to a processing position within the chamber body 1801, if not already in a processing position. The chamber body 1801 may be maintained at a temperature of between 50° C. and 80° C., more preferably at about 65° C. This temperature of the chamber body 1801 is maintained by passing a heat transfer medium through the fluid channel 1802.

The substrate which may have one or more material layers of the type described above with respect to FIGS. 3A-3C, 5A-5E, 7A-7D, 8A-8B, 10A-10D or 11A-11C is cooled below 65° C., such as between 15° C. and 50° C., by passing a heat transfer medium or coolant through the fluid channel 1835 formed within the support assembly 1820. In one embodiment, the substrate is maintained below room temperature. In another embodiment, the substrate is maintained at a temperature of between 22° C. and 40° C. Typically, the support member 1822 is maintained below about 22° C. to reach the desired substrate temperatures specified above. To cool the support member 1822, the coolant is passed through the fluid channel 135. A continuous flow of coolant provides better control the temperature of the support member 1822. Alternatively, the substrate can be cooled using a system of the type described with respect to FIG. 13B.

The ammonia and nitrogen trifluoride gases are then introduced into the chamber 1800 to form a cleaning gas mixture. The amount of each gas introduced into the chamber is variable and may be adjusted to accommodate, for example, the thickness of the oxide layer to be removed, the geometry of the substrate or other material surface being cleaned, the volume capacity of the plasma, the volume capacity of the chamber body 1801, as well as the capabilities of the vacuum system coupled to the chamber body 1801. In one aspect, the gases are added to provide a gas mixture having at least a 1:1 molar ratio of ammonia to nitrogen trifluoride. In another aspect, the molar ratio of the gas mixture is at least about 3 to 1 (ammonia to nitrogen trifluoride). In specific embodiments, the gases are introduced in the chamber 100 at a molar ratio of from 5:1 (ammonia to nitrogen trifluoride) to 30:1. More specifically in some embodiments, the molar ratio of the gas mixture is from about 5 to 1 (ammonia to nitrogen trifluoride) to about 10 to 1. The molar ratio of the gas mixture may also fall between about 10:1 (ammonia to nitrogen trifluoride) to about 20:1.

A purge gas or carrier gas may also be added to the gas mixture. Any suitable purge/carrier gas may be used, such as argon, helium, hydrogen, nitrogen, or mixtures thereof, for example. In some embodiments, the overall gas mixture is from about 0.05% to about 20% by volume of ammonia and nitrogen trifluoride; the remainder being the carrier gas. In one embodiment, the purge or carrier gas is first introduced into the chamber body 1801 before the reactive gases to stabilize the pressure within the chamber body 1801.

The operating pressure within the chamber body 1801 can be variable. In some embodiments, the pressure is maintained between about 500 mTorr and about 30 Torr. In specific embodiments, the pressure is maintained between about 1 Torr and about 10 Torr. In one or more embodiments, the operating pressure within the chamber body 1801 is maintained between about 3 Torr and about 6 Torr.

In some embodiments, RF power from about 5 to about 600 Watts is applied to the first electrode 141 to ignite a plasma of the gas mixture within the plasma cavity 149. In a specific example, the RF power is less than 100 Watts. In a more specific example, the frequency at which the power is applied is relatively low, such as less than 100 kHz. In specific embodiments, the frequency ranges from about 50 kHz to about 90 kHz. Because of the lower electrode 1853, the blocker plate 1862 and the distribution plate 1858, plasma ignited within the plasma cavity 1849 does not contact the substrate within the processing zone 1810, but instead remains trapped within the plasma cavity 1849. The plasma is thus remotely generated in the plasma cavity 1849 with respect to the processing zone 1810. That is, the processing chamber 1800 provides two distinct regions: the plasma cavity 1849 and the processing zone 1810. These regions are not communicative with each other in terms of plasmas formed in the plasma cavity 1849, but are communicative with each other in terms of reactive species formed in the plasma cavity 1849. Specifically, reactive species resulting from the plasma can exit the plasma cavity 1849 via the apertures 1856, pass through the apertures 1863 of the blocker plate 1862, and enter into the processing zone 1810 via apertures 1861 of the distribution plate 1858.

The plasma energy dissociates the ammonia and nitrogen trifluoride gases into reactive species that combine to form a highly reactive ammonia fluoride (NH₄F) compound and/or ammonium hydrogen fluoride (NH₄F.HF) in the gas phase. These molecules flow through the apertures 1856, 1863 and 1861 to react with the oxide layer of the material layer on the substrate. In one embodiment, the carrier gas is first introduced into the chamber 1800, a plasma of the carrier gas is generated in the plasma cavity 1849, and then the reactive gases, ammonia and nitrogen trifluoride, are added to the plasma. As noted previously, the plasma formed in the plasma cavity 1849 does not reach the substrate disposed within the processing region or zone 1810.

Not wishing to be bound by theory, it is believed that the etchant gas, NH₄F and/or NH₄F.HF, reacts with the silicon oxide surface to form ammonium hexafluorosilicate (NH₄)₂SiF₆, NH₃, and H₂O products. The NH₃, and H₂O are vapors at processing conditions and removed from the chamber 1800 by the vacuum pump 1804. In particular, the volatile gases flow through the apertures 1809 formed in the liner 1808 into the pumping channel 1806 before the gases exit the chamber 1800 through the vacuum port 1807 into the vacuum pump 1804. A thin film of (NH₄)₂SiF₆ is left behind on the surface of the material layer being processed. This reaction mechanism can be summarized as follows:

NF₃+NH₃→NH₄F+NH₄F.HF+N₂

6NH₄F+SiO₂→(NH₄)₂SiF₆+H₂O

(NH₄)₂SiF₆+heat→NH₃+HF+SiF₄

After the thin film is formed on the substrate surface, the support member 1822 having the substrate supported thereon is elevated to an anneal position in close proximity to the heated distribution plate 1858. The heat radiated from the distribution plate 1858 should be sufficient to dissociate or sublimate the thin film of (NH₄)₂SiF₆ into volatile SiF₄, NH₃, and HF products. These volatile products are then removed from the chamber by the vacuum pump 1804 as described above. In effect, the thin film is boiled or vaporized off from the material layer on the substrate, leaving behind an exposed oxide surface. In one embodiment, a temperature of 75° C. or more is used to effectively sublimate and remove the thin film from the material surface. In specific embodiments, a temperature of 100° C. or more is used, such as between about 115° C. and about 200° C.

The thermal energy to dissociate the thin film of (NH₄)₂SiF₆ into its volatile components is convected or radiated by the distribution plate 1858. As described above, a heating element 1860 may be directly coupled to the distribution plate 1858, and is activated to heat the distribution plate 1858 and the components in thermal contact therewith to a temperature between about 75° C. and 250° C. In one aspect, the distribution plate 1858 is heated to a temperature of between 100° C. and 200° C., such as about 120° C.

The lift mechanism 1831 can elevate the support member 1822 toward a lower surface of the distribution plate 1858. During this lifting step, the substrate is secured to the support member 1822, such as by a vacuum chuck or an electrostatic chuck. Alternatively, the substrate can be lifted off the support member 1822 and placed in close proximity to the heated distribution plate 1858 by elevating the lift pins 1830 via the lift ring 1828.

The distance between the upper surface of the substrate having the thin film thereon and the distribution plate 1858 can be determined by experimentation. The spacing required to efficiently and effectively vaporize the thin film without damaging the underlying substrate will depend on several factors, including, but not limited to the thickness of the film. In one or more embodiments, a spacing of between about 0.254 mm (10 mils) and 5.08 mm (200 mils) is effective. Additionally, the choice of gases will also impact the spacing.

During etching, it is desirable to keep the pedestal at a relatively low temperature, for example, in the range of about 20° C. to about 60° C., less than about 50° C., specifically, less than about 45° C., less than about 40° C., or less than about 35° C. In a specific embodiment, during etching in the chamber 1800, the temperature is maintained at about 30° C. +/− about 5° C. to aid in condensing the etchant and control selectivity of the etching reaction. Removal of the film or oxide layer can further include using the lift mechanism 1831 to elevate the support member 1822 toward a lower surface of the distribution plate 1858. Alternatively, the substrate can be lifted off the support member 1822 and placed in close proximity to the heated distribution plate 1858 by elevating the lift pins 1830 via the lift ring 1828. It is desirable to heat the distribution plate to a temperature in excess of about 100° C. so that the material surface being etched is heated above about 100° C. In specific embodiments, the distribution plate 1858 is heated to at least a at least about 140° C. about 140° C., at least about 150° C., at least about 160° C., at least about 170° C., at least about 180° C., or at least about 140° C., to ensure that the material surface achieves a temperature sufficient for sublimation of SiO₂. Thus, one non-limiting, exemplary dry etch process in the chamber 1880 may include supplying ammonia or (NH₃) or nitrogen trifluoride (NF₃) gas, or an anhydrous hydrogen fluoride (HF) gas mixture with a remote plasma into the plasma volume 1849, which condenses on SiO₂ at low temperatures (e.g., −30° C.) and reacts to form a compound which is subsequently sublimated in the chamber 1800 at moderate temperature (e.g., >100° C.) to etch SiO₂. The sublimation completes the etching of the material surface, and the byproducts can be removed by vacuum pump 1804. It is desirable to keep the chamber walls at a temperature between the temperature of the substrate support and the gas distribution plate to prevent etchant and byproduct condensation on the walls of the chamber 1800.

Once the film or oxide layer has been removed from the material surface, the material surface is ready for the subsequent oxidation process to form an oxide layer. The dry etch processor 1832 is purged and evacuated. The purge may be accomplished by flowing inert gas, for example nitrogen, hydrogen or argon into the process chamber, either directly through gas inlets or through distribution plate 1858. The material layer is then further processed using an oxidation process to form the oxide layer. It will be appreciated that the step of removing a film or oxide layer from the material surface is not necessarily performed first. As will be appreciated from the description of the processes with respect to FIGS. 3A-3C, 5A-5E, 7A-7D, 8A-8B, 10A-10D or 11A-11C, in some embodiments, a step of oxidizing a surface of a material layer to form an oxide layer will be performed prior to removing a portion of the oxide layer or film from the material layer.

In one embodiment, the oxide layer is formed in the chamber 1800. In other embodiments, the oxide layer may be formed in a load-locked region (not shown) outside the slit valve opening 1811.

In embodiments in which the oxide layer is formed in the chamber 1800, oxidizing gas supply 1890 flows oxidizing gas directly into the chamber via inlet 1892. A suitable oxidizing gas can include one or more of oxygen, ozone, H₂O, H₂O₂, or a nitrogen oxide specie such as N₂O, NO or NO₂. The oxidizing gas is introduced into the chamber at a suitably low pressure. The chamber is then heated to an appropriate temperature so that an oxide layer grows on the material surface. In one or more embodiments, the chamber temperature is heated in the range of about 200° C. to about 800° C. In specific embodiments, the chamber is heated in the range of about 300° C. to about 400° C. To promote an oxidation reaction on the material being processed to form a material layer, for example as shown and described above with respect to FIGS. 3A-3C, 5A-5E, 7A-7D, 8A-8B, 10A-10D or 11A-11C.

In an alternative embodiment, an oxidizing gas, for example, oxygen or one of the other oxidizing gases, can be introduced through the cooled support member 1822 through gas channels in the support member to reduce premature decomposition of the oxidizing gas before it contacts the material surface onto which the oxide layer is to be formed.

In another alternative embodiment, the oxidizing gas supply 1890 may be in fluid communication with the plasma volume 1849 via a gas inlet (not shown), and an oxide layer can be formed on the material surface of the substrate introduction of an oxygen plasma. In another alternative embodiment, an oxidizing plasma can be formed in a remote plasma oxidation source in fluid communication with the chamber 1800, similar to the arrangement shown in FIG. 13. A remote nitridation plasma can also be formed by supplying nitrogen to a remote plasma source. In still another embodiment, the substrate support 1822 can be biased with a radio frequency (RF) power source similar to the arrangement shown in FIG. 15.

Accordingly, in summary, formation of an oxide layer on a material surface can be accomplished in chamber 1800 by one or more of introduction of an oxidizing gas into the chamber and heating the material surface, introduction of an oxidizing plasma formed in a remote plasma source separate from plasma volume 1849, introduction of oxidizing gases into the plasma volume 1849 and delivery of the oxidizing plasma to the substrate on the support 1822, or by formation of a plasma using RF powered substrate support 1822 and introduction of oxidizing gases into the chamber. Exemplary and suitable pressures in the chamber 1800 are in the range of about 1 milli Torr to about 10 Torr.

In yet another alternative embodiment, precise heating of the material surface to form an oxide layer may be achieved through utilization of a lamp or laser heating feature of the type described above with respect to FIGS. 16 and 17. Such a lamp or laser heating feature may be utilized to rapidly heat the device being processed to a temperature in the range of 0° C. to 1000° C. In a specific embodiment, ozone can be used at the oxidizing gas, which can be introduced through a gas inlet or through the substrate support 1822, and ultraviolet light can be used to initiate a photochemical oxidation reaction. Such a reaction may be desirably performed in a load lock region outside the slit valve 1811.

After formation of an oxide layer oxidizing a surface of a material layer, the chamber 1800 can be purged again to remove the oxidizing gas and byproducts of the oxidation reaction(s). Purging can be achieved by flowing an inert gas into the chamber and/or with the vacuum pump 1804. The steps of formation of an oxide layer, etching (by plasma and sublimation) can be repeated cyclically within chamber 1800 until an oxide layer have a desired material thickness has been formed. Exemplary devices and process sequences are described above with respect to FIGS. 3A-3C, 5A-5E, 7A-7D, 8A-8B, 10A-10D or 11A-11C, and any of these processes can be performed in the single chamber 1800 described above.

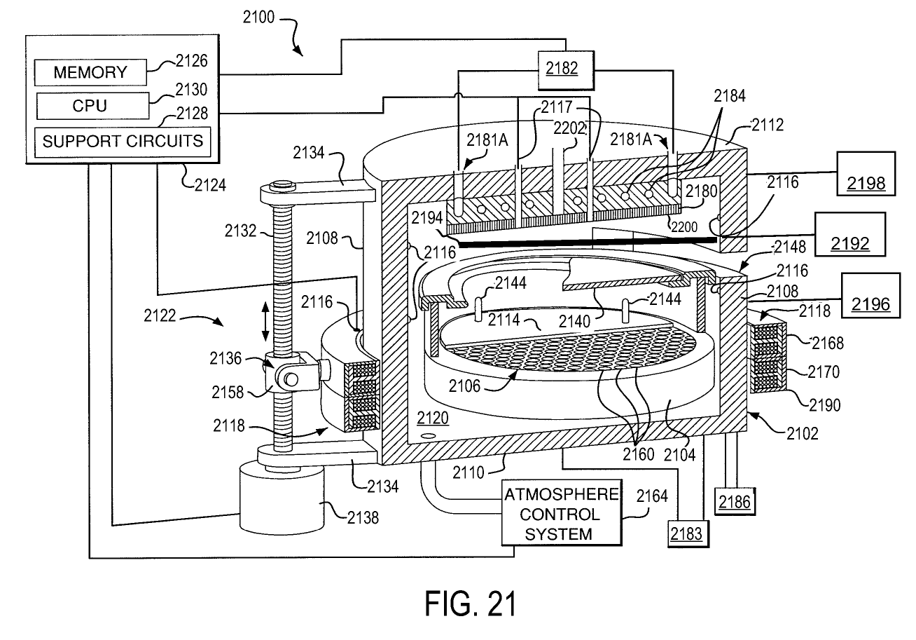

A single chamber rapid thermal processing (RTP) apparatus may also be used to perform the steps of formation of an oxide layer, etching (by plasma and sublimation) can be repeated cyclically within chamber until an oxide layer have a desired material thickness has been formed. Exemplary devices and process sequences are described above with respect to FIGS. 3A-3C, 5A-5E, 7A-7D, 8A-8B, 10A-10D or 11A-11C, and any of these processes can be performed in the single chamber described in FIG. 21. FIG. 21 shows an exemplary embodiment of a rapid thermal processing chamber 2100. The processing chamber 2100 includes a substrate support 2104, a chamber body 2102, having walls 2108, a bottom 2110, and a top 2112 defining an interior volume 2120. The walls 2108 typically include at least one substrate access port 2148 to facilitate entry and egress of a substrate 2140 (a portion of which is shown in FIG. 21). The access port may be coupled to a transfer chamber (not shown) or a load lock chamber (not shown) and may be selectively sealed with a valve, such as a slit valve (not shown). In one embodiment, the substrate support 2104 is annular and the chamber 2100 includes a radiant heat source 2106 disposed in an inside diameter of the substrate support 2104. The radiant heat source 2106 typically comprises a plurality of lamps. Examples of an RTP chamber that may be modified and a substrate support that may be used is described in U.S. Pat. No. 6,800,833 and United States Patent Application Publication No. 2005/0191044. In one embodiment of the invention, the chamber 2100 includes a reflector plate 2200 incorporating gas distribution outlets (described in more detail below) to distribute gas evenly over a substrate to allow rapid and controlled heating and cooling of the substrate. The plate 2200 can be heated and or cooled to facilitate oxidation and/or etching as described above.

The plate may be absorptive, reflective, or have a combination of absorptive and reflective regions. In a detailed embodiment, the plate may have regions, some within view of the pyrometers, some outside the view of the pyrometers. The regions within view of the pyrometers may be about one inch in diameter, if circular, or other shape and size as necessary. The regions within view of the probes may be very highly reflective over the wavelength ranges observed by the pyrometers. Outside the pyrometer wavelength range and field of view, the plate can range from reflective to minimize radiative heat loss, to absorptive to maximize radiative heat loss to allow for shorter thermal exposure.

The RTP chamber 2100 shown in FIG. 21 also includes a cooling block 2180 adjacent to, coupled to, or formed in the top 2112. Generally, the cooling block 2180 is spaced apart and opposing the radiant heat source 2106. The cooling block 2180 comprises one or more coolant channels 2184 coupled to an inlet 2181A and an outlet 2181 B. The cooling block 2180 may be made of a process resistant material, such as stainless steel, aluminum, a polymer, or a ceramic material. The coolant channels 2184 may comprise a spiral pattern, a rectangular pattern, a circular pattern, or combinations thereof and the channels 2184 may be formed integrally within the cooling block 2180, for example by casting the cooling block 2180 and/or fabricating the cooling block 2180 from two or more pieces and joining the pieces. Additionally or alternatively, the coolant channels 184 may be drilled into the cooling block 2180.

The inlet 2181A and outlet 2181B may be coupled to a coolant source 2182 by valves and suitable plumbing and the coolant source 2182 is in communication with the system controller 2124 to facilitate control of pressure and/or flow of a fluid disposed therein. The fluid may be water, ethylene glycol, nitrogen (N₂), helium (He), or other fluid used as a heat-exchange medium.

In the embodiment shown, the substrate support 2104 is optionally adapted to magnetically levitate and rotate within the interior volume 2120. The substrate support 2104 shown is capable of rotating while raising and lowering vertically during processing, and may also be raised or lowered without rotation before, during, or after processing. This magnetic levitation and/or magnetic rotation prevents or minimizes particle generation due to the absence or reduction of moving parts typically required to raise/lower and/or rotate the substrate support.

The chamber 2100 also includes a window 2114 made from a material transparent to heat and light of various wavelengths, which may include light in the infra-red (IR) spectrum, through which photons from the radiant heat source 2106 may heat the substrate 2140. In one embodiment, the window 2114 is made of a quartz material, although other materials that are transparent to light maybe used, such as sapphire. The window 2114 may also include a plurality of lift pins 2144 coupled to an upper surface of the window 2114, which are adapted to selectively contact and support the substrate 2140, to facilitate transfer of the substrate into and out of the chamber 2100. Each of the plurality of lift pins 2144 are configured to minimize absorption of energy from the radiant heat source 2106 and may be made from the same material used for the window 2114, such as a quartz material. The plurality of lift pins 2144 may be positioned and radially spaced from each other to facilitate passage of an end effector coupled to a transfer robot (not shown). Alternatively, the end effector and/or robot may be capable of horizontal and vertical movement to facilitate transfer of the substrate 2140.

In one embodiment, the radiant heat source 2106 includes a lamp assembly formed from a housing which includes a plurality of honeycomb tubes 2160 in a coolant assembly (not shown) coupled to a second coolant source 2183. The second coolant source 2183 may be one or a combination of water, ethylene glycol, nitrogen (N₂), and helium (He). The housing walls 2108, 2110 may be made of a copper material or other suitable material having suitable coolant channels formed therein for flow of the coolant from the second coolant source 2183. The coolant cools the housing of the chamber 2100 so that the housing is cooler than the substrate 2140. Each tube 2160 may contain a reflector and a high-intensity lamp assembly or an IR emitter from which is formed a honeycomb like pipe arrangement. This close-packed hexagonal arrangement of pipes provides radiant energy sources with high power density and good spatial resolution. In one embodiment, the radiant heat source 2106 provides sufficient radiant energy to thermally process the substrate, for example, annealing a silicon layer disposed on the substrate 2140. The radiant heat source 2106 may further comprise annular zones, wherein the voltage supplied to the plurality of tubes 2160 by controller 2124 may varied to enhance the radial distribution of energy from the tubes 2160. Dynamic control of the heating of the substrate 2140 may be effected by the one or more temperature sensors 2117 adapted to measure the temperature across the substrate 2140.

In the embodiment shown, an optional stator assembly 2118 circumscribes the walls 2108 of the chamber body 2102 and is coupled to one or more actuator assemblies 2122 that control the elevation of the stator assembly 2118 along the exterior of the chamber body 2102. In one embodiment (not shown), the chamber 2100 includes three actuator assemblies 2122 disposed radially about the chamber body, for example, at about 120° angles about the chamber body 2102. The stator assembly 2118 is magnetically coupled to the substrate support 2104 disposed within the interior volume 2120 of the chamber body 2102. The substrate support 2104 may comprise or include a magnetic portion to function as a rotor, thus creating a magnetic bearing assembly to lift and/or rotate the substrate support 2104. In one embodiment, at least a portion of the substrate support 2104 is partially surrounded by a trough (not shown) that is coupled to a fluid source 2186, which may include water, ethylene glycol, nitrogen (N₂), helium (He), or combinations thereof, adapted as a heat exchange medium for the substrate support. The stator assembly 2118 may also include a housing 2190 to enclose various parts and components of the stator assembly 2118. In one embodiment, the stator assembly 2118 includes a drive coil assembly 2168 stacked on a suspension coil assembly 2170. The drive coil assembly 168 is adapted to rotate and/or raise/lower the substrate support 2104 while the suspension coil assembly 2170 may be adapted to passively center the substrate support 2104 within the processing chamber 2100. Alternatively, the rotational and centering functions may be performed by a stator having a single coil assembly.

An atmosphere control system 2164 is also coupled to the interior volume 2120 of the chamber body 2102. The atmosphere control system 2164 generally includes throttle valves and vacuum pumps for controlling chamber pressure. The atmosphere control system 2164 may additionally include gas sources for providing process or other gases to the interior volume 2120. The atmosphere control system 2164 may also be adapted to deliver process gases for thermal deposition processes, thermal etch processes, and in-situ cleaning of chamber components. The atmosphere control system works in conjunction with the showerhead gas delivery system.

The chamber 2100 also includes a controller 2124, which generally includes a central processing unit (CPU) 2130, support circuits 128 and memory 2126. The CPU 2130 may be one of any form of computer processor that can be used in an industrial setting for controlling various actions and sub-processors. The memory 2126, or computer-readable medium, may be one or more of readily available memory such as random access memory (RAM), read only memory (ROM), floppy disk, hard disk, or any other form of digital storage, local or remote, and is typically coupled to the CPU 2130. The support circuits 2128 are coupled to the CPU 2130 for supporting the controller 2124 in a conventional manner. These circuits include cache, power supplies, clock circuits, input/output circuitry, subsystems, and the like.

In one embodiment, each of the actuator assemblies 122 generally comprise a precision lead screw 2132 coupled between two flanges 2134 extending from the walls 108 of the chamber body 2102. The lead screw 2132 has a nut 2158 that axially travels along the lead screw 2132 as the screw rotates. A coupling 2136 is coupled between the stator 2118 and nut 2158 so that as the lead screw 2132 is rotated, the coupling 2136 is moved along the lead screw 2132 to control the elevation of the stator 2118 at the interface with the coupling 2136. Thus, as the lead screw 2132 of one of the actuators 2122 is rotated to produce relative displacement between the nuts 2158 of the other actuators 2122, the horizontal plane of the stator 2118 changes relative to a central axis of the chamber body 2102.

In one embodiment, a motor 2138, such as a stepper or servo motor, is coupled to the lead screw 2132 to provide controllable rotation in response to a signal by the controller 2124. Alternatively, other types of actuators 2122 may be utilized to control the linear position of the stator 2118, such as pneumatic cylinders, hydraulic cylinders, ball screws, solenoids, linear actuators and cam followers, among others.

The chamber 2100 also includes one or more sensors 2116, which are generally adapted to detect the elevation of the substrate support 2104 (or substrate 2140) within the interior volume 2120 of the chamber body 2102. The sensors 2116 may be coupled to the chamber body 2102 and/or other portions of the processing chamber 2100 and are adapted to provide an output indicative of the distance between the substrate support 2104 and the top 2112 and/or bottom 2110 of the chamber body 2102, and may also detect misalignment of the substrate support 2104 and/or substrate 2140.

The one or more sensors 2116 are coupled to the controller 2124 that receives the output metric from the sensors 2116 and provides a signal or signals to the one or more actuator assemblies 2122 to raise or lower at least a portion of the substrate support 2104. The controller 2124 may utilize a positional metric obtained from the sensors 2116 to adjust the elevation of the stator 2118 at each actuator assembly 2122 so that both the elevation and the planarity of the substrate support 2104 and substrate 2140 seated thereon may be adjusted relative to and a central axis of the RTP chamber 2100 and/or the radiant heat source 2106. For example, the controller 2124 may provide signals to raise the substrate support by action of one actuator 2122 to correct axial misalignment of the substrate support 2104, or the controller may provide a signal to all actuators 2122 to facilitate simultaneous vertical movement of the substrate support 2104.

The one or more sensors 2116 may be ultrasonic, laser, inductive, capacitive, or other type of sensor capable of detecting the proximity of the substrate support 2104 within the chamber body 2102. The sensors 2116, may be coupled to the chamber body 2102 proximate the top 2112 or coupled to the walls 2108, although other locations within and around the chamber body 2102 may be suitable, such as coupled to the stator 2118 outside of the chamber 2100. In one embodiment, one or more sensors 2116 may be coupled to the stator 2118 and are adapted to sense the elevation and/or position of the substrate support 2104 (or substrate 2140) through the walls 2108. In this embodiment, the walls 2108 may include a thinner cross-section to facilitate positional sensing through the walls 2108.

The chamber 2100 also includes one or more temperature sensors 2117, which may be adapted to sense temperature of the substrate 2140 before, during, and after processing. In the embodiment depicted in FIG. 21, the temperature sensors 2117 are disposed through the top 2112, although other locations within and around the chamber body 2102 may be used. The temperature sensors 2117 may be optical pyrometers, as an example, pyrometers having fiber optic probes. The sensors 2117 may be adapted to couple to the top 2112 in a configuration to sense the entire diameter of the substrate, or a portion of the substrate. The sensors 2117 may comprise a pattern defining a sensing area substantially equal to the diameter of the substrate, or a sensing area substantially equal to the radius of the substrate. For example, a plurality of sensors 2117 may be coupled to the top 2112 in a radial or linear configuration to enable a sensing area across the radius or diameter of the substrate. In one embodiment (not shown), a plurality of sensors 2117 may be disposed in a line extending radially from about the center of the top 2112 to a peripheral portion of the top 2112. In this manner, the radius of the substrate may be monitored by the sensors 2117, which will enable sensing of the diameter of the substrate during rotation.

As described herein, the chamber 2100 is adapted to receive a substrate in a “face-up” orientation, wherein the deposit receiving side or face of the substrate is oriented toward the plate 2200 and the “backside” of the substrate is facing the radiant heat source 2106. The “face-up” orientation may allow the energy from the radiant heat source 2106 to be absorbed more rapidly by the substrate 2140 as the backside of the substrate is sometimes less reflective than the face of the substrate.

Although the plate 2200 and radiant heat source 2106 is described as being positioned in an upper and lower portion of the interior volume 2120, respectively, the position of the cooling block 2180 and the radiant heat source 2106 may be reversed. For example, the cooling block 2180 may be sized and configured to be positioned within the inside diameter of the substrate support 2104, and the radiant heat source 2106 may be coupled to the top 2112. In this arrangement, the quartz window 2114 may be disposed between the radiant heat source 2106 and the substrate support 2104, such as adjacent the radiant heat source 106 in the upper portion of the chamber 2100. Although the substrate 2140 may absorb heat readily when the backside is facing the radiant heat source 2106, the substrate 2140 could be oriented in a face-up orientation or a face down orientation in either configuration. It will be understood that since fluorine-containing gases will be flowed into the chamber 2100, the materials in the chamber components will need be resistant to attack from fluorine-containing gases. This can be achieved, for example, by manufacturing coating the chamber components exposed to the fluorine-containing gas with a material such as sapphire or alumina. Other fluorine-resistant materials can be used as well.

The chamber 2100 further includes a remote plasma source 2192 for delivering a plasma into the chamber, which may be delivered into the chamber by distribution lance 2194. The lance 2194 may be a generally elongate conduit with one or more outlets for evenly distributing plasma products into the chamber 2100. Multiple lances 2194 may be used to inject at multiple radial locations in the chamber 2100. In one or more embodiments, the lance(s) 2194 are moveable such that they can be selectively moved in and out of the space between the substrate 2140 and the plate 2200. The modified chamber can further include an oxidizing gas supply to provide an oxidizing gas, for example, O₂, N₂O, NO, and combinations thereof in fluid communication with an auxiliary gas inlet 1892 into the chamber 1800 as shown in FIG. 18. An oxidizing gas supply 2196 can be in fluid communication with an auxiliary gas inlet into the chamber. An etching gas supply 2198 can supply an etching gas such as CF₄, CHF₃, SF₆, NH₃, NF₃, He, Ar, etc to the chamber 2100 by a reducing gas inlet. Other gas supplies can include inert gas supplies and inlets (not shown) to deliver inert gases such as helium, argon, a reducing gas such as hydrogen and others. Flow of each of these gases can be regulated by mass or volume flow controllers in communication with the system controller 2124. While the gas supplies 2196 and 2198 are shown as being in fluid communication through the side of the chamber 2100, it may be desirable to introduce the gases to a conduit in fluid communication with a showerhead, a lance or other device for evenly distributing the gases within the chamber 2100. An example of a gas introduction system 2202 is described further below. The gas supplies 2196, 2198 and other gas supplies can be in fluid communication with the gas introduction system 2202.

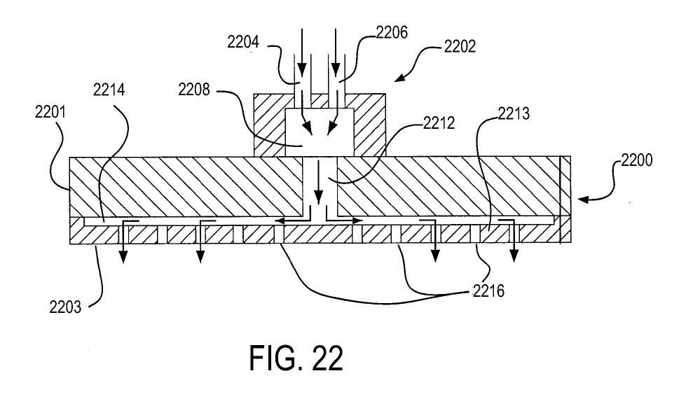

Further details on the reflector plate 2200 are shown in FIG. 22. Referring to FIG. 22, a reflector plate 2200 incorporating gas distribution outlets to distribute gas evenly over a substrate to allow rapid and controlled heating and cooling of the substrate is shown. The plate 2200 includes a top portion 2201 having a gas introduction system 2202, includes a first gas introduction port 204 and an optional second gas introduction port 2206 in communication with a gas mixing chamber 2208 for mixing gases the two gases. If only a single gas introduction port is provided, mixing chamber 2208 can be eliminated from the design. It will be understood that additional gas introduction ports can be provided as well. The gas introduction ports 2202, 2204 would of course be connected to a suitable gas source such as a tank of gas or gas supply system (not shown). Mixing chamber 2208 is in communication with gas flow passage 2212, which is in communication with gas channel 2214 and gas introduction openings 2216 formed in blocker plate 2213. The blocker plate 2213 may be a separate component fastened to the top portion 2201, or it may be integrally formed with the top portion. Of course, other designs are possible, including ones where two or more sets of individual openings of the type 2216 are provided for two or more gases so that gas mixing takes place after exiting the showerhead. The plate includes a face 2203 through which openings 2216 are formed.

In operation, cyclical oxidation and/or nitridation and etching can be performed in chamber 2100. An exemplary process includes supplying an etching plasma formed in remote plasma source 2192 into the chamber 2100. The etching plasma products can be supplied through the lance 2194 as shown, or the plasma products may be supplied through introduction port 2202. As described above, during at least part of the etching process, it is desirable to maintain the substrate and the material surface at a relatively low temperature. For example, portions of the etch process may be performed at low temperatures. During etching, it is desirable to keep the substrate and material surface at a relatively low temperature, for example, in the range of about 20° C. to about 60° C., less than about 50° C., specifically, less than about 45° C., less than about 40° C., or less than about 35° C. In a specific embodiment, during etching in the chamber 1800, the temperature is maintained at about 30° C. +/− about 5° C. to aid in condensing the etchant and control selectivity of the etching reaction. The temperature of the substrate and material surface can be maintained at a low temperature by flowing appropriate cooling gases, for example, helium through the plate 2200. Removal of the film or oxide layer by etching can further include using one or both of the lift pins 2144 and/or the stator assembly 2118 magnetically coupled to the substrate support 2104 to move the substrate being processed closer to the plate 2200.

To sublimate the film or layer formed during etching, the substrate is moved away from the plate 2200 by using the lift pins and or stator assembly 2118, and activating the radiant heat source 2106 to heat the substrate and the material surface being etched above about 100° C. In specific embodiments, the substrate 2140 is heated to at least about 140° C. about 140° C., at least about 150° C., at least about 160° C., at least about 170° C., at least about 180° C., or at least about 140° C., to ensure that the material surface achieves a temperature sufficient for sublimation of SiO₂. Thus, one non-limiting, exemplary etch process in the chamber 2100 may include supplying ammonia or (NH₃) or nitrogen trifluoride (NF₃) gas, or an anhydrous hydrogen fluoride (HF) gas mixture to the remote plasma source 2192, which condenses on SiO₂ at low temperatures (e.g., −30° C.) and reacts to form a compound which is subsequently sublimated in the chamber 210 at moderate temperature (e.g., >100° C.) to etch SiO₂. The sublimation completes the etching of the material surface, and the byproducts can be removed by atmosphere control system 2164 and/or flowing a purge gas. It is desirable to keep the chamber walls at a temperature between the temperature of the substrate support and the gas distribution plate to prevent etchant and byproduct condensation on the walls of the chamber 2100.

Forming an oxide layer on a material surface on the substrate can occur as follows. A spike thermal oxidation process can be used by rapidly activating the radiant heat source 2106 to form an oxide layer. In embodiments in which the oxide layer is formed in the chamber 2100, oxidizing gas supply 2196 flows oxidizing gas directly into the chamber via inlet. A suitable oxidizing gas can include one or more of oxygen, ozone, H₂O, H₂O₂, or a nitrogen oxide specie such as N₂O, NO or NO₂. The oxidizing gas is introduced into the chamber at a suitably low pressure. The chamber is then heated to an appropriate temperature so that an oxide layer grows on the material surface. In one or more embodiments, the chamber temperature is heated in the range of about 200° C. to about 800° C. In specific embodiments, the chamber is heated in the range of about 300° C. to about 400° C. To promote an oxidation reaction on the material being processed to form a material layer, for example as shown and described above with respect to FIGS. 3A-3C, 5A-5E, 7A-7D, 8A-8B, 10A-10D or 11A-11C. Alternatively, oxidation can be achieved by a remote plasma source 2192 (or a separate remote plasma source) having a supply of oxidizing gas can be used to generate an oxygen plasma, which can then be delivered into the chamber as described above. In another variant, an ultraviolet lamp source can be used to photochemically oxidize a material surface on the substrate. A suitable oxidizing gas can include one or more of oxygen, ozone, H₂O, H₂O₂, or a nitrogen oxide specie such as N₂O, NO or NO₂.

After formation of an oxide layer oxidizing a surface of a material layer, the chamber 2100 can be purged again to remove the oxidizing gas and byproducts of the oxidation reaction(s). Purging can be achieved by flowing an inert gas into the chamber and/or with the atmosphere control system 2164. The steps of formation of an oxide layer, etching (by plasma and sublimation) can be repeated cyclically within chamber 2100 until an oxide layer have a desired material thickness has been formed. Exemplary devices and process sequences are described above with respect to FIGS. 3A-3C, 5A-5E, 7A-7D, 8A-8B, 10A-10D or 11A-11C, and any of these processes can be performed in the single chamber 2100 described above.

Accordingly, in summary, formation of an oxide layer on a material surface can be accomplished in chamber 2100 by one or more of introduction of an oxidizing gas into the chamber and heating the material surface or introduction of an oxidizing plasma formed in a remote plasma source and delivery of the oxidizing plasma to the substrate on the support. Exemplary and suitable pressures in the chamber 2100 are in the range of about 1 milli Torr to about 10 Torr.

A system controller can control the process to perform a complete process sequence of an oxidation and/or nitridation and an etching step can be completed in the chambers in less than about three minutes. In specific embodiments, a complete process sequence of an oxidation and/or nitridation and an etching step can be completed in the chambers in less than about two minutes, and in more specific embodiments, a complete process sequence of an oxidation and/or nitridation and an etching step can be completed in the chambers in less than about one minute, for example 45 seconds or 30 seconds.

An alternative apparatus that can be used for the formation of an oxide layer and etching (by plasma and sublimation), which can be repeated cyclically until an oxide layer have a desired material thickness has been formed includes a furnace including remote or local plasma sources for generating an oxidizing plasma and etching plasma. Thus, the chamber 2100 described with respect to FIG. 21 could be replaced with a furnace suitably configured to cyclically heat and cool a substrate material surface to until an oxide layer have a desired material thickness has been formed. Exemplary devices and process sequences are described above with respect to FIGS. 3A-3C, 5A-5E, 7A-7D, 8A-8B, 10A-10D or 11A-110, and any of these processes can be performed in the single chamber 1800 described above.

Thus, a first aspect of the invention pertains to an apparatus for processing a substrate. A first embodiment of this aspect of the invention provide an apparatus for processing a substrate comprising: a process chamber having a substrate support disposed therein to support a substrate; a temperature control system to control the temperature of a substrate supported on the substrate support at a first temperature below about 100° C.; a gas source in fluid communication with the chamber to deliver at least an oxygen-containing gas, an inert gas and an etching gas into the process chamber; a plasma source in fluid communication with the process chamber to energize at least one of the oxygen-containing gas and the etching gas to form at least one of an oxidizing plasma or an etching plasma; and a heat source to heat the substrate to a second temperature greater than the first temperature.

In one variant of the first embodiment, the chamber is configured to deliver one of the etching gas and the etching plasma to the process chamber when the temperature of the substrate is at the first temperature and to deliver one of the oxidizing gas. In another variant, the second temperature is in the range of about 200° C. and 1000° C. in yet another variant, the chamber is configured to perform an etch process on a material layer on the substrate, at least a portion of the etch process being performed at the first temperature.

In still another variant of the first embodiment, the etch process comprises a dry etch process and the etching gas comprises a fluorine-containing gas. The first embodiment may include a gas source that further includes a nitrogen gas in communication with a plasma source. In one variant of the first embodiment, the etching gas is in fluid communication with the plasma source to form an etching plasma.

In another variant of the first embodiment, the temperature control system includes a cooling system to perform at least a portion of the etching process at a temperature below about 50° C. More specifically, the cooling system is configured to reduce the temperature of the substrate to a temperature in the range of about 25° C. to about 35° C. In one specific variant of the first embodiment, the apparatus is configured to cycle between the first temperature and second temperature in less than about three minutes.

In another specific variant of the first embodiment, the apparatus is configured to shape a material layer on the substrate, the material layer having a desired shape with a first width proximate a base of the desired shape that is substantially equivalent to a second width proximate a top of the desired shape, wherein the first and second width of the desired shape is between about 1 to about 30 nanometers. The apparatus may be configured to form a material layer comprising a floating gate. The apparatus may be configured to cyclically perform an etching process and on oxidation process on the material layer.

In one or more variants of the first embodiment, the oxidation process comprises rapid thermal oxidation, radical oxidation, plasma oxidation, chemical oxidation, or photochemical oxidation, and the etching process comprises at least one of wet or dry chemical etch, reactive ion etch, or plasma etch.

A second aspect of the invention pertains to a method of shaping a material layer on a substrate comprising: (a) processing a surface of a material layer to form an oxide or nitride-containing layer in a process chamber; (b) terminating formation of the oxide or nitride-containing layer;(c) removing at least some of the oxide or nitride-containing layer by an etching process in the same process chamber as in (a); and (d) repeating (a) through (c) in the same process chamber until the material layer is formed to a desired shape. In a variant of the method, (a) is performed at an initial rate and includes an oxidation process; (b) is terminated when the oxidation rate is about 90% of below the initial rate.

In another variant of the method, oxidizing the material layer to form the oxide layer is performed by at least one of wet or dry rapid thermal oxidation, radical oxidation, plasma oxidation, wet or dry chemical oxidation, or photochemical oxidation.

In another variant of the method, the etch process comprises at least one of wet or dry chemical etch, reactive ion etch, or plasma etch. In still another variant of the method, the material layer is formed into the desired shape having a first width proximate a base of the desired shape that is substantially equivalent to a second width proximate a top of the desired shape. In another variant of the method, the desired shape has an aspect ratio of between about 0.5 to about 20 nanometers. More specifically, the first and second width of the desired shape is between about 1 to about 30 nanometers. Still more specifically, a height of the desired shape is between about 1 to about 30 nanometers. The material layer may comprise a floating gate.

A second embodiment of an apparatus for performing a cyclical oxidation and etching process on a material layer, comprises: a processing chamber having a plurality of walls defining a processing region within the processing chamber including a substrate support to hold a substrate having a material layer within the processing region; an oxygen-containing gas supply, an inert gas supply and an etching gas supply in fluid communication with the processing chamber to deliver the oxygen-containing gas, the inert gas and the etching gas into the process chamber; a plasma source to form a plasma in a plasma generation region inside the chamber and at least one of the oxygen-containing gas and etching gas to energize the gas to form at least one of an oxygen plasma, and an etching plasma to contact the material layer; a heating system to heat the substrate within the chamber to a first temperature greater than about 100° C.; a cooling system to cool the substrate within the chamber to a second temperature below the first temperature; and a control system to cycle the substrate within the chamber between the first temperature the second temperature. In a variant of the second embodiment, the control system, the heating system and the cooling system are configured to cycle between the first temperature and second temperature within a time period of less than about three minutes.

In another variant of the second embodiment, the cooling system comprises a substrate support including passages for allowing cooling medium to flow therethrough. In still another variant of the second embodiment, the cooling system comprises a showerhead disposed in the chamber adjacent the substrate support, the showerhead in communication with a cooling fluid.

In another variant of the second embodiment, the heating system comprises at least one a light source and a resistive heater. In one variant, resistive heater is disposed within the substrate support. Alternatively, the resistive heater is disposed within the showerhead. In another variant of the second embodiment, the heating system includes a light source disposed so that light energy emitted by the light source contacts the material surface at an angle of incidence that optimizes absorption by the material being processed. In a specific configuration, the angle of incidence is at a Brewster angle for the material layer being processed.

In one specific configuration of the second embodiment, the process chamber has a ceiling plasma source comprising a power applicator including a coil disposed over the ceiling the coil coupled through an impedance match network a power source to generate plasma within the plasma generation region. In another variant, the etching gas comprises a fluorine-containing gas and the chamber further comprises a nitrogen gas source in communication with a plasma source.

A third embodiment of an apparatus for performing a cyclical oxidation and etching process on a material layer, comprises: a processing chamber a chamber body having a plurality of walls defining a processing region within the processing chamber including a substrate support to hold a substrate having a material layer within the processing region; a lid assembly disposed on an upper surface of the chamber body, the lid assembly comprising a first electrode and a second electrode that define a plasma cavity therebetween, wherein the second electrode is heated and adapted to heat the substrate; an oxygen-containing gas supply, an inert gas supply and an etching gas supply in fluid communication with at least one the process chamber and lid assembly to deliver the oxygen-containing gas, the inert gas and the etching gas into one of the process chamber and the lid; a heating system to heat the substrate within the chamber to a first temperature greater than about 100° C.; a cooling system to cool the substrate within the chamber to a second temperature below the first; and a control system to cycle the substrate within the chamber between the first temperature the second temperature.

In one variant of the third embodiment, the oxidizing gas is in fluid communication with the lid assembly to form an oxidizing plasma to process the material layer. In another variant of the third embodiment, the etching gas is in fluid communication with the lid assembly to form an etching plasma to process the material layer. In a specific variant, the etching gas includes a fluorine-containing gas. In one specific variant, the etching gas comprises ammonia and one or more of NH₃NF₃) gas and anhydrous hydrogen fluoride (HF).

In one configuration of the third embodiment, the substrate support is adapted to move vertically within the chamber body to locate the substrate in a heating position proximate the second electrode during an oxidation process and to locate the substrate in an etch position removed from the second electrode during an etch process. In a specific configuration of the third embodiment, the substrate support comprises a receiving surface adapted to support the substrate thereon, wherein the receiving surface is disposed above a shaft coupled to a lift mechanism. In one example, the lift mechanism is adapted to move the receiving surface vertically within the chamber body to locate the substrate in a heating position proximate the second electrode during an oxidation process and to locate the substrate in an etch position removed from the second electrode during an etch process.

In another variant of the third embodiment, the substrate support assembly comprises one or more gas passageways that are in fluid communication with the receiving surface at one end thereof, and a purge gas source or vacuum source at a second end thereof. In another variant, the receiving surface comprises one or more recessed channels formed on an upper surface thereof.

In another variant of the third embodiment, the shaft comprises one or more embedded gas conduits adapted to deliver one or more fluids to the gas passageways. In one example, the one or more embedded conduits are adapted to deliver a heating medium to the one or more fluid channels. The one or more embedded conduits can be adapted to deliver a coolant to the one or more fluid channels.

In a specific variant of the third embodiment, the control system, the heating system and the cooling system are configured to cycle between the first temperature and second temperature within a time period of less than about three minutes.

In another variant of the third embodiment, the cooling system comprises a showerhead disposed in the chamber adjacent the substrate support, the showerhead in communication with a cooling fluid. In still another variant of the third embodiment, the heating system comprises at least one a light source and a resistive heater.

In embodiments including the resistive heater, the resistive heater can disposed within the substrate support and/or within the showerhead. The heating system of the third embodiment may include a light source disposed so that light energy emitted by the light source contacts the material surface at an angle of incidence that optimizes absorption by the material being processed. The angle of incidence in one specific variant is at a Brewster angle for the material layer being processed.

A further embodiment of an apparatus for performing a cyclical oxidation and etching process on a material layer, comprises: a processing chamber having a plurality of walls defining a processing region within the processing chamber including a substrate support to hold a substrate having a material layer within the processing region; an oxygen-containing gas supply, an inert gas supply and an etching gas supply in fluid communication with the processing chamber to deliver the oxygen-containing gas, the inert gas and the etching gas into the process chamber; a remote plasma source in fluid communication with the process chamber and the etching gas to form an etching plasma remotely from the chamber and conduit to deliver the etching plasma into the chamber; a heating system to heat the substrate within the chamber to a first temperature greater than about 100° C.; a cooling system to cool the substrate within the chamber to a second temperature below the first temperature; and a control system to cycle the substrate within the chamber between the first temperature the second temperature.

In one variant of the fourth embodiment, the apparatus is configured to conduct an oxidation process substantially only by thermal oxidation. In a specific variant of the third embodiment, the apparatus is configured to conduct oxidation by a rapid thermal oxidation process. In another specific variant of the fourth embodiment, the heating system comprises a rapid thermal processing chamber comprising a radiant heat source and a reflector plate, wherein the substrate support is disposed between the reflector plate and the radiant heat source.

In one variant of the fourth embodiment, the remote plasma source is in fluid communication with an etching gas comprising a fluorine-containing gas. In another variant of the fourth embodiment, the chamber includes at least one elongate lance to deliver etching plasma products into the chamber. The chamber can include a plurality of elongate lances radially spaced about the chamber to deliver the etching plasma products into the chamber.

In another variant of the fourth embodiment, the cooling system comprises a reflector plate incorporating gas distribution outlets to distribute a gas evenly over a substrate to allow rapid and controlled heating and cooling of the substrate. In still another variant of the fourth embodiment, the apparatus comprises lift pins adapted to selectively contact and support the substrate to move the substrate towards and away from the reflector plate. In another variant of the fourth embodiment, the apparatus includes a stator assembly coupled to the substrate support to move the substrate being processed towards and away from the plate. The stator assembly can be magnetically coupled to the substrate support.

In a specific configuration of the fourth embodiment, at least one of the stator assembly and lift pins cooperate with the cooling system to move the substrate support closer to the reflector plate to cool the substrate.

In another specific configuration of the fourth embodiment, the control system, the heating system and the cooling system are configured to cycle between the first temperature and second temperature within a time period of less than about three minutes. In yet another variant, the apparatus is configured to conduct an oxidation process by photochemical oxidation.

Thus, semiconductor devices suitable for narrow pitch applications and methods of fabrication thereof are described herein. The apparatus described herein can be used to manufacture semiconductor devices have a floating gate configuration suitable for use in narrow pitch applications, such as at device nodes of 32 nm and below. Exemplary devices nodes are less than or equal to about 30 nm, less than or equal to about 25 nm, less than or equal to about 20 nm, less than or equal to about 15 nm, and less than or equal to about 13 nm. Such semiconductor devices may include, for example, NAND and NOR flash memory devices. The floating gate configuration provided herein advantageously provides semiconductor devices having maintained or improved sidewall capacitance between a floating gate and a control gate, and reduced interference or noise between adjacent floating gates in such devices.

Further, the apparatus for performing the methods disclosed herein advantageously form the semiconductor devices while limiting undesired processes, such as oxygen diffusion which can, for example, thicken a tunnel oxide layer of the inventive device. The methods can advantageous be applied towards the fabrication of other devices or structures, for example, such as FinFET devices or hard mask structures to overcome limitations in the critical dimension imposed by conventional lithographic patterning.

While the foregoing is directed to embodiments of the present invention, other and further embodiments of the invention may be devised without departing from the basic scope thereof.

1. An apparatus for performing a cyclical oxidation and etching process on a material layer, comprising:
a processing chamber having a plurality of walls defining a processing region within the processing chamber including a substrate support to hold a substrate having a material layer within the processing region;
an oxygen-containing gas supply, an inert gas supply and an etching gas supply in fluid communication with the processing chamber to deliver the oxygen-containing gas, the inert gas and the etching gas into the process chamber;
a plasma source to form a plasma in a plasma generation region inside the chamber and at least one of the oxygen-containing gas and etching gas to energize the gas to form at least one of an oxygen plasma, and an etching plasma to contact the material layer;
a heating system to heat the substrate within the chamber to a first temperature greater than about 100° C.;
a cooling system to cool the substrate within the chamber to a second temperature below the first temperature; and
a control system to cycle the substrate within the chamber between the first temperature the second temperature.

2. The apparatus of claim 1, wherein the control system, the heating system and the cooling system are configured to cycle between the first temperature and second temperature within a time period of less than about three minutes.

3. The apparatus of claim 1, wherein the cooling system comprises a substrate support including passages for allowing cooling medium to flow therethrough.

4. The apparatus of claim 1, wherein the cooling system comprises a showerhead disposed in the chamber adjacent the substrate support, the showerhead in communication with a cooling fluid.

5. The apparatus of claim 4, wherein the heating system comprises at least one a light source and a resistive heater.

6. The apparatus of claim 5, wherein the resistive heater is disposed within the substrate support.

7. The apparatus of claim 5, wherein the resistive heater is disposed within the showerhead.

8. The apparatus of claim 1 wherein the heating system includes a light source disposed so that light energy emitted by the light source contacts the material surface at an angle of incidence that optimizes absorption by the material being processed.

9. The apparatus of claim 8, wherein the angle of incidence is at a Brewster angle for the material layer being processed.

10. The apparatus of claim 1, wherein the process chamber has a ceiling plasma source comprising a power applicator including a coil disposed over the ceiling the coil coupled through an impedance match network a power source to generate plasma within the plasma generation region.

11. The apparatus of claim 10, wherein the etching gas comprises a fluorine-containing gas and the chamber further comprises a nitrogen gas source in communication with a plasma source.

12. The apparatus of claim 2, wherein the second temperature is in the range of about 200° C. and 1000° C.

13. The apparatus of claim 12, wherein the chamber is configured to perform an etch process on a material layer on the substrate, at least a portion of the etch process being performed at the first temperature.

14. The apparatus of claim 13, wherein the etch process comprises a dry etch process and the etching gas comprises a fluorine-containing gas.

15. The apparatus of claim 14, wherein the gas source further includes a nitrogen gas in communication with a plasma source.

16. The apparatus of claim 13, wherein the etching gas is in fluid communication with the plasma source to form an etching plasma.

17. The apparatus of claim 2, wherein the temperature control system includes a cooling system to perform at least a portion of the etching process at a temperature below about 50° C.

18. The apparatus of claim 17, wherein the cooling system is configured to reduce the temperature of the substrate to a temperature in the range of about 25° C. to about 35° C.

19. The apparatus of claim 18, wherein the apparatus is configured to cycle between the first temperature and second temperature in less than about three minutes.

20. The apparatus of claim 1, wherein the apparatus is configured to shape a material layer on the substrate, the material layer having a desired shape with a first width proximate a base of the desired shape that is substantially equivalent to a second width proximate a top of the desired shape, wherein the first and second width of the desired shape is between about 1 to about 30 nanometers.
